(19) United States
(12) Patent Application Publication
(10) Pub. No.: US 2026/0173756 A1
(43) Pub. Date: Jun. 18, 2026

(54) POLYCYCLIC COMPOUND, LIGHT-EMITTING DEVICE AND ELECTRONIC DEVICE

(71) Applicant: Samsung Display Co., Ltd., Yongin-si (KR)

(72) Inventors: Se Ran KIM, Yongin-si (KR); Hyeon Deuk KIM, Yongin-si (KR); Hoi Lim KIM, Yongin-si (KR); Jun Ha PARK, Yongin-si (KR); Seung In BAEK, Yongin-si (KR); Dong Sun YOO, Yongin-si (KR); Seok Gyu YOON, Yongin-si (KR)

(21) Appl. No.: 19/341,847

(22) Filed: Sep. 26, 2025

(30) Foreign Application Priority Data
Dec. 17, 2024 (KR) 10-2024-0188694

(51) Int. Cl. H10K 85/60; C07F 5/02; C09K 11/02; C09K 11/06; H10K 50/12; H10K 101/20

(52) U.S. Cl. CPC H10K 85/658; C07F 5/027; C09K 11/02; C09K 11/06; H10K 85/615; H10K 85/6572; C07B 2200/05; C09K 2211/1416; C09K 2211/1425; C09K 2211/1441; H10K 50/12; H10K 2101/20

(57) ABSTRACT

A light-emitting device includes a first electrode, a second electrode, and an emission layer disposed between the first electrode and the second electrode. The emission layer includes a polycyclic compound represented by Chemical Formula 1. In addition, an electronic apparatus that includes the light-emitting device, an electronic device that includes the light-emitting device, and the polycyclic compound are also provided.

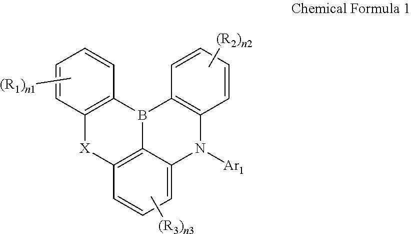

### CROSS-REFERENCE TO RELATED APPLICATION

The present application claims priority to and the benefit of Korean Patent Application No. 10-2024-0188694, filed on Dec. 17, 2024, in the Korean Intellectual Property Office, the entire disclosure of which is incorporated herein by reference.

### BACKGROUND

### 1. Field

One or more embodiments of the present application relate to a polycyclic compound, a light-emitting device including the polycyclic compound, and an electronic device including the light-emitting device.

### 2. Description of the Related Art

Organic light-emitting devices (OLEDs) are self-emissive under an applied driving voltage and may offer improved viewing angles and contrast ratios. Additionally, organic light-emitting devices typically exhibit high response speeds and high luminance compared to other types (kinds) of light-emitting devices.

An organic light-emitting device may include an emission layer arranged between a first electrode and a second electrode. Holes provided from the first electrode and electrons provided from the second electrode may be recombined in the emission layer to generate excitons. As the excitons transition and decay from an excited state to a ground state, light may be emitted from the emission layer.

The emission layer may include a light-emitting material. Excitons may be generated in a ratio of 25% singlet state and 75% triplet state. The light-emitting material may be classified as a fluorescent material, a phosphorescent material, or a delayed fluorescent material, depending on the decay mechanism of the excitons.

From a quantum mechanical perspective, a singlet exciton (S₁) may contribute to light emission in fluorescent materials, whereas a triplet exciton (T₁) typically undergoes a non-radiative transition to the ground state (S₀), resulting in no light emission.

To achieve a theoretical internal quantum efficiency of 100%, materials capable of efficiently facilitating reverse intersystem crossing (RISC) from the triplet state to the singlet state are under research and development.

### SUMMARY

One or more aspects of embodiments of the present disclosure are directed toward a polycyclic compound that has improved color property, luminous efficiency, and life-span property.

One or more aspects of embodiments of the present disclosure are directed toward a light-emitting device that has improved color property, luminous efficiency, and life-span property.

One or more aspects of embodiments of the present disclosure are directed toward an electronic device that has improved color property, luminous efficiency, and life-span property.

Additional aspects will be set forth in part in the description which follows and, in part, will be apparent from the description, or may be learned by practice of the presented embodiments of the disclosure.

According to one or more embodiments of the present disclosure, a polycyclic compound is represented by Chemical Formula 1.

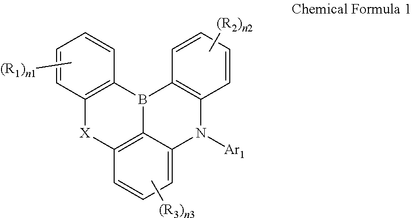

In Chemical Formula 1, X may represent N(R₄), S, O, or Se, and Ar₁ may be represented by Chemical Formula 2.

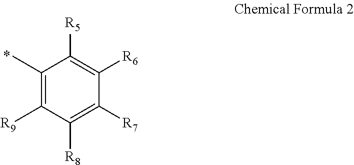

In Chemical Formulae 1 and 2, R₁ to R₉ may each independently be selected from among groups including hydrogen, deuterium, —OH, —CN, —F, —CL, —Br, —I, —CD₃, —CD₂H, —CDH₂, —CF₃, —CF₂H, —CFH₂, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₆₀ cycloalkyl group, a substituted or unsubstituted C₅-C₆₀ cycloalkenyl group, a substituted or unsubstituted C₃-C₆₀ heterocycloalkyl group, a substituted or unsubstituted C₃-C₆₀ heterocycloalkenyl group, a substituted or unsubstituted C₆-C₆₀ aryl group, a substituted or unsubstituted C₇-C₆₀ arylalkyl group, a substituted or unsubstituted C₂-C₆₀ heteroaryl group, a substituted or unsubstituted C₃-C₆₀ heteroarylalkyl group, a substituted or unsubstituted C₆-C₆₀ aryloxy group, a substituted or unsubstituted C₆-C₆₀ arylthio group, a substituted or unsubstituted C₈-C₆₀ condensed polycyclic group, and a substituted or unsubstituted silyl group, and two or more adjacent groups selected from among the groups (i.e., R₁ to R₉) are optionally combined with each other to form a saturated ring or an unsaturated ring.

n1 and n2 are the same as or different from each other, and may each independently be an integer from 0 to 4. At least one of n1 or n2 is not 0, and n3 is an integer from 0 to 3. At least one group selected from the group consisting of at least one R₁, at least one R₂, and a combination thereof is a substituted or unsubstituted carbazole group,

At least one selected from among R₅ to R₉ is an aryl group in which a substituted or unsubstituted alicyclic hydrocarbon ring is condensed; two or more adjacent groups selected from among R₅ to R₉ are bonded to each other to form an alicyclic hydrocarbon ring; or at least one selected from among R₅ to R₉ is an aryl group in which a substituted or unsubstituted alicyclic hydrocarbon ring is condensed, and two or more adjacent groups selected from among remaining groups of R₅ to R₉ are bonded to each other to form an alicyclic hydrocarbon ring. *- represents a bonding position.

In one or more embodiments, the alicyclic hydrocarbon ring may each independently be selected from among a substituted or unsubstituted C₅-C₃₀ cycloalkane, a substituted or unsubstituted C₅-C₃₀ bicycloalkane, and a substituted or unsubstituted C₉-C₃₀ spiroalkane.

In one or more embodiments, k_{RISC} of the polycyclic compound may be about 6.00×10⁴ s⁻¹ or more.

In one or more embodiments, an oscillator strength of the polycyclic compound may be 0.36 or more, and ΔEst of the polycyclic compound may be 0.39 eV or less.

According to one or more embodiments, a light-emitting device may include a first electrode, a second electrode, and an emission layer between (e.g., arranged between) the first electrode and the second electrode. The emission layer may include the polycyclic compound represented by Chemical Formula 1.

In one or more embodiments, the light-emitting device may further include a charge generation layer between the first electrode and the second electrode. The emission layer may include a plurality of emission layers, and the charge generation layer may be arranged between adjacent emission layers among the plurality of emission layers. At least one selected from among the plurality of emission layers may include the polycyclic compound.

In one or more embodiments, the polycyclic compound may be included as a thermally activated delayed fluorescence (TADF) dopant, a host for a phosphorescent dopant, or a fluorescent host.

According to one or more embodiments of the present disclosure, an electronic device may include the light-emitting device.

The polycyclic compound according to one or more embodiments of the present disclosure may provide enhanced color purity, improved luminous efficiency, and extended operational lifetime. These improvements may result from the compound's enhanced molecular structure, which facilitates efficient exciton utilization and stable emission characteristics under electrical excitation. The light-emitting device according to one or more embodiments of the present disclosure and the electronic device including the light-emitting device may exhibit superior performance characteristics—including enhanced color rendering, higher brightness, and longer device lifespan—by incorporating the polycyclic compound described herein. For example, the polycyclic compound may function as a thermally activated delayed fluorescence (TADF) emitter or as a host material in a multilayer emission architecture. Its ability to promote reverse intersystem crossing (RISC) from triplet to singlet states enables more efficient utilization of excitons, thereby increasing internal quantum efficiency. Furthermore, the compound's structural rigidity and thermal stability contribute to improved device durability and reduced degradation over time.

### BRIEF DESCRIPTION OF DRAWINGS

The accompanying drawings are included to provide a further understanding of the present disclosure and are incorporated in and constitute a part of this disclosure. The drawings illustrate embodiments of the present disclosure and, together with the description, serve to explain principles of the disclosure. Above and/or other aspects of the disclosure should become apparent and appreciated from the following description of embodiments taken in conjunction with the accompanying drawings.

FIGS. 1-6 are each a schematic cross-sectional view illustrating a light-emitting device in accordance with one or more embodiments of the present disclosure.

FIG. 7 is a schematic cross-sectional view illustrating a display device in accordance with one or more embodiments of the present disclosure.

FIG. 8 is a schematic cross-sectional view illustrating a display device in accordance with one or more embodiments of the present disclosure.

FIG. 9 is a schematic cross-sectional view illustrating a stack construction of light-emitting structure in a display device in accordance with one or more embodiments of the present disclosure.

FIG. 10 is a schematic cross-sectional view illustrating a display device in accordance with one or more embodiments of the present disclosure.

FIG. 11 is a schematic cross-sectional view illustrating a display device in accordance with one of more embodiments of the present disclosure.

FIG. 12 is a schematic exploded perspective view illustrating an electronic device in accordance with one or more embodiments of the present disclosure.

FIG. 13 is a schematic view illustrating an electronic device in accordance with one or more embodiments of the present disclosure.

FIG. 14 is a block diagram of an electronic device in accordance with one or more embodiments of the present disclosure.

FIG. 15 are schematic diagrams of electronic devices in accordance with one or more embodiments of the present disclosure.

### DETAILED DESCRIPTION

According to one or more embodiments of the present disclosure, there is provided a polycyclic compound that may include a light-emitting core having a multiple resonance effect and a chemical structure in which at least one selected from among groups introduced into a nitrogen atom in the light-emitting core is condensed by an alicyclic hydrocarbon ring. The polycyclic compound may thus have improved oxidation stability and energy efficiency.

According to one or more embodiments of the present disclosure, a light-emitting device including the polycyclic compound and an electronic device including light-emitting device are provided.

### Definition of Terminology

In the present disclosure, the term “substituted or unsubstituted” may refer to being substituted or unsubstituted by one or more substituent selected from the group consisting of deuterium, a halogen, a cyano group, a nitro group, an amino group, a silyl group, an oxy group, a thio group, a sulfinyl group, a sulfonyl group, a carbonyl group, an ester group, boron, a phosphine oxide group, a phosphine sulfide group, an alkyl group (e.g., a C₁-C₆₀ alkyl group, a C₁-C₁₀ alkyl group), an alkenyl group (e.g., a C₂-C₆₀ alkenyl group, a C₂-C₁₀ alkenyl group), an alkynyl group (e.g., a C₂-C₆₀ alkynyl group, a C₂-C₁₀ alkynyl group), an alkoxy group (e.g., a C₁-C₆₀ alkoxy group, a C₁-C₁₀ alkoxy group), a hydrocarbon ring group, an aryl group (e.g., a C₆-C₆₀ aryl group), and a heterocyclic group (e.g., a C₁-C₆₀ heterocyclic group). For example, the term “substituted alkyl group” may refer to a group in which at least one of hydrogen atoms of the alkyl group is substituted with the above-described substituent, and thus the substituent is bonded to a carbon atom of the alkyl group.

The substituent may include a combination of substituents selected from among the groups described above. For example, at least one hydrogen atom in the alkyl group, the aryl group, and/or the like, included as a substituent may be substituted with deuterium, a halogen, a cyano group, a nitro group, an amino group, a silyl group, an oxy group, a thio group, a sulfinyl group, a sulfonyl group, a carbonyl group, an ester group, boron, a phosphine oxide group, a phosphine sulfide group, an alkyl group, an alkenyl group, an alkynyl group, a hydrocarbon ring group, an aryl group, a heterocyclic group, or a combination thereof.

In the substituents described above, a multivalent substituent such as an amino group, a phosphine sulfide group, a phosphine oxide group, a sulfinyl group, a sulfonyl group, an oxy group, a carbonyl group, an ester group, and/or the like, may each independently be substituted with a C₁-C₁₀ alkyl group, a C₁-C₁₀ alkenyl group, a C₁-C₁₀ alkynyl group, and/or a C₆-C₁₀ aryl group.

In the disclosure, regarding the term “substituted or unsubstituted Cₐ-C_{b} Y group,” the range of a to b refers to the number of carbon atoms in an unsubstituted Y group, and may not include (e.g., may exclude) the number of carbon atoms of its substituent.

In the disclosure, an alkyl group may be a monovalent hydrocarbon group in which one hydrogen atom is removed from a linear or branched hydrocarbon group.

Non-limiting examples of an alkyl group may include a methyl group, an ethyl group, a propyl group, a sec-butyl group, a tert-butyl group, an iso-butyl group, a pentyl group, a neopentyl group, a 2-ethyl butyl group, a 3,3-dimethyl butyl group, a hexyl group, a heptyl group, an octyl group, and/or the like.

In the disclosure, an alkylene group may be a divalent hydrocarbon group in which two hydrogen atoms are removed from a linear or branched hydrocarbon group.

In the disclosure, an alkenyl group may have substantially the same skeleton as that of an alkyl group, and may be a monovalent hydrocarbon group that includes at least one carbon-carbon double bond. In the disclosure, an alkenylene group may be a divalent hydrocarbon group in which one hydrogen atom is further removed from an alkenyl group.

In the disclosure, an alkynyl group may have substantially the same skeleton as that of an alkyl group, and may be a monovalent hydrocarbon group that includes at least one carbon-carbon triple bond. In the disclosure, an alkynylene group may be a divalent hydrocarbon group in which one hydrogen atom is further removed from an alkynyl group.

In the disclosure, an aryl group may be a monovalent hydrocarbon group in which one hydrogen atom is removed from a hydrocarbon group having an aromatic structure. The definition of an aryl group may also encompass a group in which multiple aromatic rings are directly connected, such as a biphenyl group. Non-limiting examples of an aryl group may include, e.g., a phenyl group, a naphthyl group, an anthracenyl group, a phenanthrenyl group, a pyrenyl group, a fluorenyl group, a tetracenyl group, a biphenyl group, a terphenyl group, a quaterphenyl group, a chrysenyl group, and/or the like.

In the disclosure, a group in which two or more aryl rings are condensed to each other or linked to each other by an alicyclic hydrocarbon ring, such as a fluorenyl group, may be encompassed in the definition of an aryl group.

For example, a biphenyl group may be interpreted as an aryl group, or may be interpreted as a phenyl group that is substituted with a phenyl group.

In the disclosure, an arylene group may be a divalent hydrocarbon group in which one hydrogen atom is further removed from an aryl group.

In the disclosure, a heteroaryl group may be a monovalent group having an aromatic structure that includes at least one heteroatom such as B, O, P, S, and/or Si as a ring-forming atom. In the disclosure, a heteroarylene group may be a divalent group having an aromatic structure that includes at least one heteroatom such as B, O, P, S, and/or Si as a ring-forming atom. When a heteroaryl group or a heteroarylene group includes two or more heteroatoms, the two or more heteroatoms may be the same as or different from each other.

In the disclosure, a group in which two or more aryl rings are condensed or linked to a non-aromatic heterocyclic ring, such as a carbazole group, may also be encompassed in the definition of a heteroaryl group.

In the disclosure, the term “cyclic group” may encompass a monocyclic group or a polycyclic group, and may also encompass an alicyclic ring or an aromatic ring.

In the disclosure, the term “polycyclic group” may be a group in which two or more rings are connected to each other or condensed to each other through one or more atoms. For example, a polycyclic structure may include a bicyclic structure through a bridge carbon, a spiro structure, a fused structure, and/or the like.

In the disclosure, the term “condensed group” or “condensed ring structure” may each be a group in which two or more adjacent rings share two or more atoms among the above-described polycyclic structures. Non-limiting examples of a condensed ring structure may include naphthalene, anthracene, phenanthrene, fluorene, pyrene, benzopyrene, pentacene, polyacene, helicene, and/or the like.

In the disclosure, the term “carbocyclic group (e.g., C₃-C₆₀ carbocyclic group)” may be a cyclic group in which only carbon atoms are ring-forming atoms. In the disclosure, a heterocyclic group (e.g., a C₁-C₆₀ heterocyclic group) may be a cyclic group that includes at least one heteroatom as a ring-forming atom, in addition to carbon atoms.

In the disclosure, a carbocyclic group and a heterocyclic group may each independently be a monocyclic group that includes (e.g., consists of) one (e.g., exactly one) ring or a polycyclic group in which two or more rings are condensed with each other.

### Polycyclic Compound

A polycyclic compound according to one or more embodiments may be represented by Chemical Formula 1.

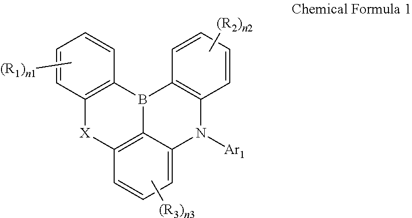

In Chemical Formula 1, X may represent N(R₄), S, O, or Se.

Ar₁ may be represented by Chemical Formula 2.

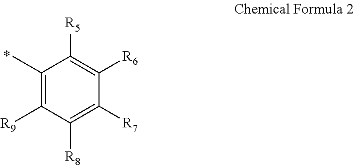

In Chemical Formulae 1 and 2, R₁ to R₉ may each independently be hydrogen, deuterium, —OH, —CN, —F, —CL, —Br, —I, —CD₃, —CD₂H, —CDH₂, —CF₃, —CF₂H, —CFH₂, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₆₀ cycloalkyl group, a substituted or unsubstituted C₅-C₆₀ cycloalkenyl group, a substituted or unsubstituted C₃-C₆₀ heterocycloalkyl group, a substituted or unsubstituted C₃-C₆₀ heterocycloalkenyl group, a substituted or unsubstituted C₆-C₆₀ aryl group, a substituted or unsubstituted C₇-C₆₀ arylalkyl group, a substituted or unsubstituted C₂-C₆₀ heteroaryl group, a substituted or unsubstituted C₃-C₆₀ heteroarylalkyl group, a substituted or unsubstituted C₆-C₆₀ aryloxy group, a substituted or unsubstituted C₆-C₆₀ arylthio group, a substituted or unsubstituted C₈-C₆₀ condensed polycyclic group, or a substituted or unsubstituted silyl group. Two or more adjacent groups selected from among the above-mentioned groups (i.e., R₁ to R₉) may optionally be combined with each other to form a saturated ring or an unsaturated ring.

n1 and n2 may be the same as or different from each other, may each independently be an integer from 0 to 4, and at least one of n1 or n2 may not 0. n3 may be an integer from 0 to 3.

At least one group selected from the group consisting of at least one R₁, at least one R₂, and a combination thereof may be a substituted or unsubstituted carbazole group.

At least one selected from among R₅ to R₉ may be an aryl group in which a substituted or unsubstituted alicyclic hydrocarbon ring is condensed; two or more adjacent groups selected from among R₅ to R₉ may be bonded to each other to form an alicyclic hydrocarbon ring; or at least one selected from among R₅ to R₉ may be an aryl group in which a substituted or unsubstituted alicyclic hydrocarbon ring is condensed, and two or more adjacent groups selected from among remaining groups of R₅ to R₉ may be bonded to each other to form an alicyclic hydrocarbon ring, and *- represents a bonding position.

Accordingly, Dexter Energy Transfer (DET) may be hindered by surrounding an emission core of the polycyclic compound with bulky substituent(s), so that oxidation stability may be improved. Additionally, exciton quenching phenomenon such as triplet-triplet annihilation (TTA) and triplet-polaron quenching (TPQ) due to interaction with the surrounding compounds may be reduced, thereby preventing or reducing energy loss.

In one or more embodiments, the saturated ring may be independently selected from among a 5-membered ring, a 6-membered ring, and a 7-membered ring, and the ring may be a hydrocarbon ring or a heteroatom-containing ring. The saturated ring may each independently be unsubstituted or substituted with at least one selected from the group consisting of deuterium, —F, —CL, —CD₃, —CD₂H, —CDH₂, a C₁-C₁₀ straight-chain alkyl group, a C₃-C₁₀ branched alkyl group, a C₂-C₁₀ straight-chain alkenyl group, a C₃-C₁₀ branched alkenyl group, and a C₆-C₁₀ aryl group.

In one or more embodiments, the unsaturated ring may be independently selected from among a 5-membered ring, a 6-membered ring, and a 7-membered ring, and the ring may be a hydrocarbon ring or a heteroatom-containing ring. The unsaturated ring may include, e.g., a cycloalkene ring or an aromatic ring containing a C═C unsaturated double bond. The unsaturated ring may be independently unsubstituted or substituted with at least one selected from the group consisting of deuterium, —F, —CL, —CD₃, —CD₂H, —CDH₂, a C₁-C₁₀ straight-chain alkyl group, a C₃-C₁₀ branched alkyl group, a C₂-C₁₀ straight-chain alkenyl group, a C₃-C₁₀ branched alkenyl group, and a C₅-C₁₀ aryl group.

In one or more embodiments, for example, the substituted or unsubstituted C₈-C₆₀ condensed polycyclic group may be a condensed polycyclic group in which a C₄-C₁₀ aliphatic hydrocarbon ring and a C₆-C₅₀ aromatic hydrocarbon ring are condensed. The condensed polycyclic group may have a structure in which, e.g., one C₄-C₆ aliphatic hydrocarbon ring is condensed between two C₆-C₁₅ aromatic hydrocarbon rings. In one or more embodiments, the condensed polycyclic group may be, e.g., a substituted or unsubstituted carbazole group, a substituted or unsubstituted fluorene group, a spiro-bifluorene group, and/or the like.

In one or more embodiments, e.g., the silyl group may be —Si(R^{Sa})(R^{Sb})(R^{Sc}), and R^{Sa}, R^{Sb}, and R^{Sc} may each independently be hydrogen, deuterium, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₆₀ cycloalkyl group, a substituted or unsubstituted C₅-C₆₀ cycloalkenyl group, a substituted or unsubstituted C₃-C₆₀ heterocycloalkyl group, a substituted or unsubstituted C₃-C₆₀ heterocycloalkenyl group, a substituted or unsubstituted C₆-C₆₀ aryl group, a substituted or unsubstituted C₂-C₆₀ heteroaryl group, a substituted or unsubstituted C₆-C₆₀ aryloxy group, a substituted or unsubstituted C₆-C₆₀ arylthio group, or a substituted or unsubstituted C₈-C₆₀ condensed polycyclic group. The above descriptions of the condensed polycyclic group may also be applied.

In one or more embodiments, X may be N(R₄), and R₄ may be represented by Chemical Formula 3.

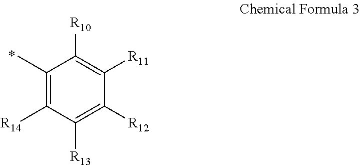

In Chemical Formula 3, R₁₀ to R₁₄ may each independently be hydrogen, deuterium, —OH, —CN, —F, —CL, —Br, —I, —CD₃, —CD₂H, —CDH₂, —CF₃, —CF₂H, —CFH₂, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₆₀ cycloalkyl group, a substituted or unsubstituted C₅-C₆₀ cycloalkenyl group, a substituted or unsubstituted C₃-C₆₀ heterocycloalkyl group, a substituted or unsubstituted C₃-C₆₀ heterocycloalkenyl group, a substituted or unsubstituted C₆-C₆₀ aryl group, a substituted or unsubstituted C₇-C₆₀ arylalkyl group, a substituted or unsubstituted C₂-C₆₀ heteroaryl group, a substituted or unsubstituted C₃-C₆₀ heteroarylalkyl group, a substituted or unsubstituted C₆-C₆₀ aryloxy group, a substituted or unsubstituted C₆-C₆₀ arylthio group, a substituted or unsubstituted C₈-C₆₀ condensed polycyclic group, or a substituted or unsubstituted silyl group. Two or more adjacent groups selected from among the-above mentioned groups (e.g., R₁₀ to R₁₄) may optionally be combined with each other to form a saturated ring or an unsaturated ring.

At least one selected from among R₁₀ to R₁₄ may be an aryl group in which a substituted or unsubstituted alicyclic hydrocarbon ring is condensed; or two or more adjacent groups selected from among R₁₀ to R₁₄ may be combined with each other to form an alicyclic hydrocarbon ring; or at least one selected from among R₁₀ to R₁₄ may be an aryl group in which a substituted or unsubstituted alicyclic hydrocarbon ring is condensed, and two or more adjacent groups selected from among remaining groups of R₁₀ to R₁₄ may be bonded to each other to form an alicyclic hydrocarbon ring. *- represents a bonding position.

In one or more embodiments, the alicyclic hydrocarbon ring may be selected from among a 5-membered ring to a 9-membered ring. For example, in one or more embodiments, the alicyclic hydrocarbon ring may be selected from among a 5-membered ring, a 6-membered ring, and a 7-membered ring.

In one or more embodiments, the alicyclic hydrocarbon ring may be a 5-membered ring, a 6-membered ring, or a 7-membered ring.

In one or more embodiments, the alicyclic hydrocarbon ring may be independently selected from among a substituted or unsubstituted cycloalkane, a substituted or unsubstituted bicycloalkane, and a substituted or unsubstituted spiroalkane. The alicyclic hydrocarbon ring may be a ring that does not contain an unsaturated bond, and may include a cycloalkane structure, a bicycloalkane structure, or a spiroalkane structure.

The cycloalkane may refer to a saturated ring compound in which carbon atoms are connected by a single bond. The bicycloalkane may refer to a ring compound in which two saturated rings are connected to each other by sharing two or more carbon atoms, and may include, e.g., a fused bicyclic compound or a bridged bicyclic compound. The spiroalkane may refer to a spiro compound in which two saturated rings are connected to each other by sharing one carbon atom.

In one or more embodiments, the alicyclic hydrocarbon rings may be independently selected from among a substituted or unsubstituted C₅-C₃₀ cycloalkane, a substituted or unsubstituted C₅-C₃₀ bicycloalkane, and a substituted or unsubstituted C₉-C₃₀ spiroalkane.

For example, the alicyclic hydrocarbon rings may be independently selected from the group consisting of substituted or unsubstituted cyclopentane, substituted or unsubstituted cyclohexane, substituted or unsubstituted cycloheptane, substituted or unsubstituted bicyclo[2.1.0]pentane, substituted or unsubstituted bicyclo[2.2.0]hexane, substituted or unsubstituted bicyclo[4.1.0]heptane, substituted or unsubstituted spiro[4.4]nonane, substituted or unsubstituted spiro[4.5]decane, substituted or unsubstituted spiro[5.5]undecane, substituted or unsubstituted spiro[6.5]dodecane, and substituted or unsubstituted spiro[6.6]tridecane.

In one or more embodiments, X may be N(R₄) or O.

In one or more embodiments, the polycyclic compound may be represented by Chemical Formula 1-1.

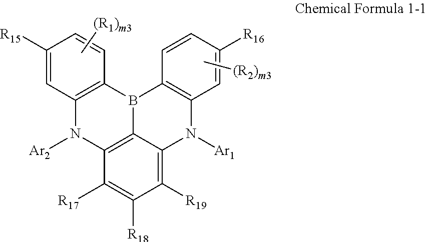

In Chemical Formula 1-1, at least one of Ar₁ or Ar₂ may be independently (e.g., may be any one) selected from among groups represented by Chemical Formulae 4-1 to 4-19.

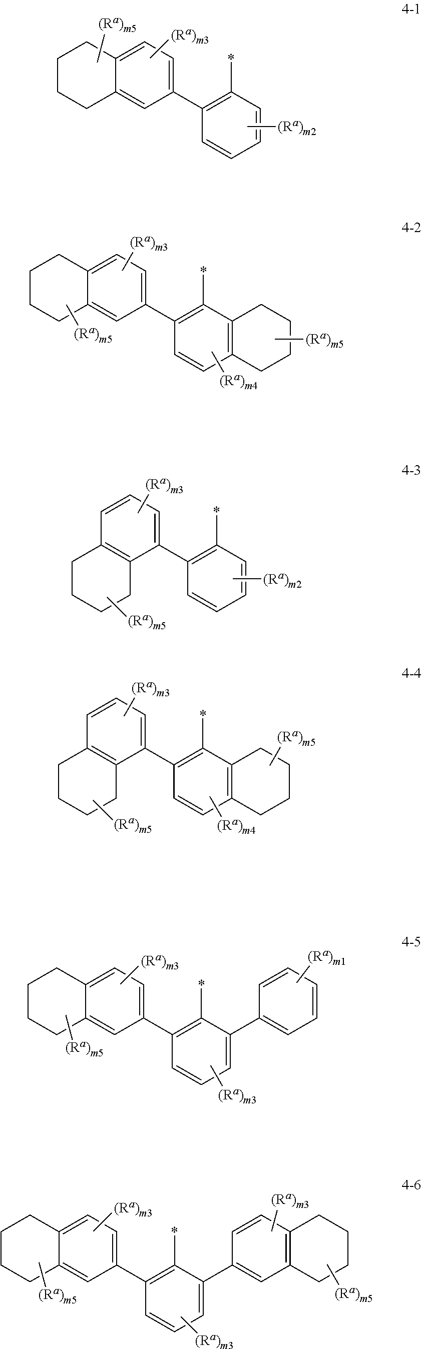

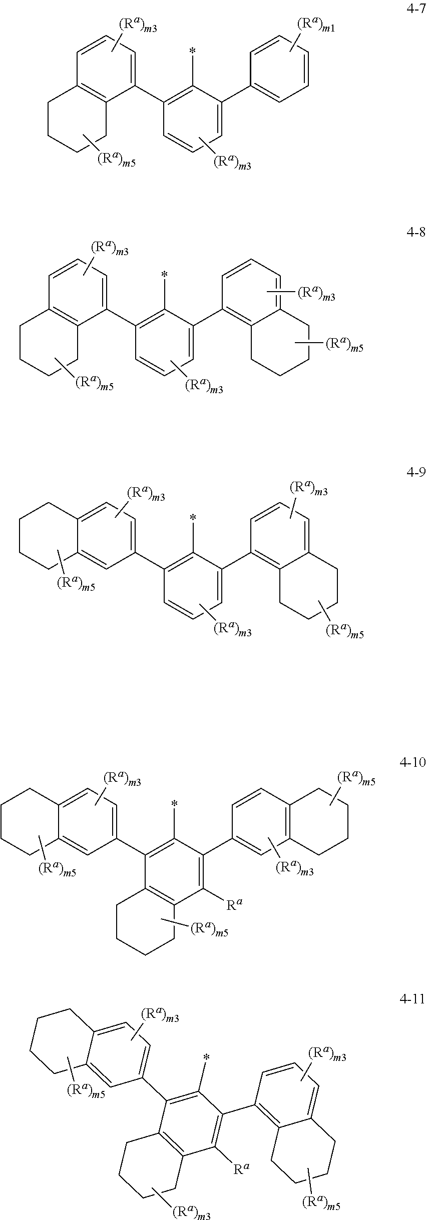

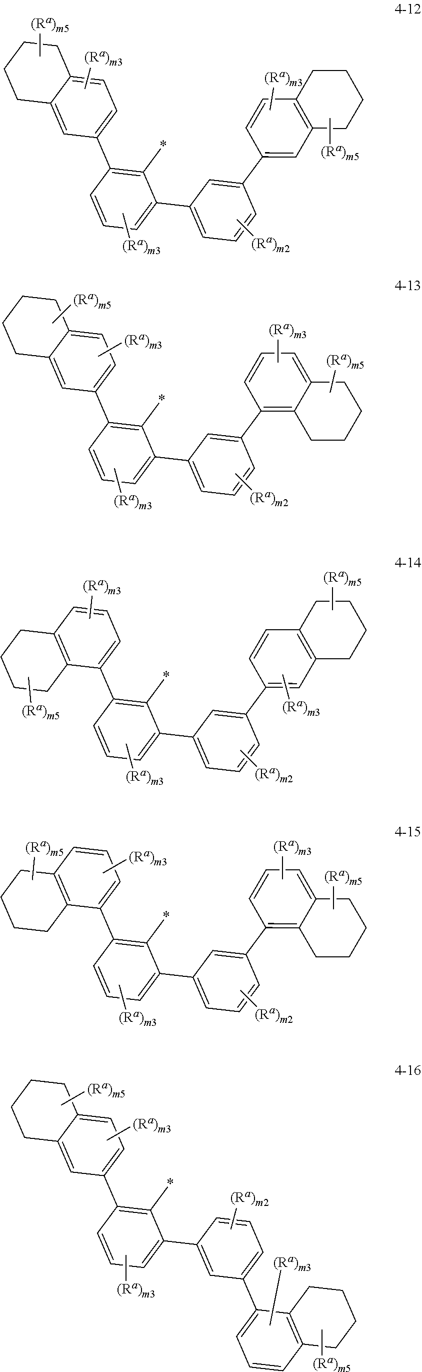

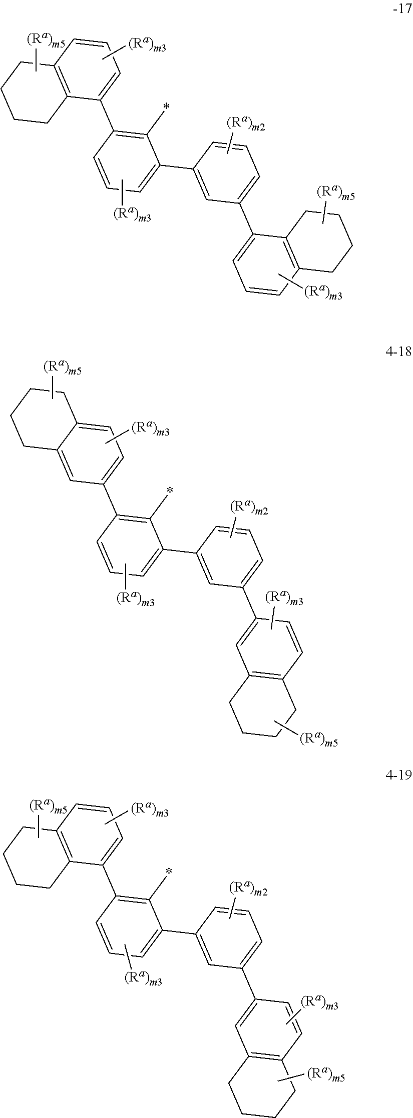

In Chemical Formula 1-1 and Chemical Formulae 4-1 to 4-19, R₁, R₂, R₁₅ to R₁₉, and R^{a} may each independently be hydrogen, deuterium, —OH, —CN, —F, —CL, —Br, —I, —CD₃, —CD₂H, —CDH₂, —CF₃, —CF₂H, —CFH₂, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₆₀ cycloalkyl group, a substituted or unsubstituted C₅-C₆₀ cycloalkenyl group, a substituted or unsubstituted C₃-C₆₀ heterocycloalkyl group, a substituted or unsubstituted C₃-C₆₀ heterocycloalkenyl group, a substituted or unsubstituted C₆-C₆₀ aryl group, a substituted or unsubstituted C₇-C₆₀ arylalkyl group, a substituted or unsubstituted C₂-C₆₀ heteroaryl group, a substituted or unsubstituted C₃-C₆₀ heteroarylalkyl group, a substituted or unsubstituted C₆-C₆₀ aryloxy group, a substituted or unsubstituted C₆-C₆₀ arylthio group, a substituted or unsubstituted C₈-C₆₀ condensed polycyclic group, or a substituted or unsubstituted silyl group. Two or more adjacent groups selected from among the above-mentioned groups (e.g., R₁, R₂, R₁₅ to R₁₉, and R^{a}) may optionally be combined with each other to form a saturated ring or an unsaturated ring.

At least one of R₁₅ or R₁₆ may be a substituted or unsubstituted carbazole group.

A plurality of m1 may be the same as or different from each other, and may each independently be an integer from 0 to 5, A plurality of m2 may be the same as or different from each other, and may each independently be an integer from 0 to 4. A plurality of m3 may be the same as or different from each other, and may each independently be an integer from 0 to 3. A plurality of m4 may be the same as or different from each other, and may each independently be an integer from 0 to 2. A plurality of m5 may be the same as or different from each other, and may each independently be an integer from 0 to 8. *- represents a bonding position.

In one or more embodiments, at least one of Ar₁ or Ar₂ may be selected from among the groups represented by Chemical Formulae 4-5 to 4-11.

In one or more embodiments, Ar₁ and Ar₂ may each independently be selected from among the groups represented by Chemical Formulae 4-1 to 4-19.

Accordingly, oxidation stability and energy efficiency of the polycyclic compound may be further improved.

In one or more embodiments, R₁₅ and R₁₆ may each independently be selected from among groups represented by Chemical Formulae 5-1 to 5-6, and at least one of R₁₅ or R₁₆ may be represented by Chemical Formula 5-1.

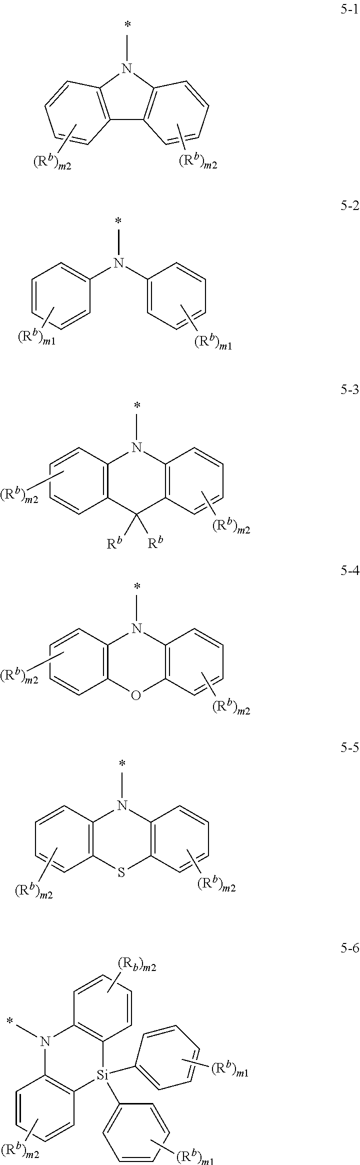

In Chemical Formulae 5-1 to 5-6, R^{b} may each independently be hydrogen, deuterium, —OH, —CN, —F, —CL, —Br, —I, —CD₃, —CD₂H, —CDH₂, —CF₃, —CF₂H, —CFH₂, a substituted or unsubstituted C₁-C₆₀ alkyl group, a substituted or unsubstituted C₂-C₆₀ alkenyl group, a substituted or unsubstituted C₃-C₆₀ cycloalkyl group, a substituted or unsubstituted C₅-C₆₀ cycloalkenyl group, a substituted or unsubstituted C₃-C₆₀ heterocycloalkyl group, a substituted or unsubstituted C₃-C₆₀ heterocycloalkenyl group, a substituted or unsubstituted C₁-C₆₀ aryl group, a substituted or unsubstituted C₇-C₆₀ arylalkyl group, a substituted or unsubstituted C₂-C₆₀ heteroaryl group, or a substituted or unsubstituted C₃-C₆₀ heteroarylalkyl group. Two or more adjacent groups selected from among the above-mentioned groups (e.g., R^{b}(s)) may optionally be combined with each other to form a saturated ring or an unsaturated ring.

A plurality of m1 may be the same as or different from each other, and may each independently be an integer from 0 to 5. A plurality of m2 may be the same as or different from each other, and may each independently be an integer from 0 to 4. *- represents a bonding position.

Accordingly, multiple resonance effect of the polycyclic compound may be further enhanced to achieve improved color properties.

In one or more embodiments, R₁₅ and R₁₆ may each be represented by Chemical Formula 5-1.

In one or more embodiments, R₁₇ to R₁₉ in Chemical Formula 1-1 may each independently be selected from among hydrogen, deuterium, —CD₃, —CD₂H, —CDH₂, and groups represented by Chemical Formulae 6-1 to 6-8.

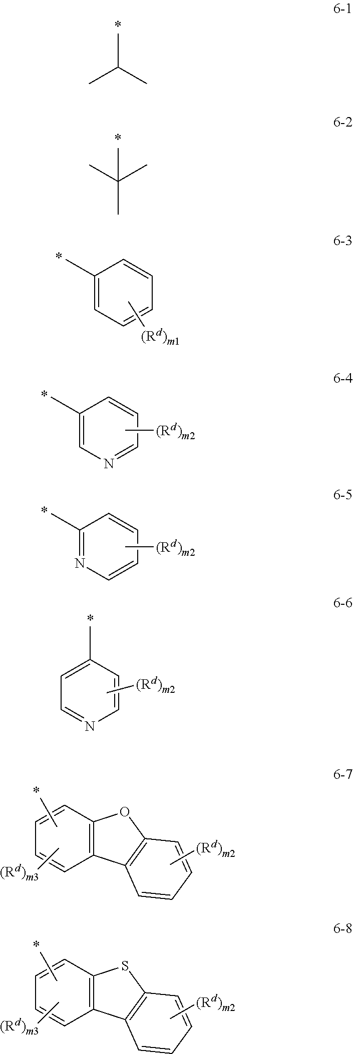

In Chemical Formulae 6-1 to 6-8, R^{d} may each independently be hydrogen, deuterium, —OH, —CN, —F, —CL, —Br, —I, —CD₃, —CD₂H, —CDH₂, —CF₃, —CF₂H, —CFH₂, a substituted or unsubstituted C₁-C₃₀ alkyl group, a substituted or unsubstituted C₂-C₃₀ alkenyl group, a substituted or unsubstituted C₃-C₃₀ cycloalkyl group, a substituted or unsubstituted C₅-C₃₀ cycloalkenyl group, a substituted or unsubstituted C₃-C₃₀ heterocycloalkyl group, a substituted or unsubstituted C₃-C₃₀ heterocycloalkenyl group, a substituted or unsubstituted C₆-C₆₀ aryl group, a substituted or unsubstituted C₇-C₃₀ arylalkyl group, a substituted or unsubstituted C₂-C₃₀ heteroaryl group, or a substituted or unsubstituted C₃-C₃₀ heteroarylalkyl group. Two or more adjacent groups selected from among the above-mentioned groups (e.g., R^{d}(s)) may optionally be combined with each other to form a saturated ring or an unsaturated ring.

m1 may be an integer of 0 to 5, m2 may be an integer of 0 to 4, and m3 may be an integer of 0 to 3. *- represents a bonding position.

In one or more embodiments, R₁₇ and R₁₉ may each independently be hydrogen, deuterium, —CD₃, —CD₂H, or —CDH₂. R₁₈ may be selected from among hydrogen, deuterium, —CD₃, —CD₂H, —CDH₂, and groups represented by Chemical Formulae 6-1 to 6-3. Accordingly, exciton quenching due to interaction with the polycyclic compound and the surrounding compounds/molecules may be further suppressed or reduced.

In one or more embodiments, the polycyclic compound may be any one selected from among the following compounds 1 to 120.

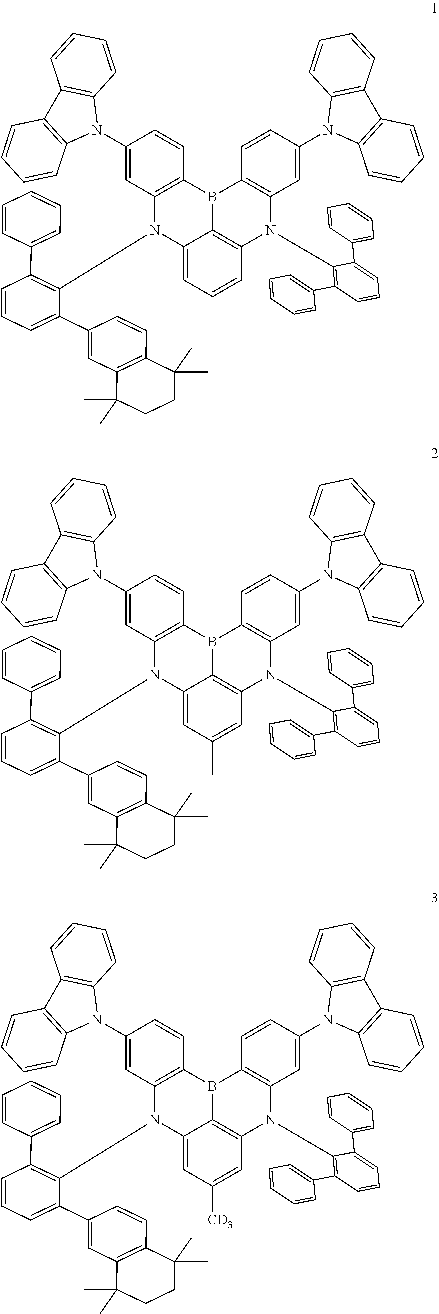 [SMILES: CC1(C)CCC(C)(C)c2cc(-c3cccc(-c4ccccc4)c3N3c4cc(-n5c6ccccc6c6ccccc65)ccc4B4c5ccc(-n6c7ccccc7c7ccccc76)cc5N(c5c(-c6ccccc6)cccc5-c5ccccc5)c5cccc3c54)ccc21 ; Cc1cc2c3c(c1)N(c1c(-c4ccccc4)cccc1-c1ccc4c(c1)C(C)(C)CCC4(C)C)c1cc(-n4c5ccccc5c5ccccc54)ccc1B3c1ccc(-n3c4ccccc4c4ccccc43)cc1N2c1c(-c2ccccc2)cccc1-c1ccccc1 ; [2H]C([2H])([2H])c1cc2c3c(c1)N(c1c(-c4ccccc4)cccc1-c1ccc4c(c1)C(C)(C)CCC4(C)C)c1cc(-n4c5ccccc5c5ccccc54)ccc1B3c1ccc(-n3c4ccccc4c4ccccc43)cc1N2c1c(-c2ccccc2)cccc1-c1ccccc1]

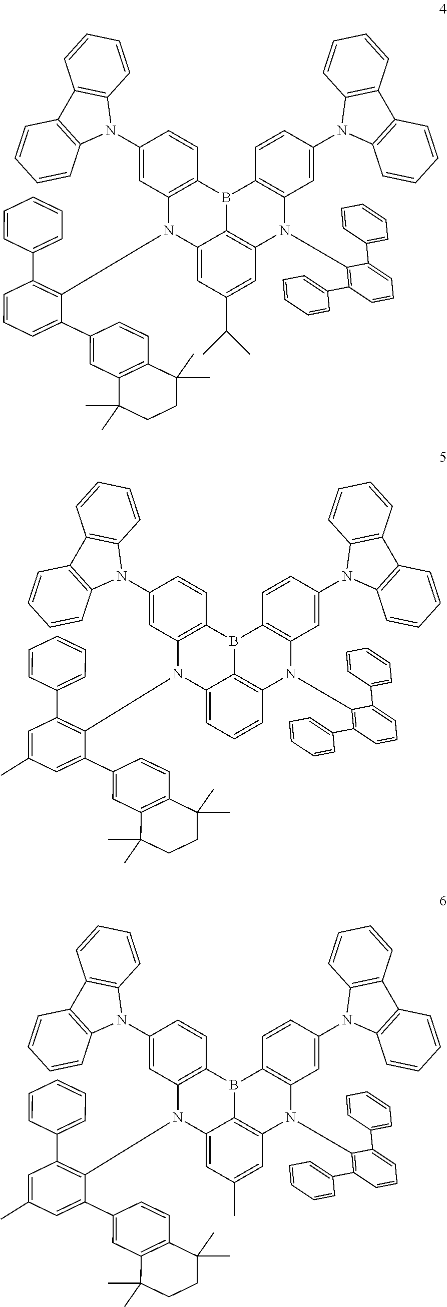 [SMILES: CC(C)c1cc2c3c(c1)N(c1c(-c4ccccc4)cccc1-c1ccc4c(c1)C(C)(C)CCC4(C)C)c1cc(-n4c5ccccc5c5ccccc54)ccc1B3c1ccc(-n3c4ccccc4c4ccccc43)cc1N2c1c(-c2ccccc2)cccc1-c1ccccc1 ; Cc1cc(-c2ccccc2)c(N2c3cc(-n4c5ccccc5c5ccccc54)ccc3B3c4ccc(-n5c6ccccc6c6ccccc65)cc4N(c4c(-c5ccccc5)cccc4-c4ccccc4)c4cccc2c43)c(-c2ccc3c(c2)C(C)(C)CCC3(C)C)c1 ; Cc1cc(-c2ccccc2)c(N2c3cc(-n4c5ccccc5c5ccccc54)ccc3B3c4ccc(-n5c6ccccc6c6ccccc65)cc4N(c4c(-c5ccccc5)cccc4-c4ccccc4)c4cc(C)cc2c43)c(-c2ccc3c(c2)C(C)(C)CCC3(C)C)c1]

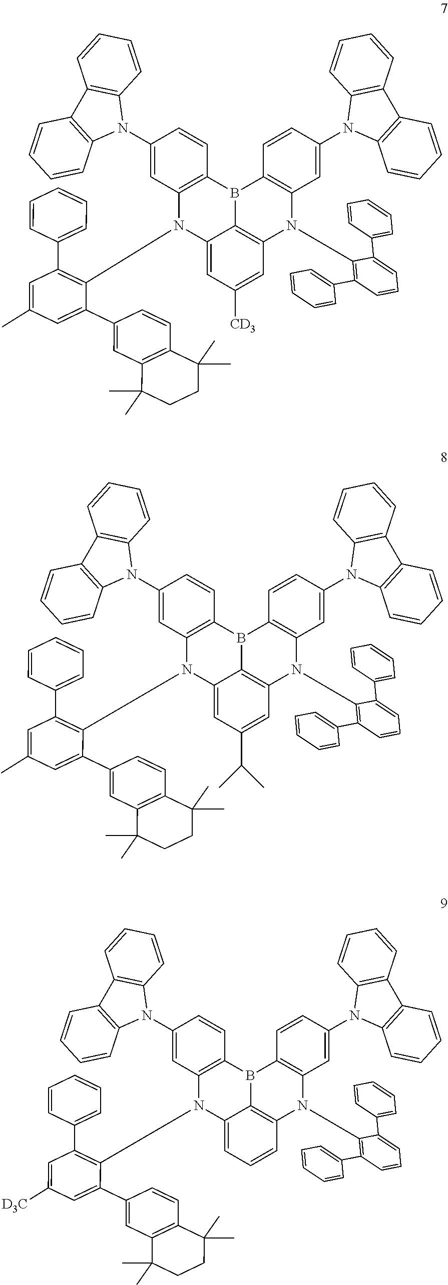

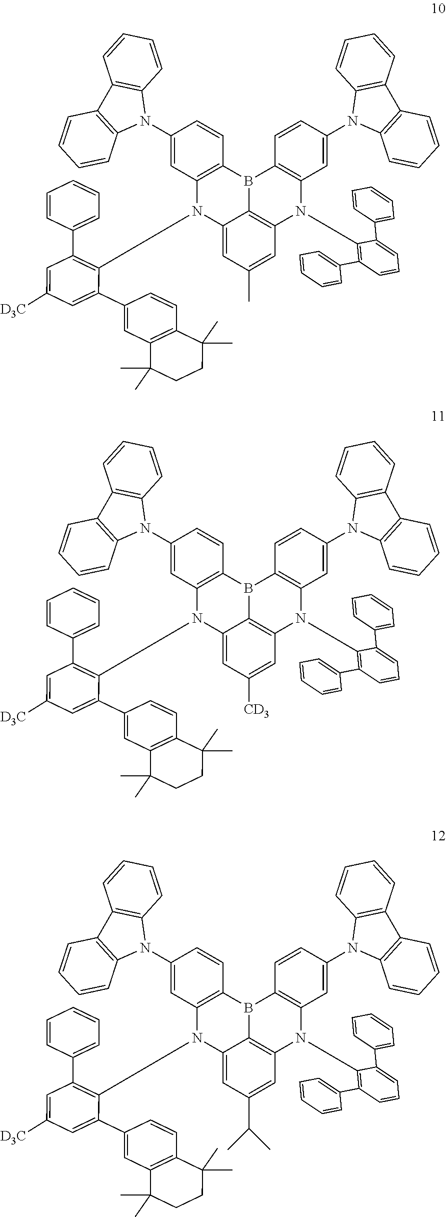

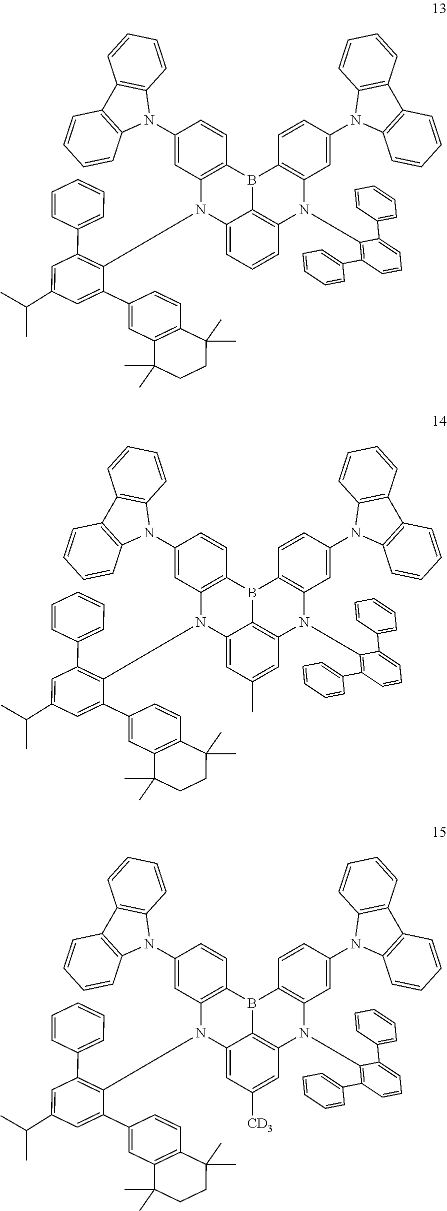

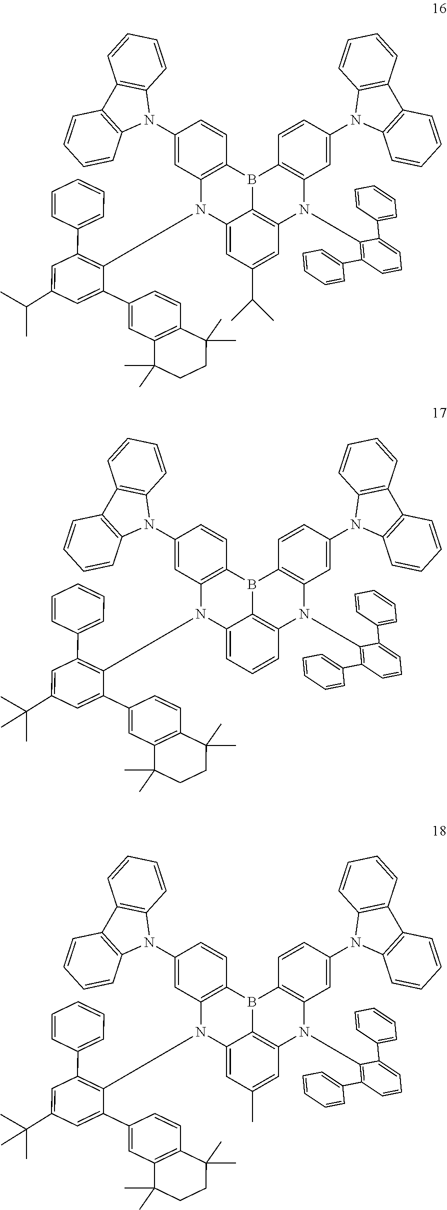 [SMILES: CC(C)c1cc(-c2ccccc2)c(N2c3cc(-n4c5ccccc5c5ccccc54)ccc3B3c4ccc(-n5c6ccccc6c6ccccc65)cc4N(c4c(-c5ccccc5)cccc4-c4ccccc4)c4cc(C(C)C)cc2c43)c(-c2ccc3c(c2)C(C)(C)CCC3(C)C)c1 ; CC(C)(C)c1cc(-c2ccccc2)c(N2c3cc(-n4c5ccccc5c5ccccc54)ccc3B3c4ccc(-n5c6ccccc6c6ccccc65)cc4N(c4c(-c5ccccc5)cccc4-c4ccccc4)c4cccc2c43)c(-c2ccc3c(c2)C(C)(C)CCC3(C)C)c1 ; Cc1cc2c3c(c1)N(c1c(-c4ccccc4)cc(C(C)(C)C)cc1-c1ccc4c(c1)C(C)(C)CCC4(C)C)c1cc(-n4c5ccccc5c5ccccc54)ccc1B3c1ccc(-n3c4ccccc4c4ccccc43)cc1N2c1c(-c2ccccc2)cccc1-c1ccccc1]

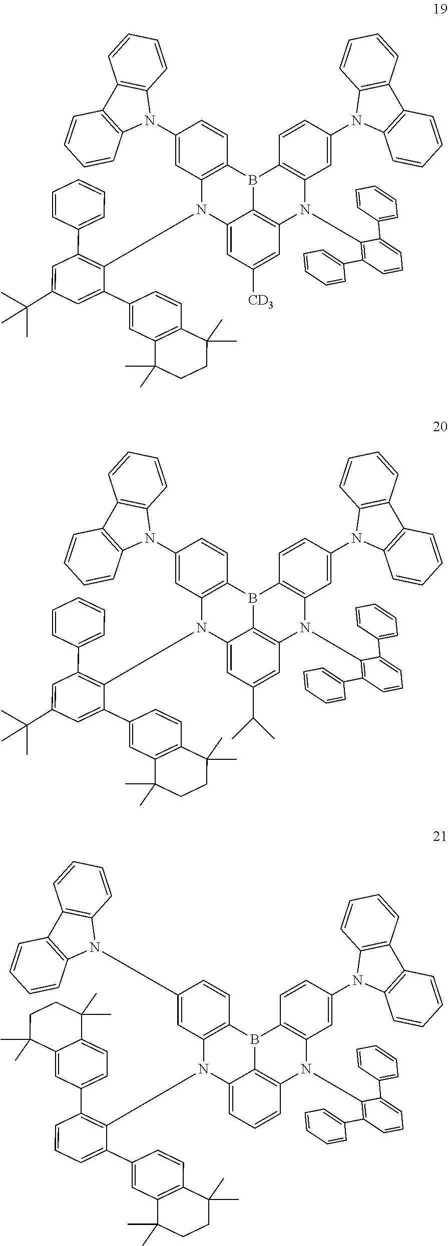

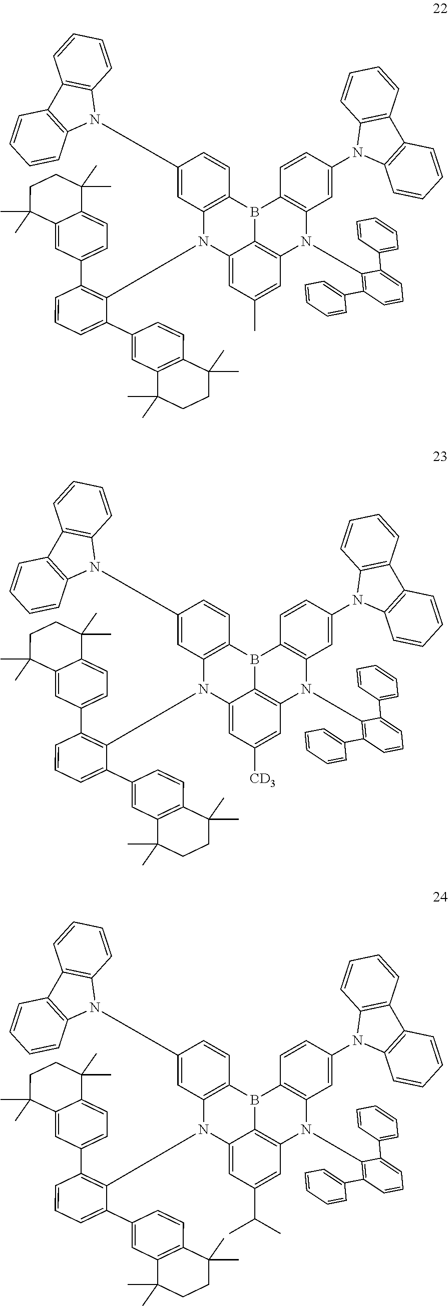

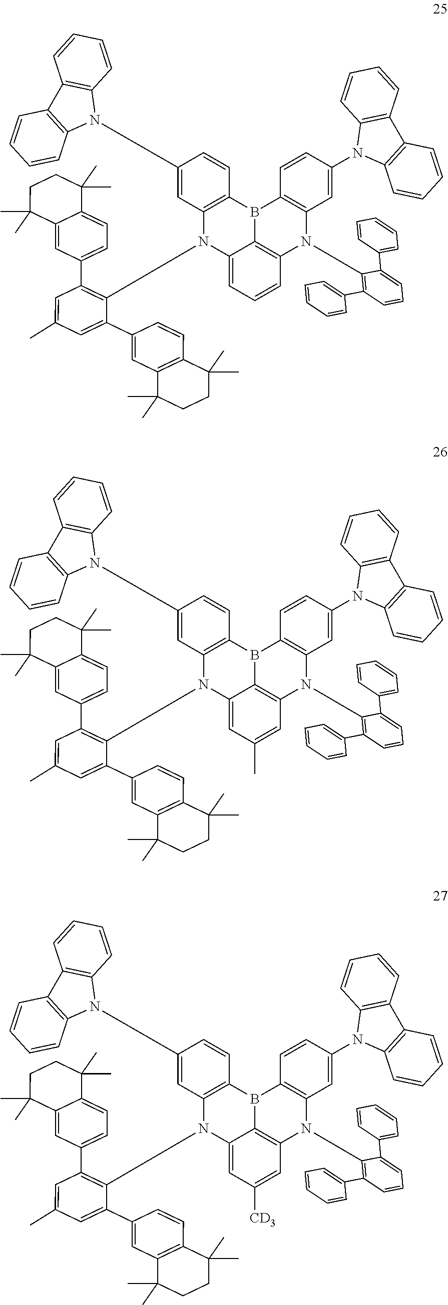

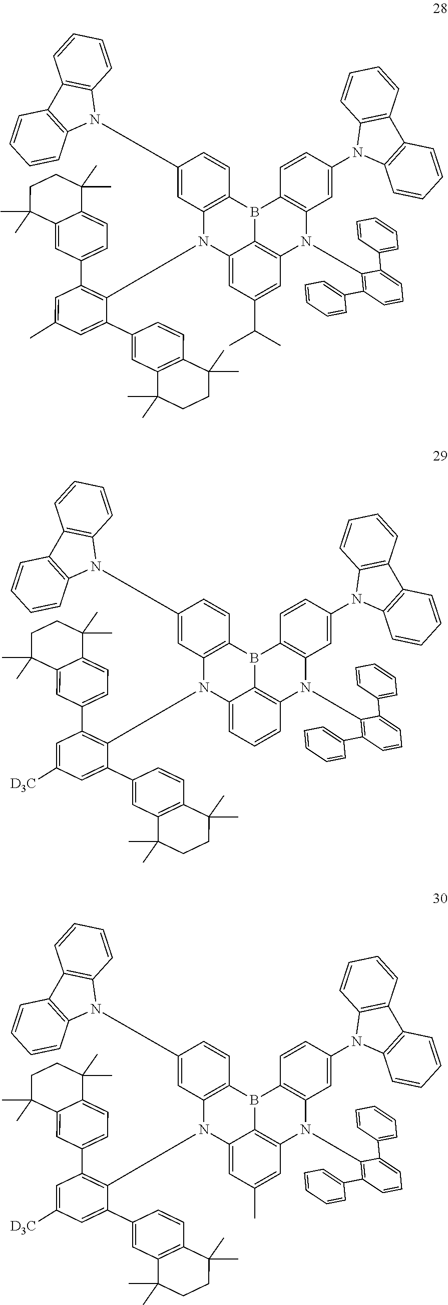

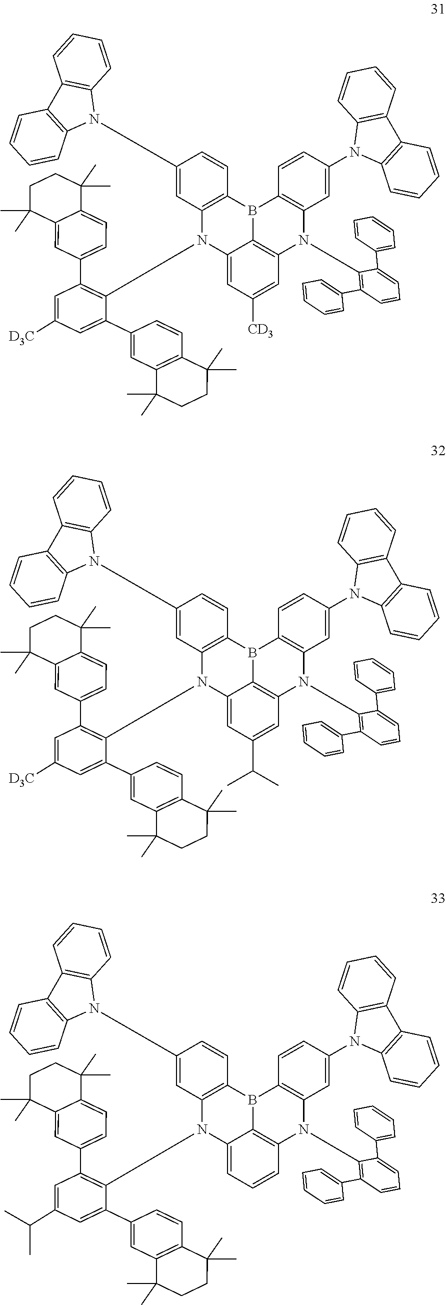

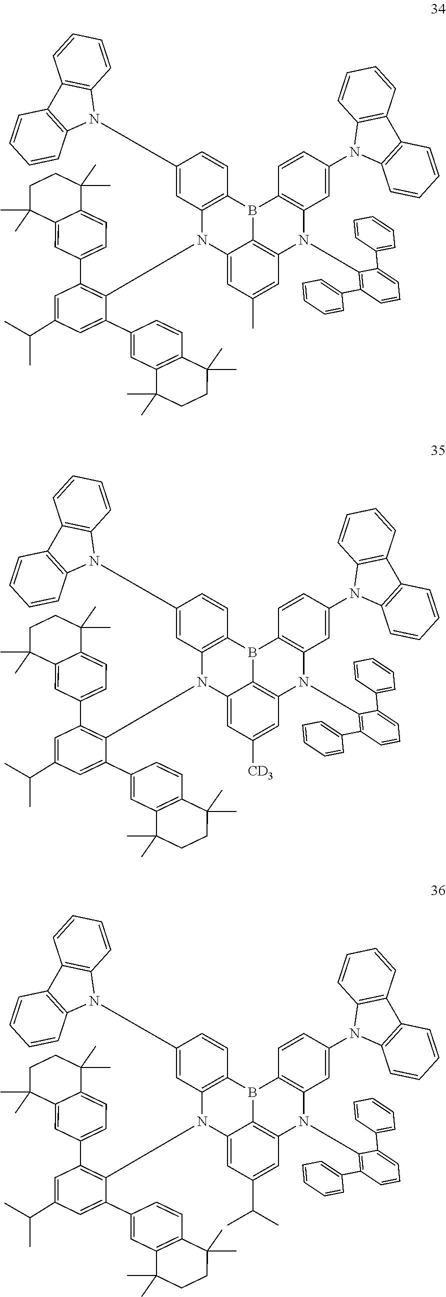

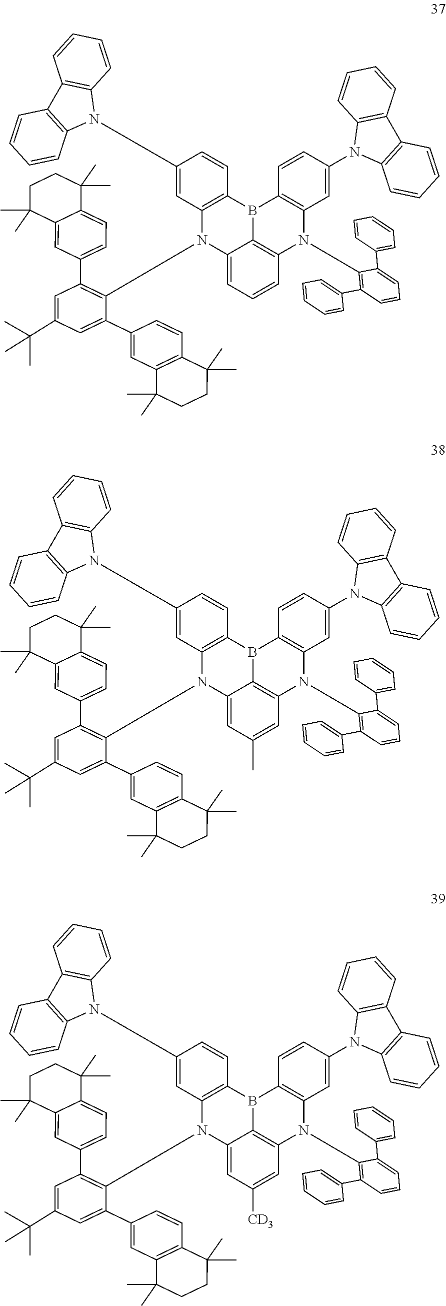

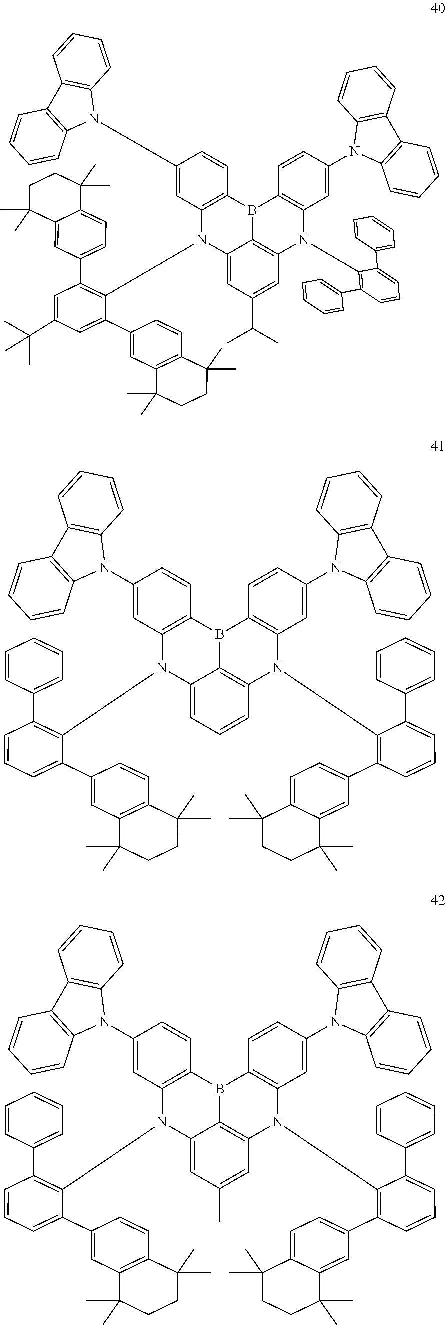

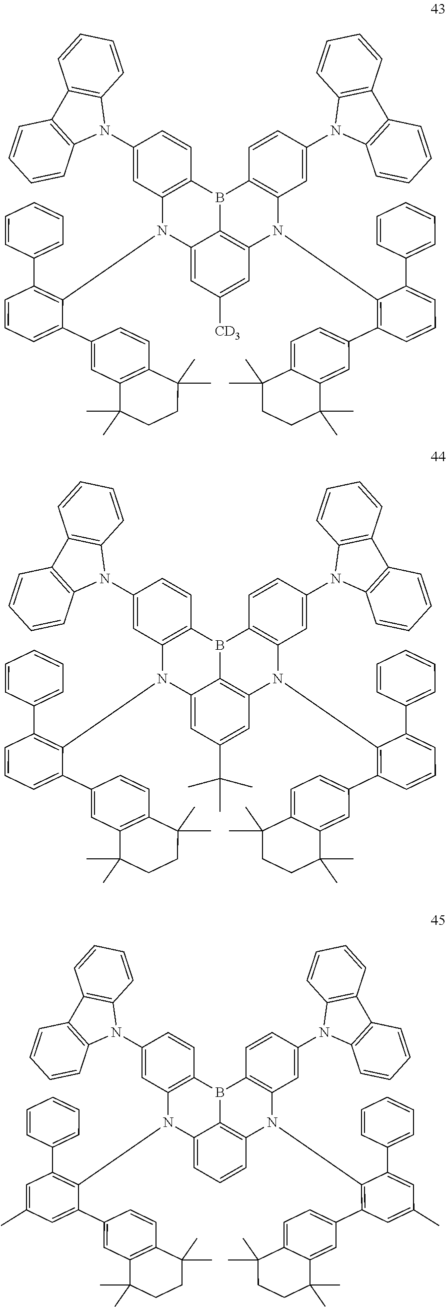

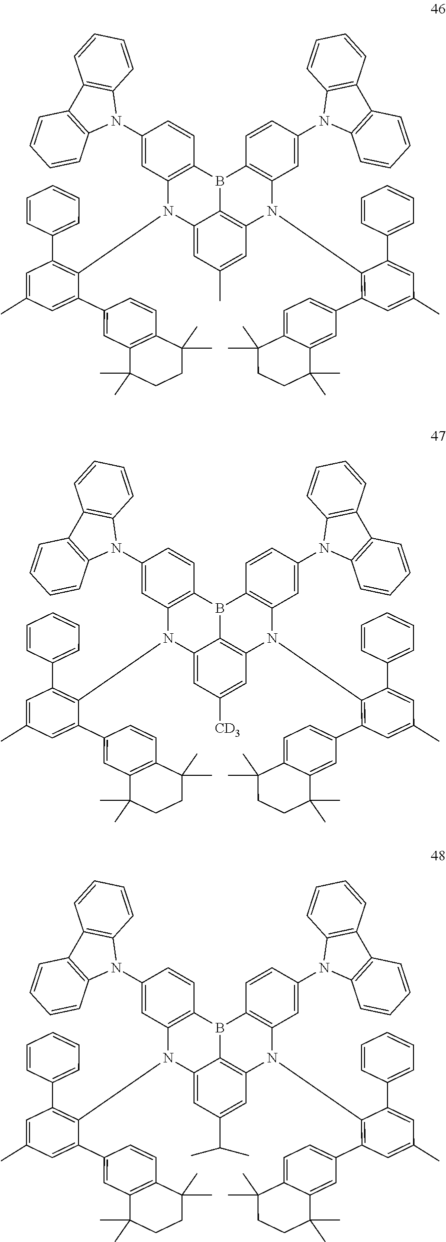

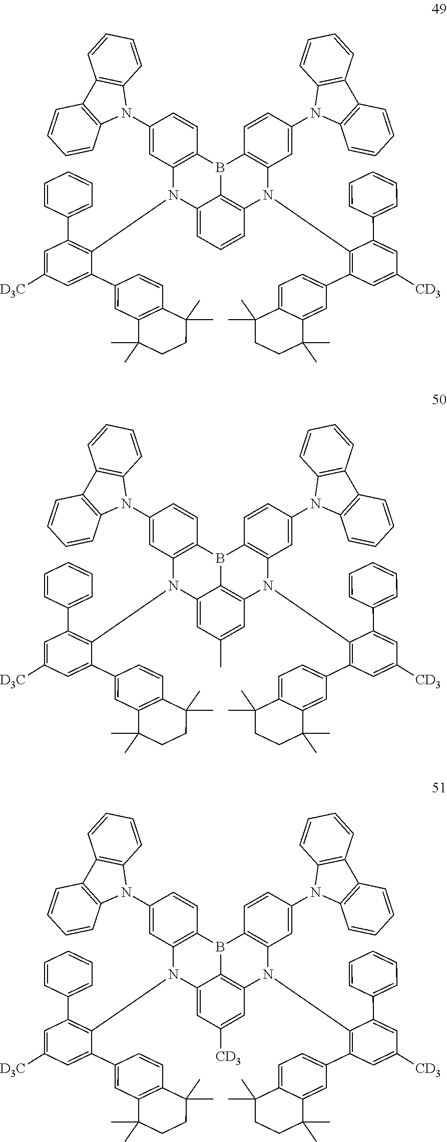

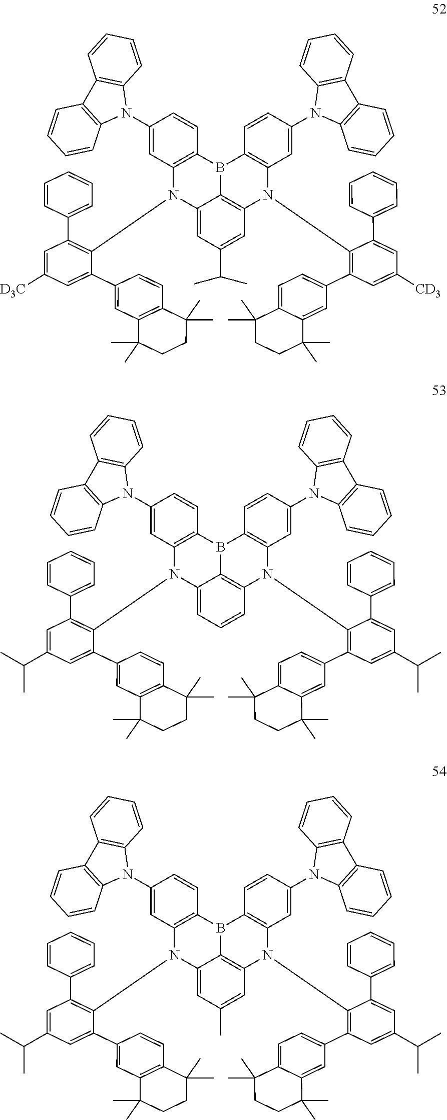

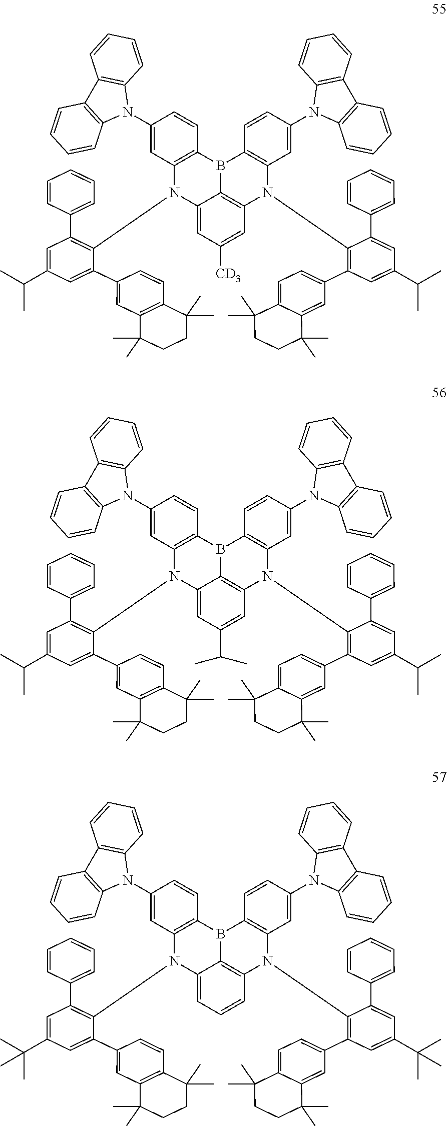

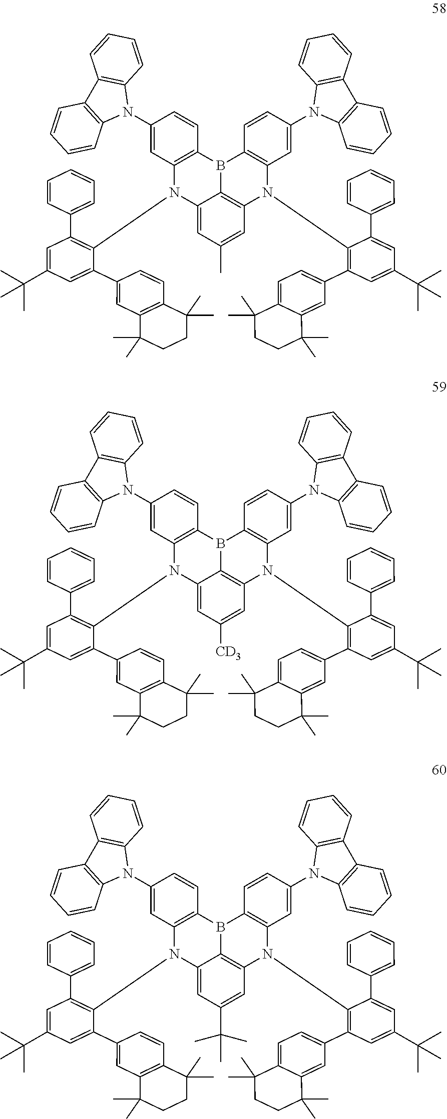

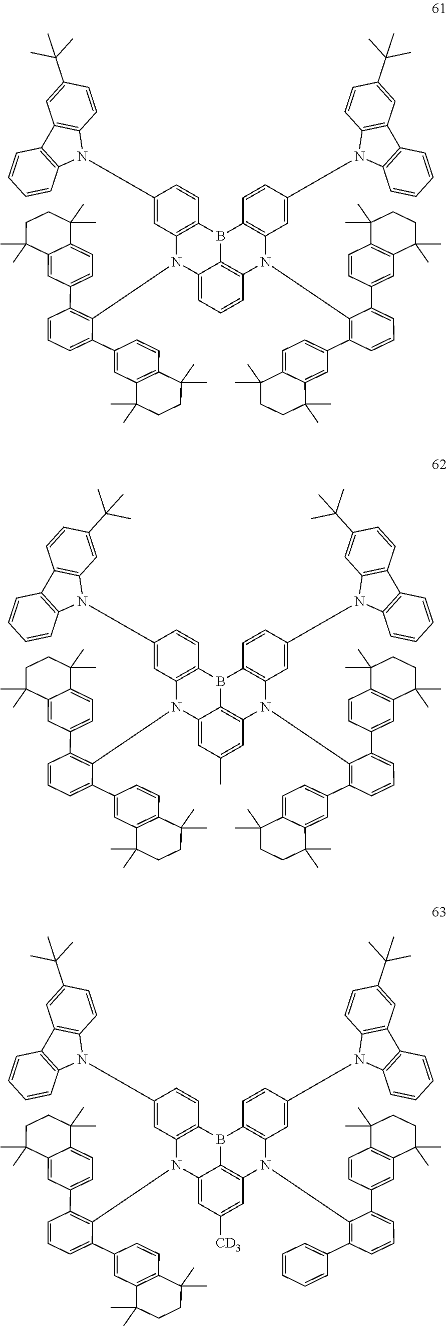

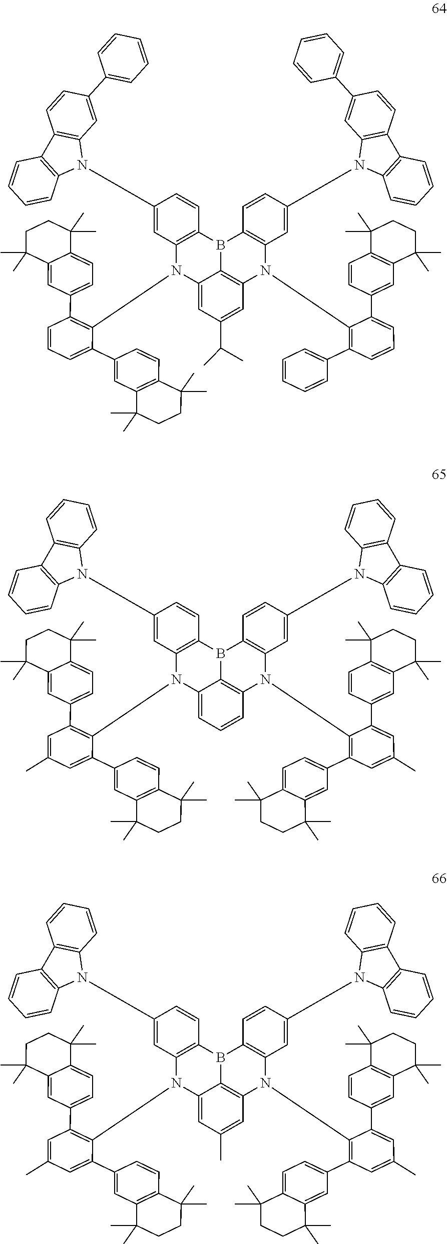

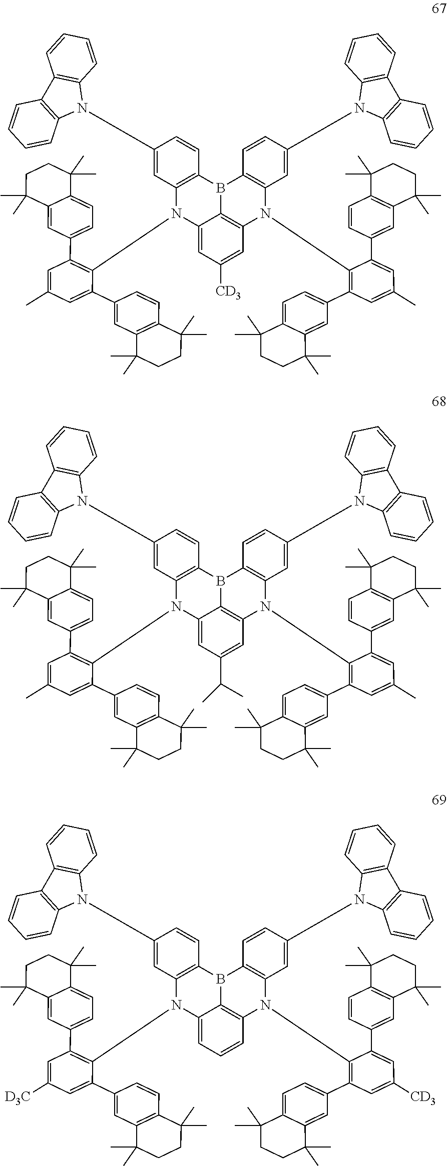

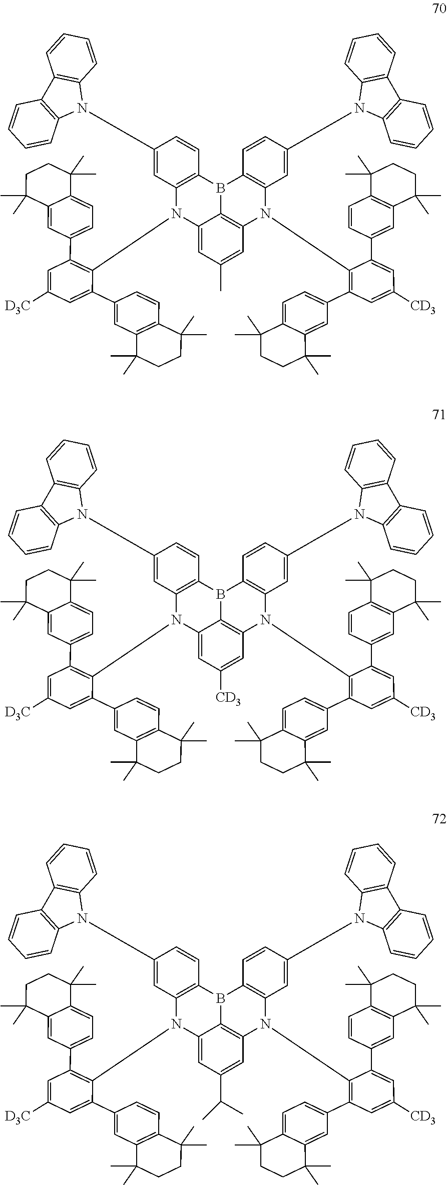

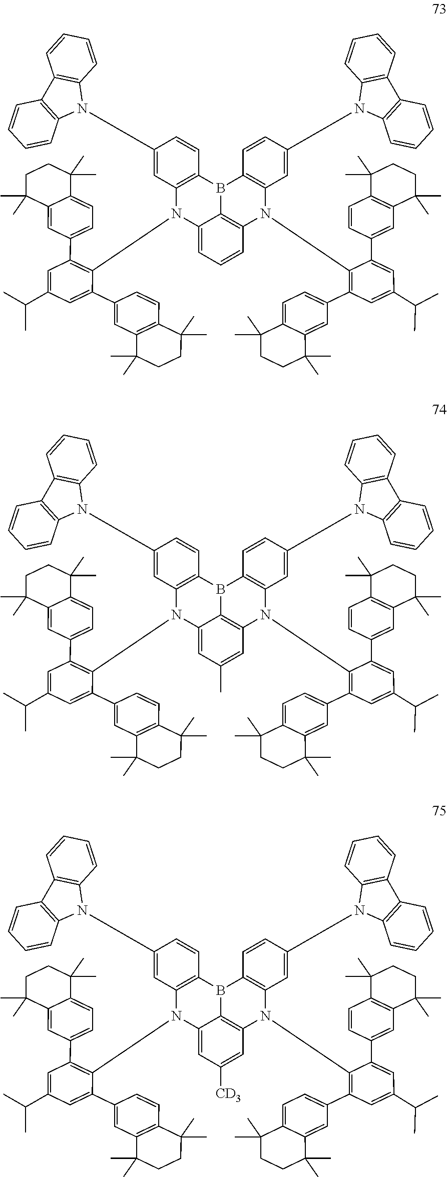

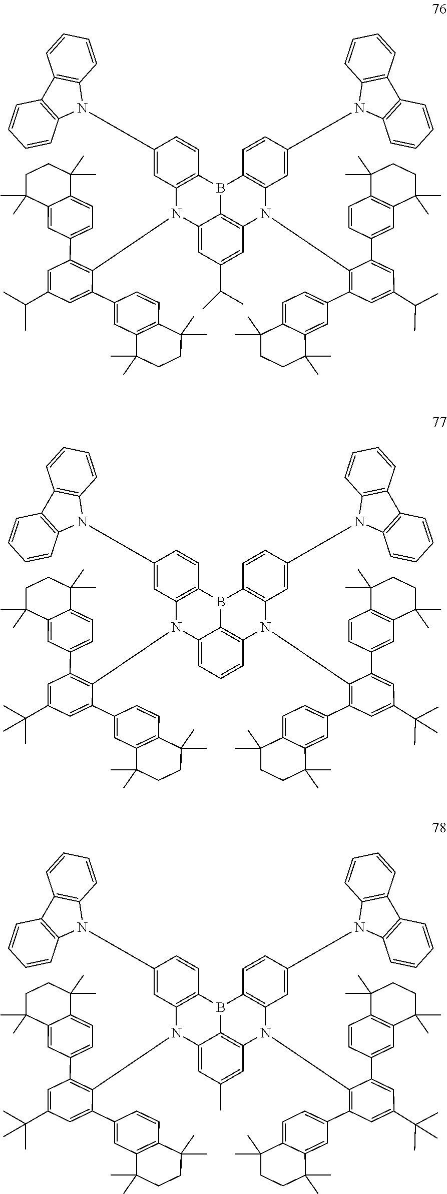

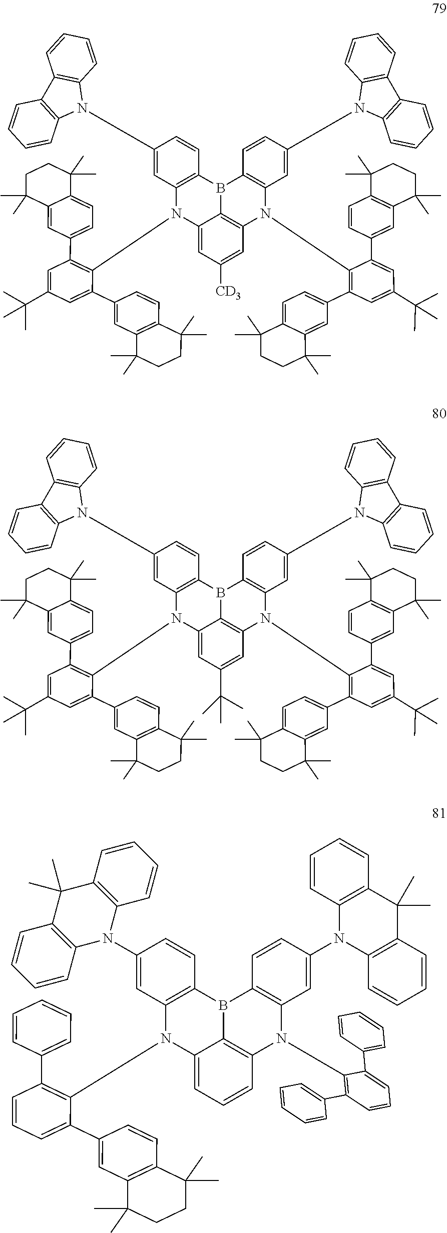

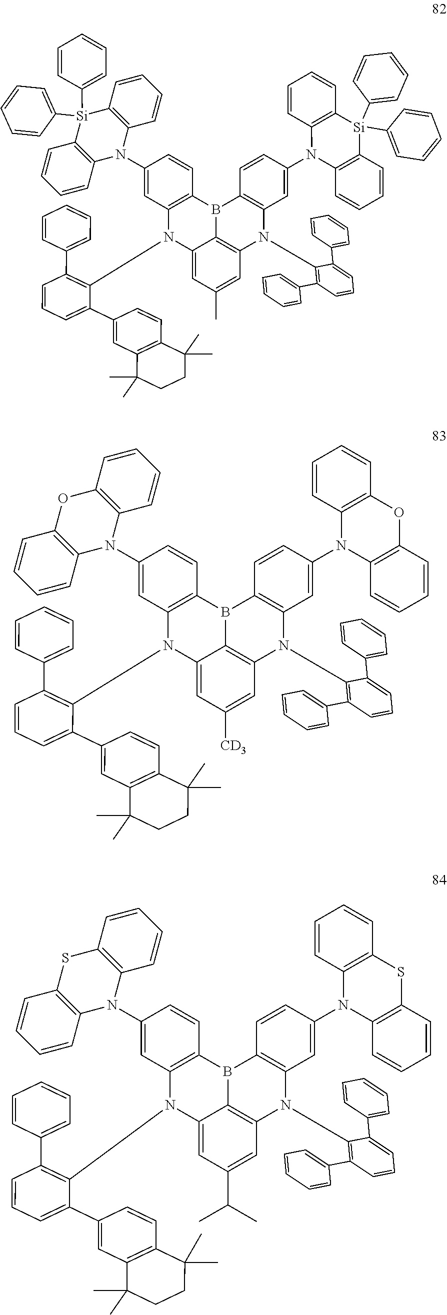

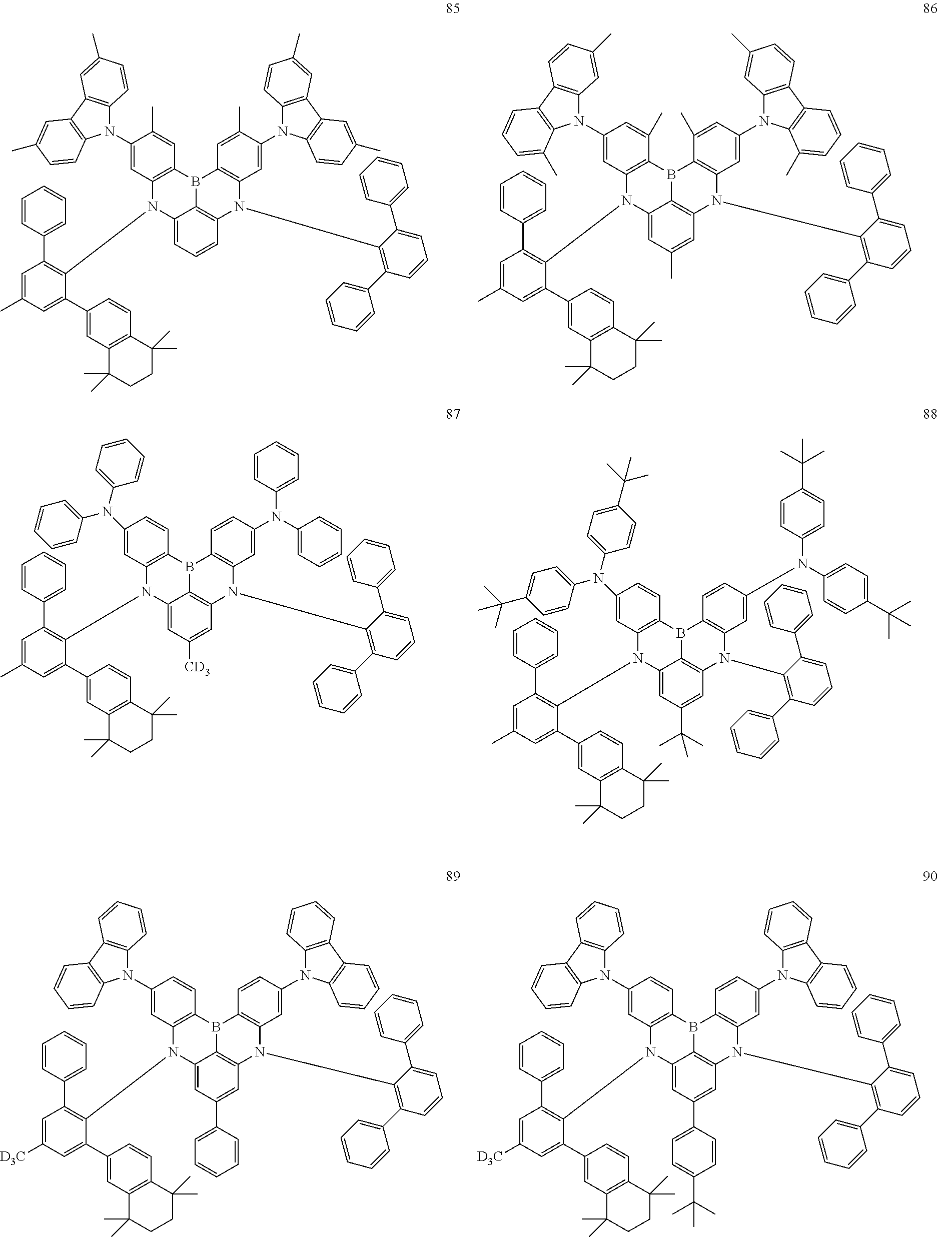

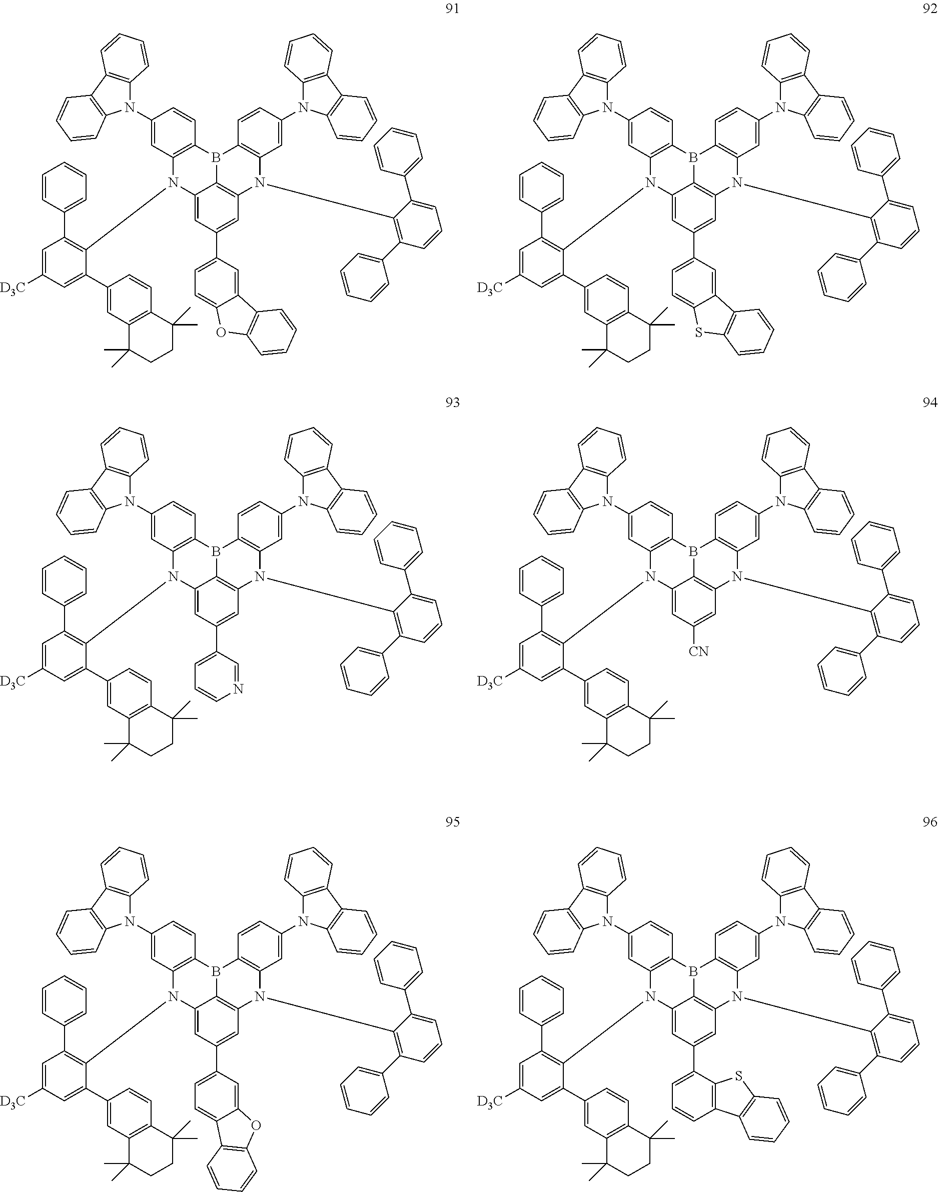

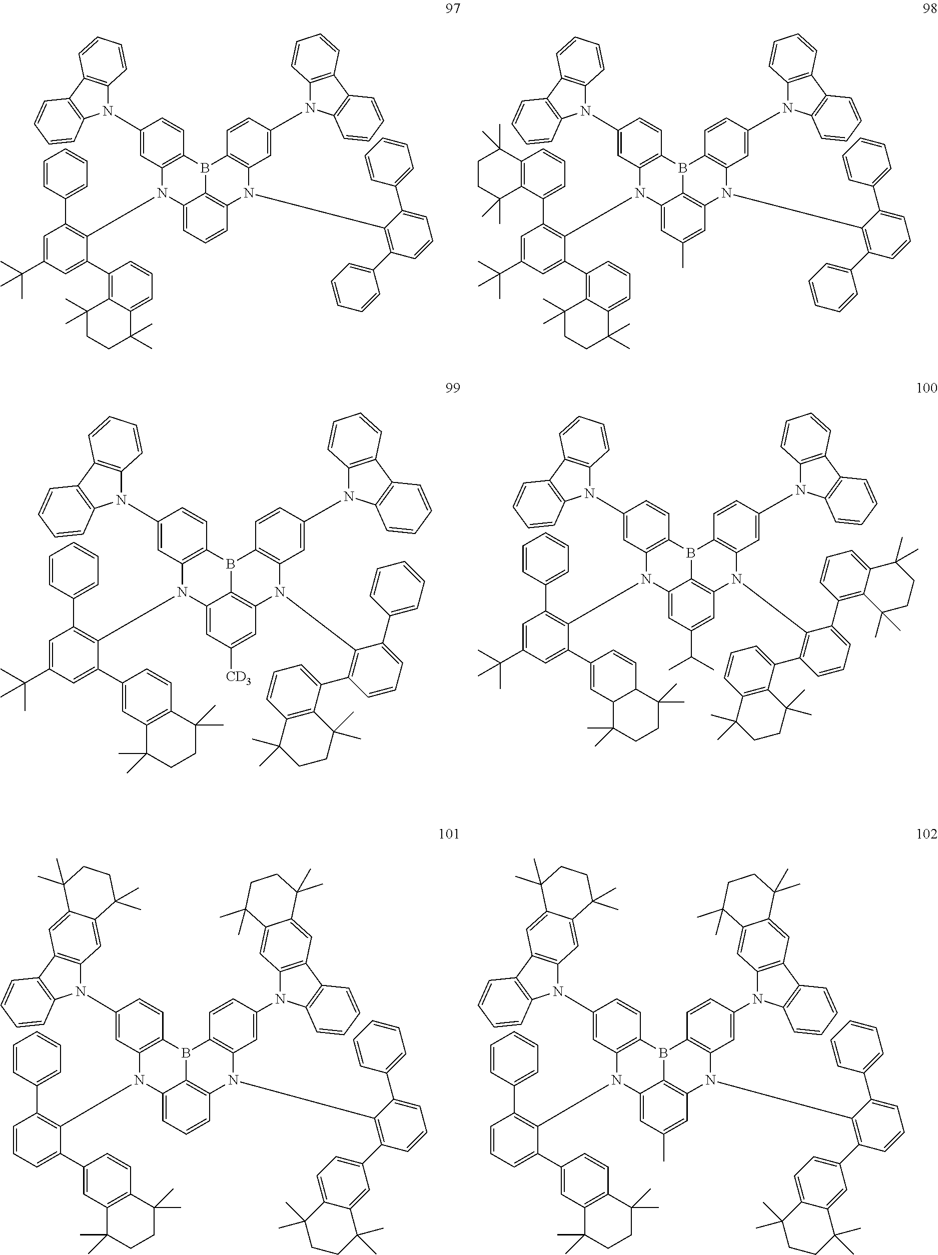

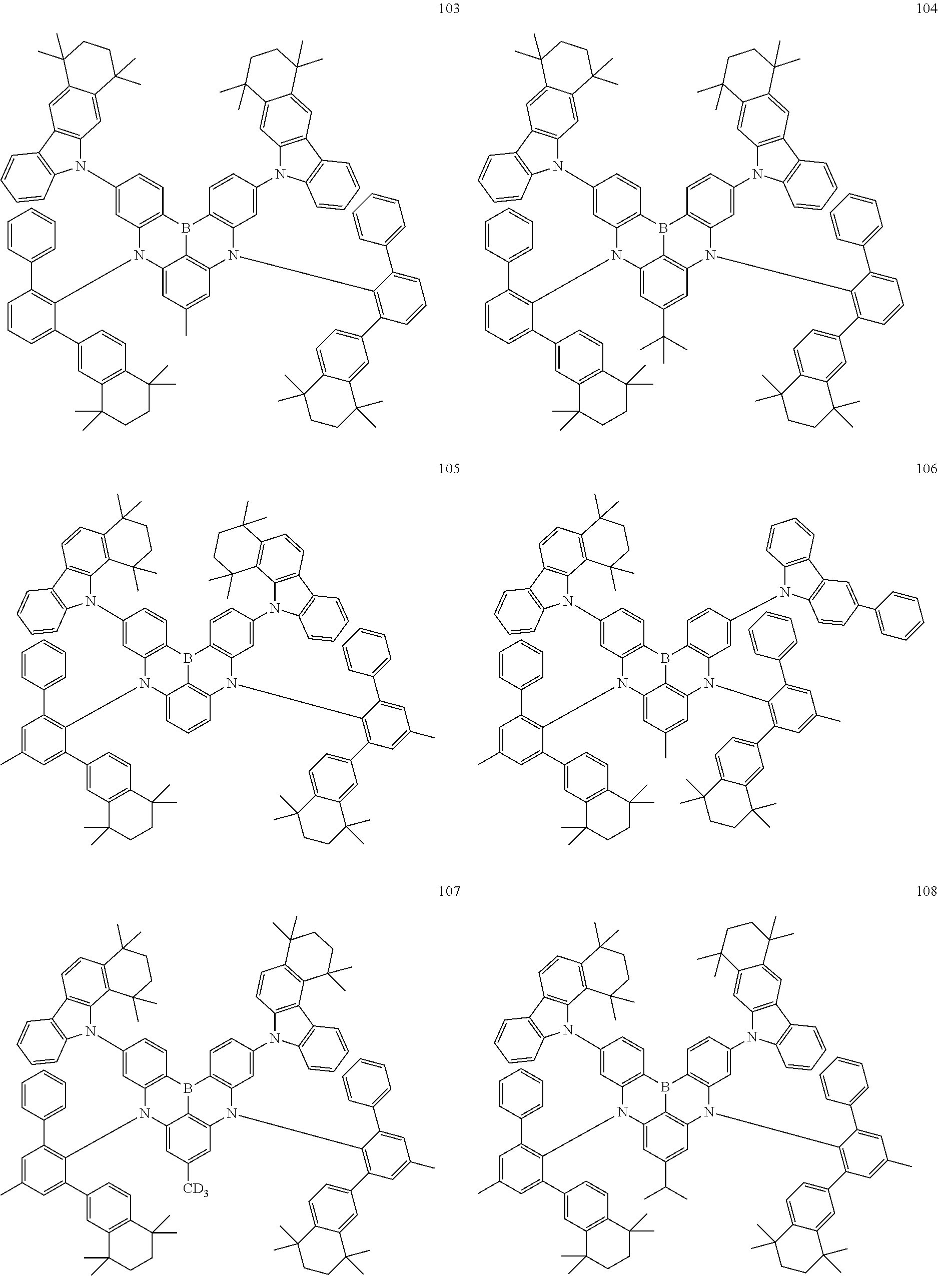

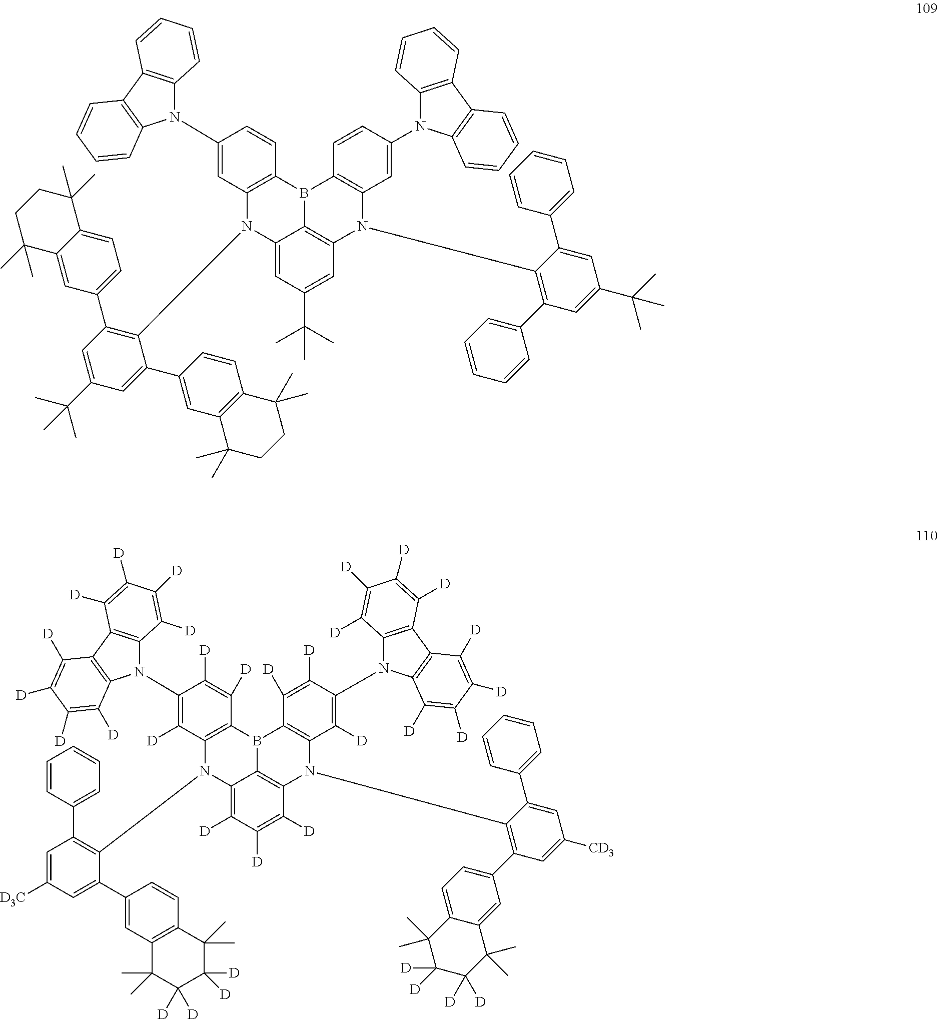

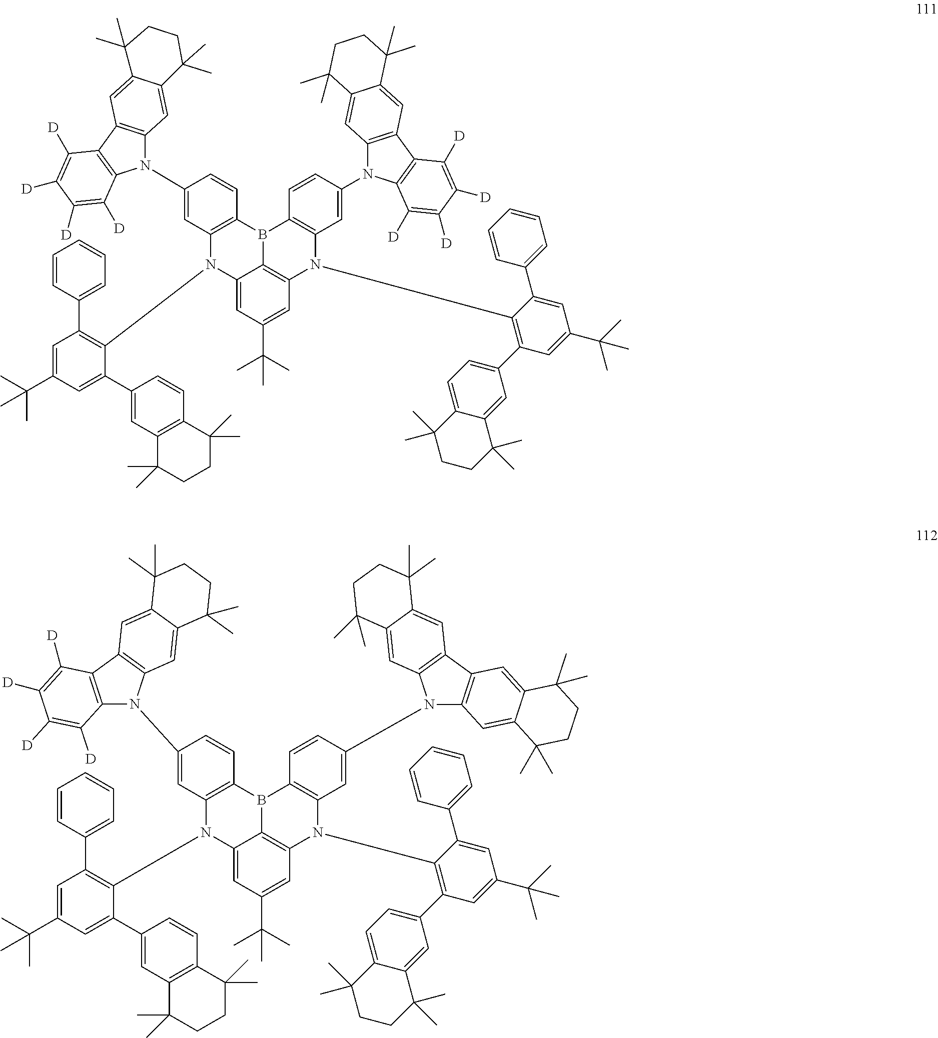

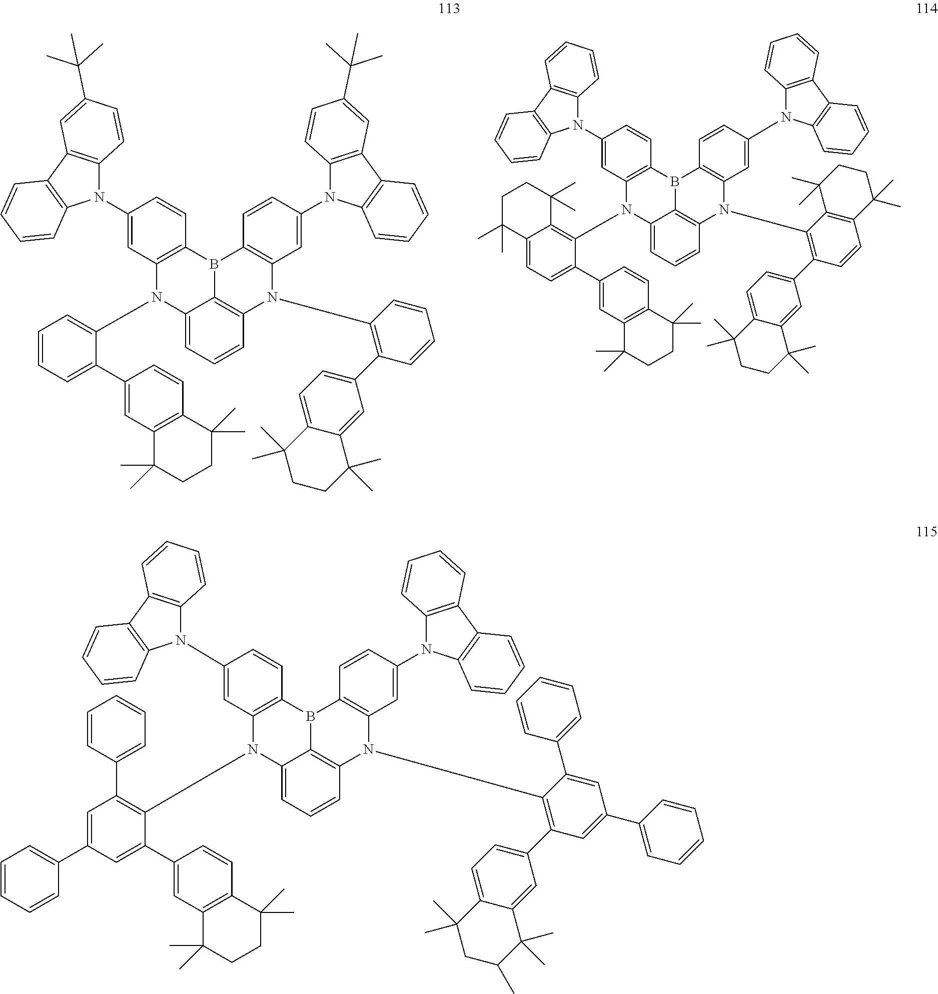

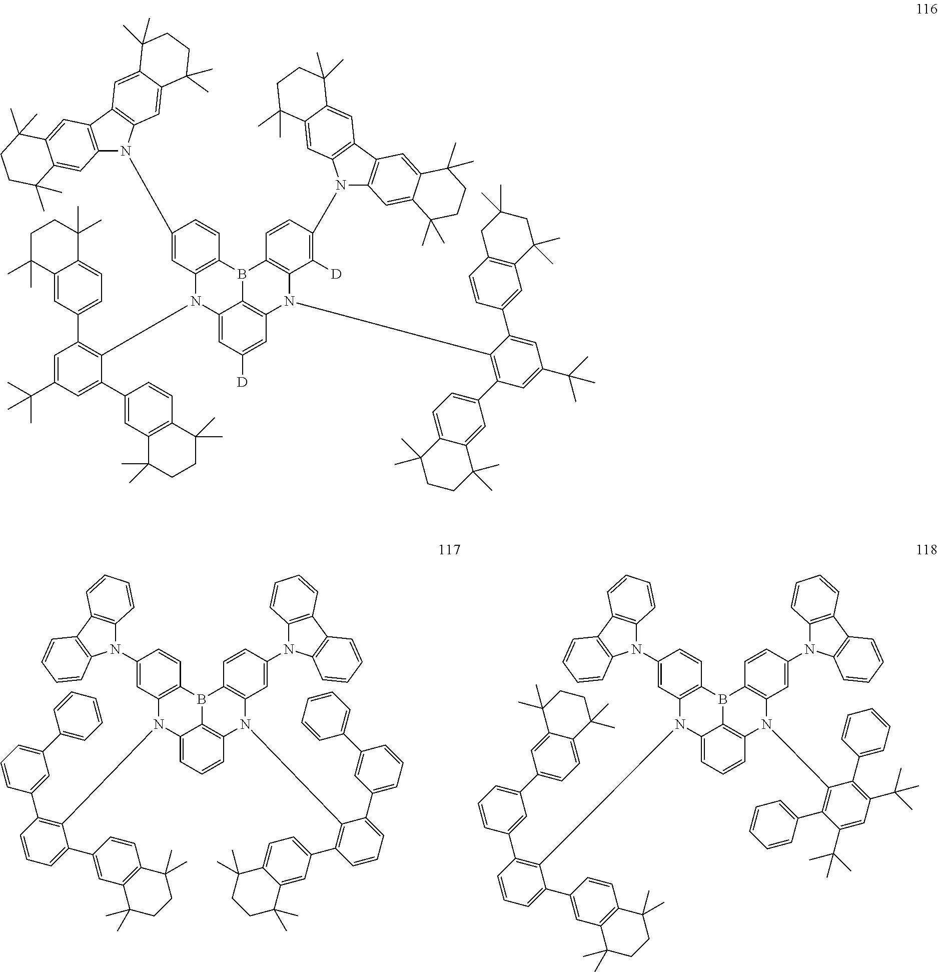

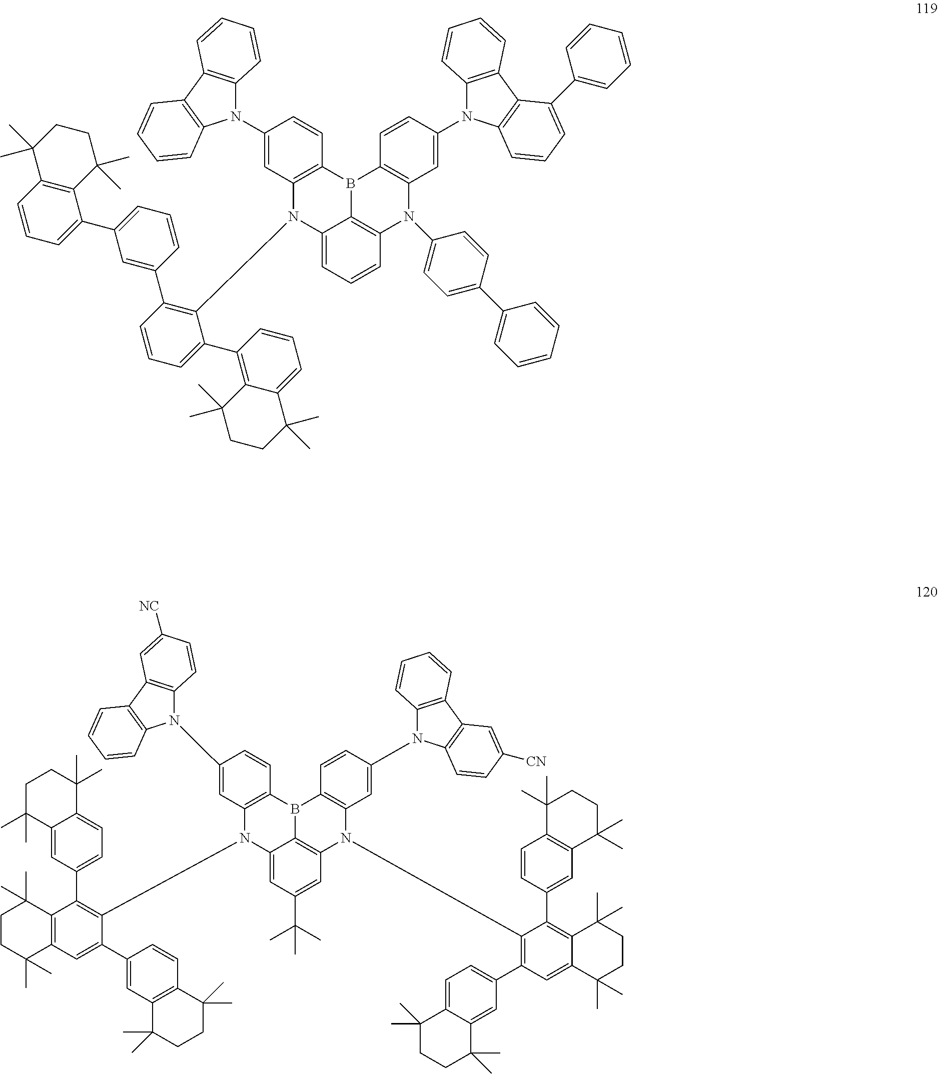 [SMILES: CC1(C)CCC(C)(C)c2c(-c3cccc(-c4cccc(-c5cccc6c5C(C)(C)CCC6(C)C)c4N4c5cc(-n6c7ccccc7c7ccccc76)ccc5B5c6ccc(-n7c8ccccc8c8c(-c9ccccc9)cccc87)cc6N(c6ccc(-c7ccccc7)cc6)c6cccc4c65)c3)cccc21 ; CC(C)(C)c1cc2c3c(c1)N(c1c(-c4ccc5c(c4)C(C)(C)CCC5(C)C)cc4c(c1-c1ccc5c(c1)C(C)(C)CCC5(C)C)C(C)(C)CCC4(C)C)c1cc(-n4c5ccccc5c5cc(C#N)ccc54)ccc1B3c1ccc(-n3c4ccccc4c4cc(C#N)ccc43)cc1N2c1c(-c2ccc3c(c2)C(C)(C)CCC3(C)C)cc2c(c1-c1ccc3c(c1)C(C)(C)CCC3(C)C)C(C)(C)CCC2(C)C]

In one or more embodiments, an absolute value (ΔEst) of a difference between an energy level of the lowest singlet excited state (S1 level) and an energy level of the lowest triplet excited state (T1 level) of the polycyclic compound may be 0.39 eV or less. For example, ΔEst may be, e.g., 0.39 eV or less, 0.38 eV or less, or 0.37 eV or less.

In one or more embodiments, a reverse intersystem crossing constant (k_{RISC}) of the polycyclic compound may be about 6.00×10⁴ s⁻¹ or more. For example, the k_{RISC} may be about 1.00×10⁵ s⁻¹ or more, about 2.0×10⁵ s⁻¹ or more, about 2.3×10⁵ s⁻¹ or more, or about 3.00×10⁵ s⁻¹ or more.

For example, k_{RISC} may be calculated based on a photoluminescence quantum yield of a prompt light-emitting component measured by a transient electroluminescence spectroscopy, a life-span of the prompt light-emitting component, a life-span of a delayed light-emitting component, and a radial decay rate constant from S1 to S0.

In one or more embodiments, an oscillator strength (f) of the polycyclic compound may be 0.36 or more. In one or more embodiments, the oscillator strength (f) may be, for example, 0.36 or more, 0.39 or more, or 0.40 or more.

The oscillator strength (f) may be calculated based on, e.g., an empirical molecular orbital method, and may be calculated using, e.g., Gaussian's Gaussian 09 program.

According to one or more embodiments, the polycyclic compound may be provided as a thermally activated delayed fluorescence (TADF) dopant, a host for a phosphorescent light-emitting device (e.g., for a phosphorescent dopant), or a fluorescent host.

The polycyclic compound may further improve luminous and life-span properties of the light-emitting device.

The polycyclic compound may have a narrow full width at half maximum by enhanced multi-resonance effect.

According to one or more embodiments, the polycyclic compound may be used as a blue light-emitting dopant.

In one or more embodiments, a maximum emission wavelength (i.e., wavelength at a maximum peak intensity) of the blue light may be, e.g., in a range from about 430 nm to about 490 nm, from about 440 nm to about 480 nm, from about 440 nm to about 465 nm, or from about 445 nm to about 456 nm.

In one or more embodiments, an emission half width (full width at half maximum) of the blue light may be about 30 nm or less, about 28 nm or less, about 25 nm or less, from about 10 nm to about 30 nm, or from about 10 nm to about 28 nm.

### Light-Emitting Device

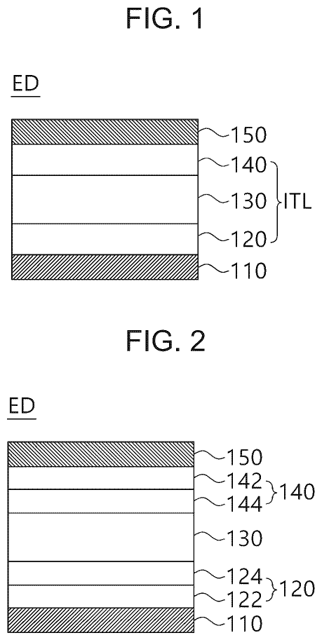

FIGS. 1 to 6 are each a schematic cross-sectional view illustrating a light-emitting device in accordance with one or more embodiments of the present disclosure.

Referring to FIG. 1, a light-emitting device ED may include a first electrode 110, a second electrode 150, and an emission layer 130 interposed between the first electrode 110 and the second electrode 150. The emission layer 130 may include at least one polycyclic compound represented by Chemical Formula 1 described above.

Accordingly, the light-emitting device may have improved color properties, luminous efficiency, and life-span properties.

The light-emitting device ED may include an intermediate layer ITL including the emission layer 130 arranged between the first electrode 110 and the second electrode 150. The intermediate layer ITL may further include a hole transfer region 120 and an electron transfer region 140.

In one or more embodiments, a plurality of the emission layers may be arranged between the first electrode 110 and the second electrode 150, and a charge generation layer may be arranged between adjacent emission layers. At least one selected from among the emission layers may include the polycyclic compound of Chemical Formula 1 described above.

In one or more embodiments, the light-emitting device ED may include two or more light-emitting structures, each of which may include the emission layer, between the first electrode 110 and the second electrode 150. The light-emitting structure may include, e.g., a stacked structure of the hole transfer region 120, the emission layer 130, and the electron transfer region 140. The charge generation layer may include, e.g., a p-type (kind) charge generation layer and/or an n-type (kind) charge generation layer.

In one or more embodiments, the light-emitting device ED may be alight-emitting device of a tandem structure which may include m light-emitting structures (m is an integer of 2 or greater) between the first electrode 110 and the second electrode 150, and (m−1) charge generation layers respectively arranged between adjacent light-emitting structures.

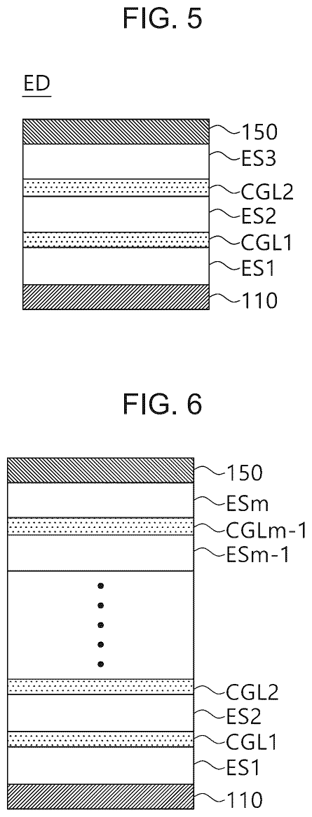

In FIG. 5, a 3-stack tandem structure including three light-emitting structures is provided, but the light-emitting device ED may have a tandem structure of a 2-stack, 4-stack, 5-stack, or more.

In one or more embodiments, the polycyclic compound may be provided as a thermally activated delayed fluorescence (TADF) dopant, a host for a phosphorescent device (e.g., for a phosphorescent dopant), or a fluorescent host.

The plurality of emission layers may include the polycyclic compound, and the polycyclic compound may serve as the TADF dopant. The plurality of emission layers may include at least one polycyclic compound represented by Chemical Formula 1.

Accordingly, color properties, luminous efficiency and life-span properties of the light-emitting device ED may be further improved.

The first electrode 110 may be an anode or a cathode. In one or more embodiments, the first electrode 110 may be an anode, and may serve as a pixel electrode. In these embodiments, the first electrode 110 may include a conductive material with a high work function that promotes hole injection.

In one or more embodiments, the first electrode 110 may be a transmissive electrode. The first electrode 110 may include a transparent conductive oxide such as indium tin oxide (ITO), indium zinc oxide (IZO), zinc oxide (ZnO), indium tin oxide (ITZO), and/or the like.

In one or more embodiments, the first electrode 110 may be a translucent electrode or a reflective electrode. The first electrode 110 may include at least one selected from among silver (Ag), magnesium (Mg), copper (Cu), aluminum (AI), platinum (Pt), palladium (Pd), gold (Au), nickel (Ni), neodymium (Nd), iridium (Ir), chromium (Cr), lithium (Li), calcium (Ca), lithium fluoride (LiF), molybdenum (Mo), titanium (Ti), tungsten (W), indium (In), tin (Sn), zinc (Zn), and an alloy containing at least two selected therefrom. For example, in one or more embodiments, the first electrode 110 may include Li, Ca, LiF/Ca (a stacked structure of LiF and Ca), LiF/Al (a stacked structure of LiF and Al), a mixture of Ag and Mg, and/or the like.

The first electrode 110 may have a single-layered structure or a multi-layered structure. For example, in one or more embodiments, the first electrode 110 may have a triple-layered structure of ITO/Ag/ITO.

A thickness of the first electrode 110 may be in a range of about 700 Angstroms (Å) to about 10,000 Å. For example, in one or more embodiments, the thickness of the first electrode 110 may be in a range of about 1,000 Å to about 3,000 Å.

The second electrode 150 may be a cathode or an anode. In one or more embodiments, the second electrode 150 may serve as an electron injection electrode or as a cathode. The second electrode 150 may include a metal, an alloy, an electrically conductive compound, and/or the like, having a low work function.

For example, in one or more embodiments, the second electrode 150 may include lithium (Li), silver (Ag), magnesium (Mg), aluminum (AI), aluminum-lithium (Al—Li), calcium (Ca), magnesium-indium (Mg—In), magnesium-silver (Mg—Ag), ytterbium (Yb), silver-ytterbium (Ag—Yb), ITO, IZO, and/or the like. The second electrode 150 may include one of the aforementioned materials, or a combination thereof.

The second electrode 150 may be a transmissive electrode, a translucent electrode, or a reflective electrode. The second electrode 150 may have a single-layered structure or a multi-layered structure.

The emission layer 130 may include a host and a dopant.

The emission layer 130 may include at least one polycyclic compound represented by Chemical Formula 1 described above.

In one or more embodiments, the emission layer 130 may include at least one polycyclic compound represented by Chemical Formula 1-1.

In one or more embodiments, the emission layer 130 may include at least one selected from among the above-described Compounds 1 to 120.

The emission layer 130 may include the above-described polycyclic compound as the dopant.

In a non-limiting example, the emission layer 130 may include the dopant in an amount of about 0.01 parts by weight to about 15.00 parts by weight, or about 0.01 parts by weight to about 12.00 parts by weight, based on 100 parts by weight of the host.

The emission layer 130 may be to emit a red light, a green light, a blue light, and/or a white light (e.g., combined white light). For example, in one or more embodiments, the emission layer 130 may be to emit a blue light.

In one or more embodiments, the emission layer 130 may be to emit a light having a maximum emission central wavelength in a range from about 430 nm to about 490 nm. The maximum emission central wavelength may be, e.g., in a range from about 430 nm to about 490 nm, about 440 nm to about 480 nm, about 440 nm to about 465 nm, or about 445 nm to about 456 nm.

In one or more embodiments, an emission half width (full width at half maximum) of the blue light may be about 30 nm or less, about 28 nm or less, about 25 nm or less, from about 10 nm to about 30 nm, or from about 10 nm to about 28 nm.

In one or more embodiments, the light emitting layer 130 may further include a host material and/or a dopant which will be described in more detail herein.

For example, in one or more embodiments, the emission layer 130 may include a host material widely suitable in the related art, such as an anthracene derivative, a pyrene derivative, a fluoranthene derivative, a chrysene derivative, a dihydrobenzanthracene derivative, a triphenylene derivative, and/or the like.

In one or more embodiments, the emission layer 130 may include, e.g., a host material represented by Chemical Formula FH. For example, the compound represented by Chemical Formula FH may be used as a fluorescent host material.

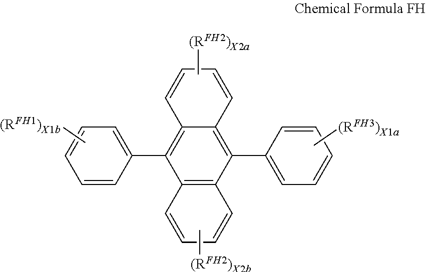

In Chemical Formula FH, R^{FH1} to R^{FH3} may at each occurrence independently be hydrogen, deuterium, a halogen, a substituted or unsubstituted silyl group, a substituted or unsubstituted thio group, a substituted or unsubstituted oxy group, a substituted or unsubstituted C₁-C₁₀ alkyl group, a substituted or unsubstituted C₂-C₁₀ alkenyl group, a substituted or unsubstituted C₆-C₆₀ aryl group, a substituted or unsubstituted C₆-C₆₀ heteroaryl group, or a cyclic group formed through a combination thereof. In one or more embodiments, in Chemical Formula FH, at least one selected from among R^{FH1} to R^{FH3} may form a condensed ring with a bonded benzene ring.

In Chemical Formula FH, x1a and x1b may each independently be an integer from 0 to 5; and x2a and x2b may each independently be an integer from 0 to 4. When x1a, x1 b, x2a, and x2b are each 2 or greater, two or more of respective R^{FH1}(s) to R^{FH3}(s) may be the same as or different from each other.

In one or more embodiments, the emission layer 130 may include, e.g., a host material represented by Chemical Formula PH. For example, the compound represented by Chemical Formula PH may be used as a host material for a phosphorescent device (e.g., for a phosphorescent dopant).

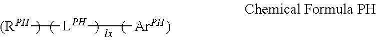

In Chemical Formula PH, R^{PH} may be a substituted or unsubstituted carbazole group. L^{PH} may be a direct linkage, a substituted or unsubstituted C₆-C₃₀ arylene group, or a substituted or unsubstituted C₂-C₃₀ heteroarylene group. Ar^{PH} may be a substituted or unsubstituted C₆-C₆₀ aryl group, or a substituted or unsubstituted C₂-C₃₀ heteroaryl group.

As described above in the definition of terminology, the term “C₆-C₆₀ aryl group” may encompass a group in which multiple aryl rings are condensed or bonded through a cyclic group (e.g., an alicyclic hydrocarbon ring). For example, a C₆-C₆₀ aryl group may be a fluorenyl group.

As described above in the definition of terminology, the term “C₂-C₃₀ heteroaryl group” may encompass a group in which multiple aryl rings are condensed or bonded through a heterocyclic ring. For example, a C₂-C₃₀ heteroaryl group may be a carbazole group, a dibenzofuran group, a dibenzothiophene group, and/or the like.

In one or more embodiments, a C₂-C₃₀ heteroaryl group may be a group in which multiple aryl rings are condensed or bonded to each other through the same or different heterocyclic rings.

In one or more embodiments, a substituent included in Ar^{PH} may be a silyl group represented by —Si(R^{sa})(R^{sb})(R^{sc}); and R^{sa}, R^{sb}, and R^{sc} may each independently be hydrogen, a halogen, a hydroxyl group, a C₁-C₆₀ alkyl group, a C₁-C₆₀ alkoxy group, a C₆-C₆₀ aryl group, or a C₂-C₃₀ heteroaryl group. At least one selected from among R^{sa}, R^{sb}, and R^{sc} may be a C₆-C₆₀ aryl group or a C₂-C₃₀ heteroaryl group. For example, in one or more embodiments, R^{sa}, R^{sb}, and R^{sc} may each independently be a C₆-C₆₀ aryl group or a C₂-C₃₀ heteroaryl group.

In Chemical Formula PH, Ix may be an integer from 0 to 10. When Ix is 2 or greater, two or more of L^{PH} (s) may be the same as or different from each other.

In one or more embodiments, the emission layer 130 may include, e.g., BCPDS (bis(4-(9H-carbazol-9-yl) phenyl) diphenylsilane), POPCPA ((4-(1-(4-(diphenylamino) phenyl) cyclohexyl) phenyl) diphenyl-phosphine oxide), DPEPO (bis[2-(diphenylphosphino)phenyl]ether oxide), mCBP (3,3′-di(9H-carbazol-9-yl)-1,1′-biphenyl), CBP (4,4′-bis(N-carbazolyl)-1,1′-biphenyl), mCP (1,3-bis(carbazol-9-yl)benzene), PPF (2,8-bis(diphenylphosphoryl) dibenzo[b,d]furan), TCTA (4,4′,4″-tris(carbazol-9-yl)-triphenylamine), TPBi (1,3,5-tris(1-phenyl-1H-benzo[d]imidazol-2-yl)benzene), Alq3 (tris(8-hydroxyquinolinato) aluminum), ADN (9,10-di(naphthalen-2-yl)anthracene), TBADN (2-tert-butyl-9,10-di(naphth-2-yl)anthracene), DSA (distyrylarylene), CDBP (4,4′-bis(9-carbazolyl)-2,2′-dimethyl-biphenyl), MADN (2-methyl-9,10-bis(naphthalen-2-yl)anthracene), CP1 (hexaphenyl cyclotriphosphazene), UGH2 (1,4-bis(triphenylsilyl)benzene), DPSiO3 (hexaphenylcyclotrisiloxane), DPSiO4 (octaphenylcyclotetrasiloxane), and/or the like, as a host material.

In one or more embodiments, in the emission layer 130, the host may include one of the materials described above, or any combination thereof.

Non-limiting examples of compounds represented by Chemical Formula PH are as follows.

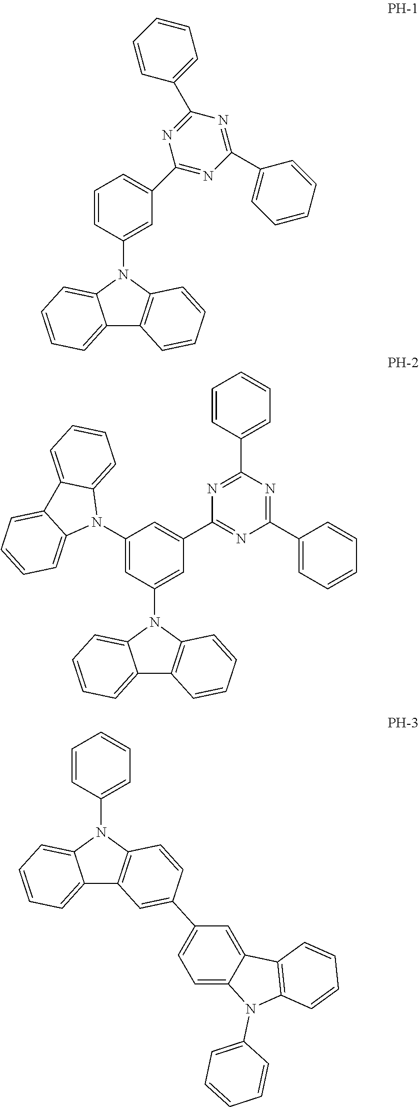

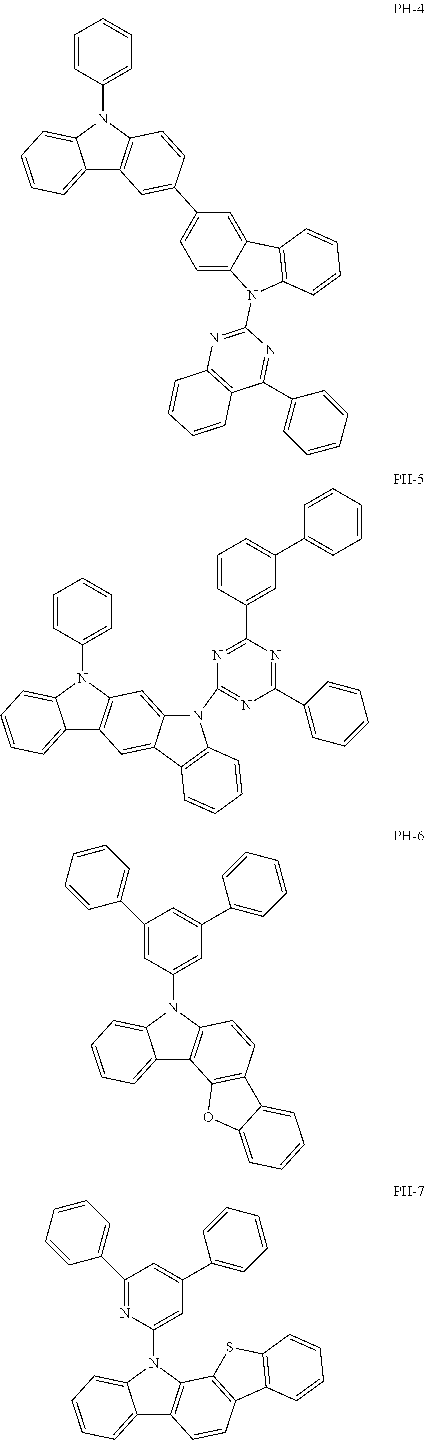

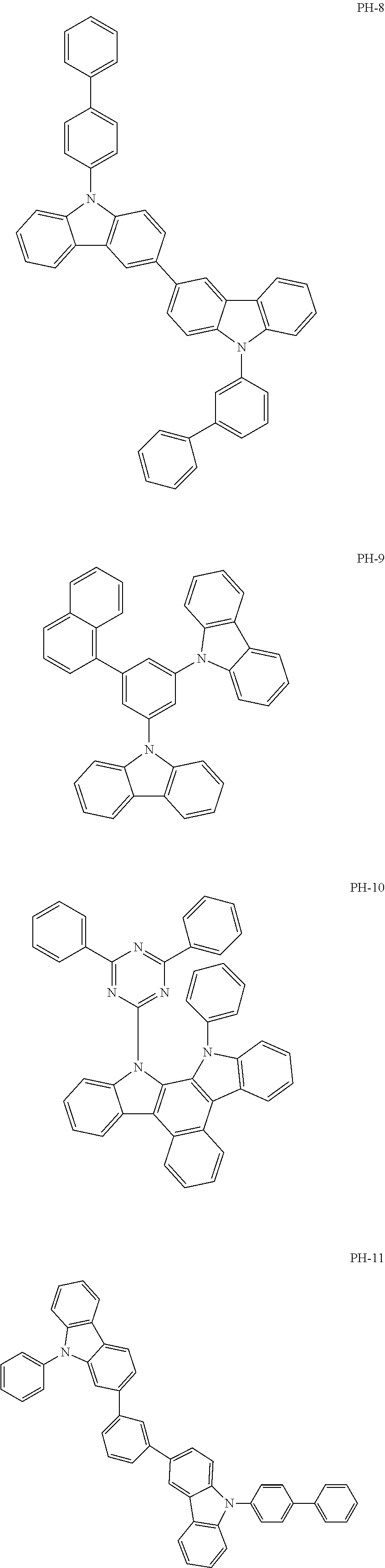 [SMILES: c1ccc(-c2ccc(-n3c4ccccc4c4cc(-c5ccc6c(c5)c5ccccc5n6-c5cccc(-c6ccccc6)c5)ccc43)cc2)cc1 ; c1ccc2c(-c3cc(-n4c5ccccc5c5ccccc54)cc(-n4c5ccccc5c5ccccc54)c3)cccc2c1 ; c1ccc(-c2nc(-c3ccccc3)nc(-n3c4ccccc4c4c5ccccc5c5c6ccccc6n(-c6ccccc6)c5c43)n2)cc1 ; c1ccc(-c2ccc(-n3c4ccccc4c4cc(-c5cccc(-c6ccc7c8ccccc8n(-c8ccccc8)c7c6)c5)ccc43)cc2)cc1]

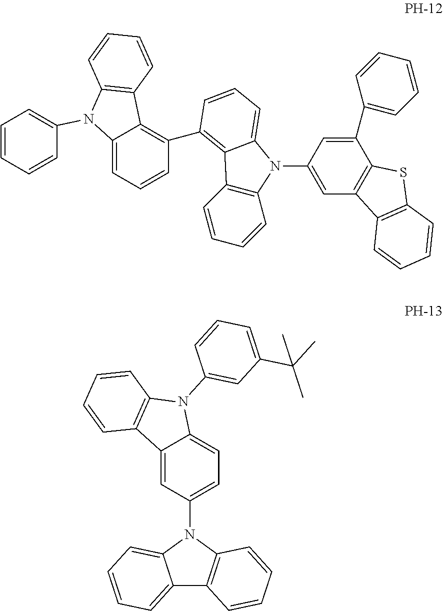 [SMILES: c1ccc(-c2cc(-n3c4ccccc4c4c(-c5cccc6c5c5ccccc5n6-c5ccccc5)cccc43)cc3c2sc2ccccc23)cc1 ; CC(C)(C)c1cccc(-n2c3ccccc3c3cc(-n4c5ccccc5c5ccccc54)ccc32)c1]

In one or more embodiments, the emission layer 130 may further include a dopant interacting with the host.

In one or more embodiments, the emission layer 130 may include a dopant represented by Chemical Formula FD. For example, the compound represented by Chemical Formula FD may be used as a fluorescent dopant.

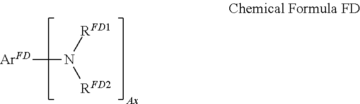

In Chemical Formula FD, Ar^{FD}, R^{FD1}, and R^{FD2} may each independently be a substituted or unsubstituted C₃-C₆₀ carbocyclic group or a substituted or unsubstituted C₁-C₆₀ heterocyclic group. Ax may be an integer from 1 to 6.

In one or more embodiments, Ar^{FD} may include a condensed ring structure in which three or more aryl rings or benzene rings are condensed together (e.g., an anthracene group, a chrysene group, a pyrene group, and/or the like).

In one or more embodiments, the emission layer 130 may include a dopant for a phosphorescent device (e.g., as a phosphorescent dopant). The dopant for the phosphorescent device may include an organometallic compound that includes a central metal and at least one ligand bonded to the central metal via a coordination bond. The central metal may include, e.g., a transition metal, and the ligand may include, e.g., a monodentate ligand, a bidentate ligand, a tridentate ligand, a tetradentate ligand, a pentadentate ligand, a hexadentate ligand, or a combination thereof.

In one or more embodiments, the dopant for the phosphorescent device may include, e.g., a compound represented by Chemical Formula PD.

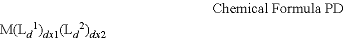

In Chemical Formula PD, M may be a transition metal, e.g., iridium (Ir), platinum (Pt), palladium (Pd), osmium (Os), titanium (Ti), gold (Au), hafnium (Hf), europium (Eu), terbium (Tb), rhodium (Rh), rhenium (Re), ruthenium (Ru), copper (Cu), or thulium (Tm).

In Chemical Formula PD, L_{d}¹ may be a ligand represented by Chemical Formula LD1.

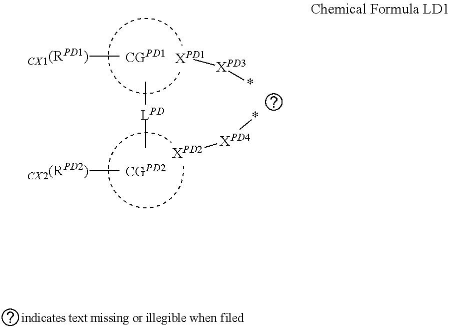

In Chemical Formula LD1, X^{PD1} and X^{PD2} may each independently be C or N.

In one or more embodiments, one of X^{PD1} and X^{PD2} may be C and the other may be N. In one or more embodiments, X^{PD1} and X^{PD2} may each be N.

In Chemical Formula LD1, CG^{PD1} and CG^{PD2} may each independently be a substituted or unsubstituted C₃-C₆₀ carbocyclic group or a substituted or unsubstituted C₁-C₆₀ heterocyclic group.

For example, CG^{PD1} and CG^{PD2} may each independently be a pyrrole group, a pyrazole group, an imidazole group, a triazole group, an oxazole group, an isoxazole group, a thiazole group, an isothiazole group, an oxadiazole group, a thiadiazole group, a benzene group, a pyridine group, a pyrimidine group, a naphthalene group, a dibenzofuran group, a dibenzothiophene group, a carbazole group, a fluorene group, a dibenzosilole group, a naphthobenzofuran group, a naphthobenzothiophene group, a benzocarbazole group, a benzofluorene group, a naphthobenzosilole group, a dinaphthofuran group, a dinaphthothiophene group, a dibenzocarbazole group, a dibenzofluorene group, a dinaphthosilole group, an azadibenzofuran group, an azadibenzothiophene group, an azacarbazole group, an azafluorene group, an azadibenzosilole group, an azanaphthobenzofuran group, an azanaphthobenzothiophene group, an azabenzocarbazole group, an azabenzofluorene group, an azanaphthobenzosilole group, an azadinapthofuran group, an azadinapthothiophene group, an azadibenzocarbazole group, an azadibenzofluorene group, or an azadinapthosilole group.

In Chemical Formula LD1, L^{PD} may be a single bond, a substituted or unsubstituted methylene group, a substituted or unsubstituted ethylene group, *—O—*′, *—S—*′, *—C(═O)—*′, *—N(R^{PD3})—*′, *—C(R^{PD4})═*′, or *═C(R^{PD5})—*′.

In Chemical Formula LD1, X^{PD3} and X^{PD4} may each independently be a chemical bond, O, S, N(R^{PD6}), B(R^{PD7}), P(R^{PD8}), C(R^{PD9})(R^{PD10}), or Si(R^{PD11})(R^{PD12}). The chemical bond may be, e.g., a covalent bond or a coordinate bond.

In Chemical Formula LD1, R^{PD1} and R^{PD2} may each independently be hydrogen, deuterium, —F, —CL, —Br, —I, —OH, —CN, —NO₂, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₆₀ cycloalkyl group, a substituted or unsubstituted C₅-C₆₀ cycloalkenyl group, a substituted or unsubstituted C₃-C₆₀ heterocycloalkyl group, a substituted or unsubstituted C₃-C₆₀ heterocycloalkenyl group, a substituted or unsubstituted C₆-C₆₀ aryl group, a substituted or unsubstituted C₂-C₆₀ heteroaryl group, a substituted or unsubstituted C₆-C₆₀ aryloxy group, a substituted or unsubstituted C₆-C₆₀ arylthio group, a substituted or unsubstituted C₈-C₆₀ condensed polycyclic group, a substituted or unsubstituted silyl group, a substituted or unsubstituted amine group, a substituted or unsubstituted aniline group, —B(R^{PD13})(R^{PD14}), —C(═O)(R^{PD15}), —S(═O)₂(R^{PD16}), or —P(═O)(R^{PD17})(R^{PD18}). The silyl group may be represented by —Si(R^{sa})(R^{sb})(R^{sc}), as explained above.

R^{PD3} to R^{PD18} may each independently be hydrogen, deuterium, —F, —CL, —Br, —I, —OH, —CN, —NO₂, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₆₀ cycloalkyl group, a substituted or unsubstituted C₅-C₆₀ cycloalkenyl group, a substituted or unsubstituted C₃-C₆₀ heterocycloalkyl group, a substituted or unsubstituted C₃-C₆₀ heterocycloalkenyl group, a substituted or unsubstituted C₆-C₆₀ aryl group, a substituted or unsubstituted C₂-C₆₀ heteroaryl group, a substituted or unsubstituted C₆-C₆₀ aryloxy group, a substituted or unsubstituted C₆-C₆₀ arylthio group, or a substituted or unsubstituted C₈-C₆₀ condensed polycyclic group.

In Chemical Formula LD1, cx1 and cx2 may each independently be an integer from 0 to 10. When at least one of cx1 or cx2 is 2 or greater, two or more of R^{PD1}(s) and/or two or more of R^{PD2}(s) may be the same as or different from each other.

The symbols -* and -*′ each represent a binding site where the ligand represented by Chemical Formula LD1 bonds to M.

In Chemical Formula PD, dx1 may be an integer from 1 to 3. When dx1 is 2 or 3, two or three of L_{d}¹(s) may be the same as or different from each other. Among two or three of L_{d}¹(s), CG^{PD1} and/or CG^{PD2} adjacent to each other may be connected to each other through a connecting group such as L^{PD1}, L^{PD2}, and/or the like. The connecting group such as L^{PD1}, L^{PD2}, and/or the like, may each independently be the same as defined with respect to L^{PD}.

In Chemical Formula PD, L_{d}² may be an organic ligand. L_{d}² may include, e.g., a halogen, CO, NO, CS, picolinate, acetate, oxalate, a diketone group, an isonitrile group, isothiocyanato-N, thiosulphato-S, an alkyl phosphine, phenylphosphine, an aryl phosphine, phosphine oxide, phosphite, or a combination thereof.

In Chemical Formula PD, dx2 is an integer of 0 to 4. When dx2 is 2 or greater, two or more of L_{d}²(s) may be the same as or different from each other.

Non-limiting examples of the compound represented by Chemical Formula PD are as follows,

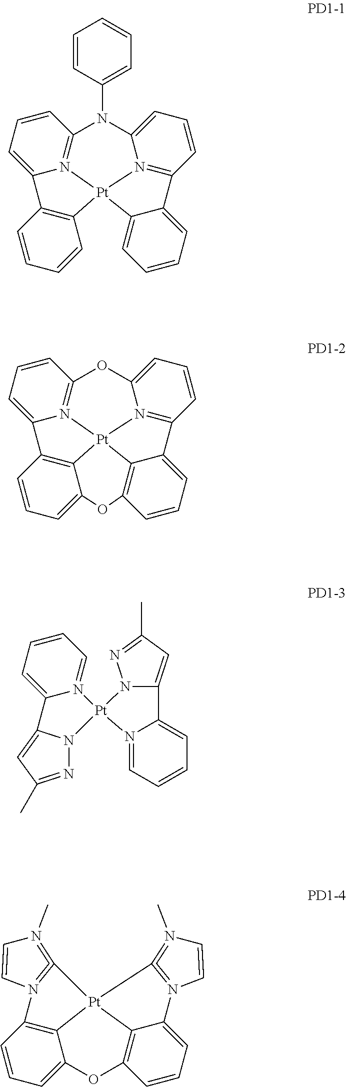

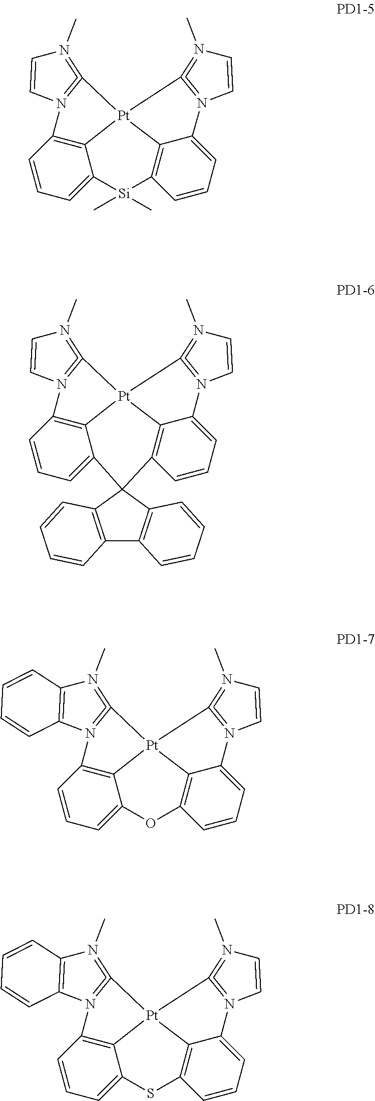

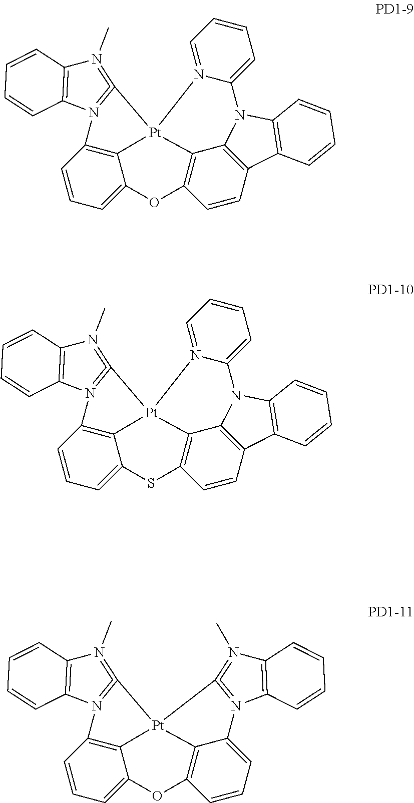

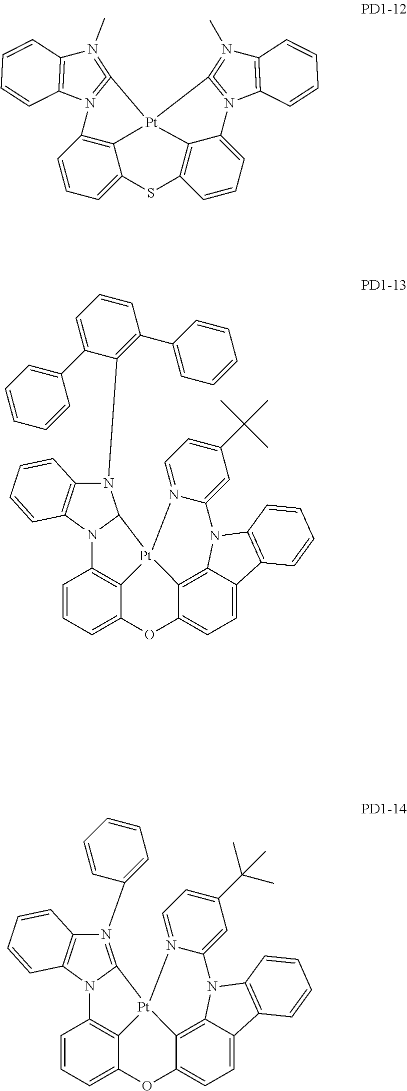

In one or more embodiments, the emission layer 130 may include a styryl derivative (e.g., 1,4-bis[2-(3-N-ethylcarbazolyl)vinyl]benzene (BCzVB), 4-(di-p-tolylamino)-4′-[(di-p-tolylamino)styryl]stilbene (DPAVB), N-(4-((E)-2-(6-((E)-4-(diphenylamino)styryl)naphthalen-2-yl)vinyl)phenyl)-N-phenylbenzenamine (NBDAVBi), and/or the like), 4,4′-bis[2-(4-(N,N-diphenylamino)phenyl)vinyl]biphenyl (DPAVBi), perylene or a derivative thereof (e.g., 2,5,8,11-tetra-t-butylperylene (TBP)), pyrene or a derivative thereof (e.g., 1,1-dipyrene, 1,4-dipyrenylbenzene, 1,4-bis(N,N-diphenylamino)pyrene), and/or the like), and/or the like, as a fluorescent dopant material.

In one or more embodiments, the emission layer 130 may include a metal complex that includes iridium (Ir), platinum (Pt), osmium (Os), gold (Au), titanium (Ti), zirconium (Zr), hafnium (Hf), europium (Eu), terbium (Tb), or thulium (Tm) as a phosphorescent dopant, in addition to one or more of the materials described above. For example, Flrpic (iridium(III) bis(4,6-difluorophenylpyridinato-N,C2′)picolinate), FIr6 (bis(2,4-difluorophenylpyridinato)-tetrakis(1-pyrazolyl)borate iridium(III)), PtOEP (platinum octaethyl porphyrin), and/or the like, may be used as a phosphorescent dopant.

In one or more embodiments, the emission layer 130 may include a boron-containing dopant represented by Chemical Formula BD.

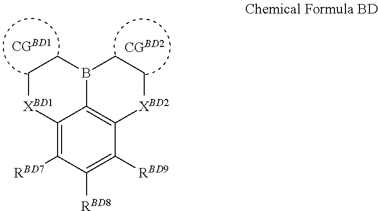

In Chemical Formula BD, X^{BD1} and X^{BD2} may each independently be N(R^{BD1}), P(R^{BD2}), C(R^{BD3})(R^{BD4}), Si(R^{BD5})(R^{BD6}), 8, or 0. In one or more embodiments, X^{BD1} and X^{BD2} may each be N(R^{BD1}). R^{BD1} to R^{BD6} may each independently be hydrogen, deuterium, a substituted or unsubstituted C₁-C₂₀ alkyl group, a substituted or unsubstituted C₆-C₆₀ aryl group, or a substituted or unsubstituted C₂-C₃₀ heteroaryl group. R^{BD7}, R^{BD8}, and R^{BD9} may each independently be hydrogen, deuterium, halogen, a cyano group, a substituted or unsubstituted amine group, a substituted or unsubstituted boryl group, a substituted or unsubstituted oxy group, a substituted or unsubstituted thio group, a substituted or unsubstituted C₁-C₂₀ alkyl group, a substituted or unsubstituted C₆-C₆₀ aryl group, or a substituted or unsubstituted C₂-C₃₀ heteroaryl group. R^{BD7}, R^{BD8}, and/or R^{BD9} may be optionally bonded to an adjacent group to form a ring.

In Chemical Formula BD, CG^{BD1} and CG^{BD2} each represent a cyclic group, and CG^{BD1} and CG^{BD2} may each independently be a substituted or unsubstituted C₃-C₆₀ carbocyclic group or a substituted or unsubstituted C₁-C₆₀ heterocyclic group. In one or more embodiments, CG^{BD1} and COG^{BD2} may each independently be a substituted or unsubstituted C₆-C₆₀ aryl group or a substituted or unsubstituted C₂-C₃₀ heteroaryl group.

In one or more embodiments, CG^{BD1} and CG^{BD2} may each independently be a substituted or unsubstituted benzene ring. In these embodiments, the boron-containing dopant may serve as a thermally activated delayed fluorescence (TADF) dopant.

In one or more embodiments, one of CG^{BD1} and CG^{BD2} may be a non-condensed aryl group or a non-condensed heteroaryl group, and the other one thereof may be a condensed polycyclic aryl group or a condensed polycyclic heteroaryl group.

In these embodiments, the boron-containing dopant may serve as a fluorescent dopant.

In one or more embodiments, the emission layer 130 may include one of the dopant materials described above, or any combination thereof.

In one or more embodiments, the emission layer 130 may include two or more host materials. For example, in one or more embodiments, the emission layer 130 may include a hole transporting host and an electron transporting host. In this regard, the emission layer 130 may include a hole transporting host, an electron transporting host, a photosensitive agent, and a dopant. In one or more embodiments, the hole transporting host and the electron transporting host may form an exciplex, and energy may be transferred from the exciplex to the photosensitive agent and from the photosensitive agent to the dopant, thereby inducing a light emission.

Non-limiting examples of the hole transporting host may include a compound represented by Chemical Formula HT which will be described later. Non-limiting examples of the electron transporting host may include a compound represented by Chemical Formula ET which will be described later.

In one or more embodiments, the emission layer 130 may include quantum dots. A quantum dot may include a Group II-VI compound, a Group III-VI compound, a Group I-III-VI compound, a Group III-V group compound, a Group III-II-V group compound, a Group IV-VI compound, a Group IV element, a Group IV compound, or a combination thereof.

The quantum dot may include a core that includes the compound as described above, and a shell around (e.g., surrounding) the core. The shell may include an inorganic oxide or a semiconductor compound. Non-limiting examples of the semiconductor compound as a shell may include CdS, CdSe, CdTe, ZnS, ZnSe, ZnTe, ZnSe, ZnTeS, GaAs, GaP, GaSb, HgS, HgSe, HgTe, InAs, InP, InGaP, InSb, AlAs, AlP, AlSb, and/or the like.

In one or more embodiments, a color of light from a quantum dot may be adjusted according to a particle size of the quantum dot. The quantum dot may be a blue quantum dot that is to emit blue light, a red quantum dot that is to emit red light, or a green quantum dot that is to emit green light.

The hole transfer region 120 may be formed between the first electrode 110 and the emission layer 130. The hole transfer region 120 may have a single-layered structure or a multi-layered structure including different materials.

The hole transfer region 120 may include a hole injection layer, a hole transport layer, and/or an electron blocking layer, and may further include an auxiliary emission layer.

In one or more embodiments, as illustrated in FIG. 2, the hole transfer region 120 may include a hole injection layer 122 and a hole transport layer 124, sequentially stacked from the first electrode 110.

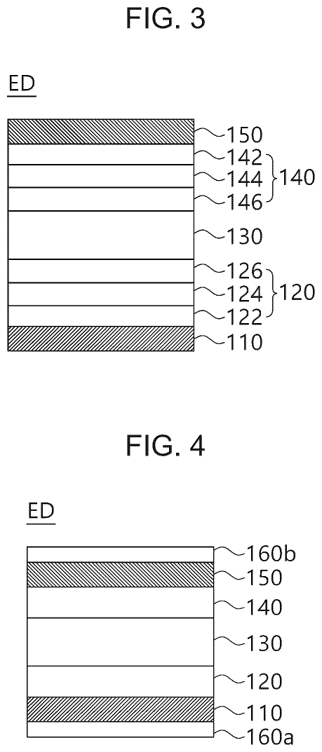

In one or more embodiments, as illustrated in FIG. 3, the hole transfer region 120 may include a hole injection layer 122, a hole transport layer 124, and an electron blocking layer 126, sequentially stacked from the first electrode 110. The electron blocking layer 126 may block electrons from the electron transfer region 140 to the hole transfer region 120. Accordingly, the generation of excitons in the emission layer 130 may be increased, and light-emission efficiency may be further increased.

For example, in one or more embodiments, the hole transfer region 120 may include a compound represented by Chemical Formula HT.

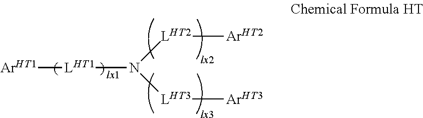

In Chemical Formula HT, L^{HT1}, L^{HT2}, and L^{HT3} may each independently be a direct linkage, a substituted or unsubstituted C₆-C₆₀ arylene group, or a substituted or unsubstituted C₂-C₃₀ heteroarylene group.

In Chemical Formula HT, Ix1 to Ix3 may each independently be an integer from 0 to 10. When Ix1, Ix2, or Ix3 is 2 or greater, two or more of respective L^{HT1}(s), L^{HT2}(s), or L^{HT3}(s) may be directly connected by, e.g., carbon atoms (e.g., sp² carbons) of each aryl ring, to form a substituted or unsubstituted C₆-C₆₀ arylene group or a substituted or unsubstituted C₂-C₃₀ heteroarylene group. For example, when Ix3 is 2 or more, two or more of L^{HT3}(s) may be directly connected by, e.g., carbon atoms (e.g., sp² carbons) of each aryl ring, to form a substituted or unsubstituted C₆-C₆₀ arylene group or a substituted or unsubstituted C₂-C₃₀ heteroarylene group. When Ix1 is 2 or more, two or more of L^{HT1}(s) may be directly connected by, e.g., carbon atoms (e.g., sp² carbons) of each aryl ring, to form a substituted or unsubstituted C₆-C₆₀ arylene group or a substituted or unsubstituted C₂-C₃₀ heteroarylene group. When Ix2 is 2 or more, two or more of L^{HT2}(s) may be directly connected by, e.g., carbon atoms (e.g., sp² carbons) of each aryl ring, to form a substituted or unsubstituted C₆-C₆₀ arylene group or a substituted or unsubstituted C₂-C₃₀ heteroarylene group.

In Chemical Formula HT, Ar^{HT1} and Ar^{HT2} may each independently be a substituted or unsubstituted C₆-C₆₀ aryl group or a substituted or unsubstituted C₂-C₃₀ heteroaryl group. Ar^{HT3} may be a substituted or unsubstituted C₆-C₃₀ aryl group.

In one or more embodiments, the compound represented by Chemical Formula HT may be a monoamine compound. In one or more embodiments, the compound represented by Chemical Formula HT may be a diamine compound in which at least one selected from among Ar^{HT1} to Ar^{HT3} includes an amine group as a substituent.

In one or more embodiments, the compound represented by Chemical Formula HT may be a carbazole-based compound in which at least one of Ar^{HT1} or Ar^{HT2} includes a substituted or unsubstituted carbazole group. or a fluorene-based compound in which at least one of Ar^{HT1} or Ar^{HT2} includes a substituted or unsubstituted fluorene group.

In one or more embodiments, two adjacent groups selected from among Ar^{HT1} to Ar^{HT3} may be condensed together to form a ring.

Non-limiting examples of the compound represented by the formula HT are as follows.

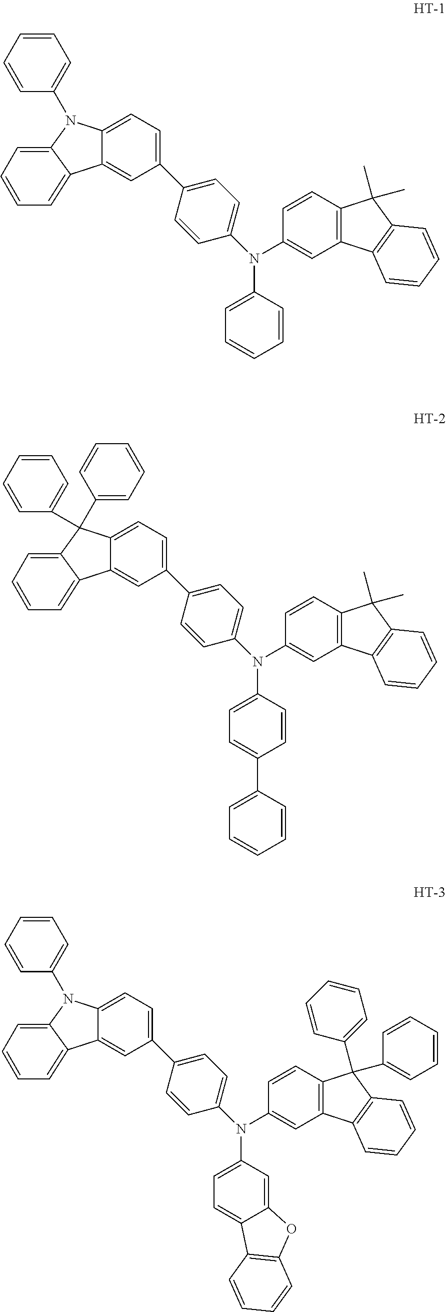 [SMILES: CC1(C)c2ccccc2-c2cc(N(c3ccccc3)c3ccc(-c4ccc5c(c4)c4ccccc4n5-c4ccccc4)cc3)ccc21 ; CC1(C)c2ccccc2-c2cc(N(c3ccc(-c4ccccc4)cc3)c3ccc(-c4ccc5c(c4)-c4ccccc4C5(c4ccccc4)c4ccccc4)cc3)ccc21 ; c1ccc(-n2c3ccccc3c3cc(-c4ccc(N(c5ccc6c(c5)-c5ccccc5C6(c5ccccc5)c5ccccc5)c5ccc6c(c5)oc5ccccc56)cc4)ccc32)cc1]

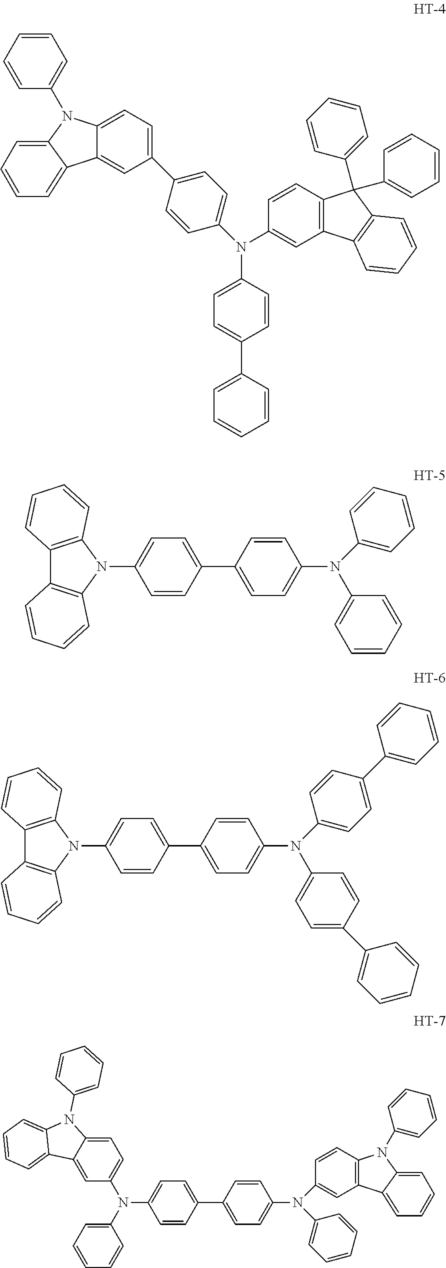 [SMILES: c1ccc(-c2ccc(N(c3ccc(-c4ccc5c(c4)c4ccccc4n5-c4ccccc4)cc3)c3ccc4c(c3)-c3ccccc3C4(c3ccccc3)c3ccccc3)cc2)cc1 ; c1ccc(N(c2ccccc2)c2ccc(-c3ccc(-n4c5ccccc5c5ccccc54)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1]

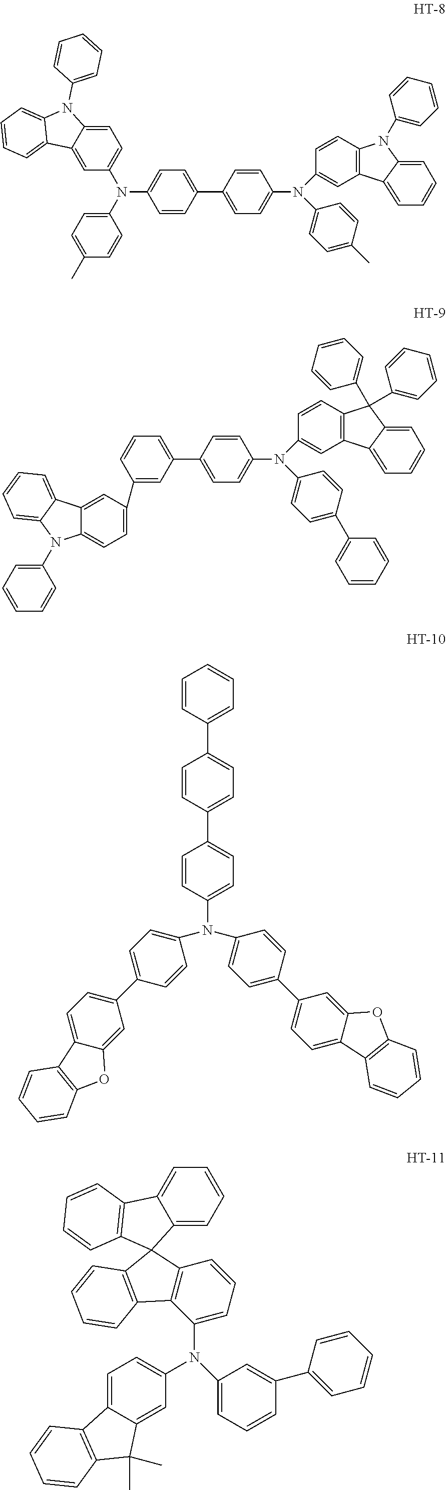 [SMILES: Cc1ccc(N(c2ccc(-c3ccc(N(c4ccc(C)cc4)c4ccc5c(c4)c4ccccc4n5-c4ccccc4)cc3)cc2)c2ccc3c(c2)c2ccccc2n3-c2ccccc2)cc1 ; c1ccc(-c2ccc(N(c3ccc(-c4cccc(-c5ccc6c(c5)c5ccccc5n6-c5ccccc5)c4)cc3)c3ccc4c(c3)-c3ccccc3C4(c3ccccc3)c3ccccc3)cc2)cc1 ; c1ccc(-c2ccc(-c3ccc(N(c4ccc(-c5ccc6c(c5)oc5ccccc56)cc4)c4ccc(-c5ccc6c(c5)oc5ccccc56)cc4)cc3)cc2)cc1 ; CC1(C)c2ccccc2-c2ccc(N(c3cccc(-c4ccccc4)c3)c3cccc4c3-c3ccccc3C43c4ccccc4-c4ccccc43)cc21]

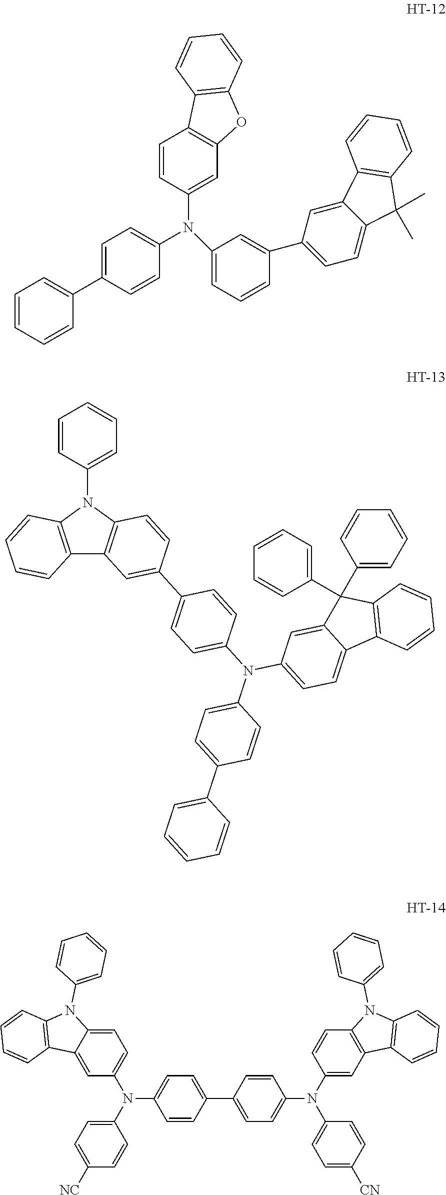 [SMILES: CC1(C)c2ccccc2-c2cc(-c3cccc(N(c4ccc(-c5ccccc5)cc4)c4ccc5c(c4)oc4ccccc45)c3)ccc21 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1 ; N#Cc1ccc(N(c2ccc(-c3ccc(N(c4ccc(C#N)cc4)c4ccc5c(c4)c4ccccc4n5-c4ccccc4)cc3)cc2)c2ccc3c(c2)c2ccccc2n3-c2ccccc2)cc1]

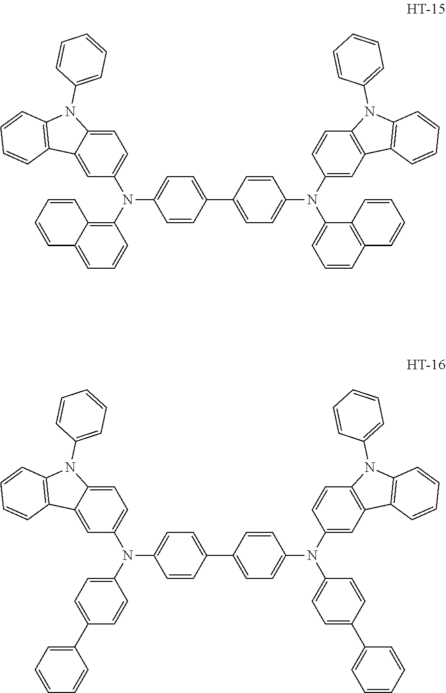 [SMILES: c1ccc(-n2c3ccccc3c3cc(N(c4ccc(-c5ccc(N(c6ccc7c(c6)c6ccccc6n7-c6ccccc6)c6cccc7ccccc67)cc5)cc4)c4cccc5ccccc45)ccc32)cc1 ; c1ccc(-c2ccc(N(c3ccc(-c4ccc(N(c5ccc(-c6ccccc6)cc5)c5ccc6c(c5)c5ccccc5n6-c5ccccc5)cc4)cc3)c3ccc4c(c3)c3ccccc3n4-c3ccccc3)cc2)cc1]

For example, in one or more embodiments, the hole transfer region 120 may include one or more selected from among m-MTDATA (4,4′,4″-[tris(3-methylphenyl)phenylamino]triphenylamine), TDATA (4,4′4″-tris(N,N-diphenylamino)triphenylamine), 2-TNATA (4,4′,4″-tris[N(2-naphthyl)-N-phenylamino]-triphenylamine), NPB (N,N′-di(naphthalen-1-yl)-N,N′-diphenyl-benzidine), TPD (N,N′-bis(3-methylphenyl)-N,N′-diphenyl-[1,1′-biphenyl]-4,4′-diamine), Spiro-TPD, Spiro-NPB, DNTPD (N¹,N¹′-([1,1′-biphenyl]-4,4′-diyl)bis(N1-phenyl-N4,N4-di-m-tolylbenzene-1,4-diamine), TAPC (4,4′-cyclohexylidene bis[N,N-bis(4-methylphenyl)benzenamine]), HMTPD (4,4′-bis[N,N′-(3-tolyl)amino]-3,3′-dimethyl biphenyl), TCTA (4,4′,4″-tris(N-carbazolyl)triphenylamine), PANI/DBSA (polyaniline/dodecylbenzenesulfonic acid), PEDOT/PSS (poly(3,4-ethylenedioxythiophene)/poly(4-styrenesulfonate)), PANI/CSA(Polyaniline/Camphor sulfonicacid), PANI/PSS (polyaniline/poly(4-styrenesulfonate)), a phthalocyanine compound, a carbazole compound (N-phenylcarbazole, polyvinylcarbazole, CzSi(9-(4-tert-Butylphenyl)-3,6-bis(triphenylsilyl)-9H-carbazole, and/or the like), a fluorene compound, and/or the like. The hole transfer region 120 may include one of the hole transfer materials described above, or a combination thereof.

The hole transfer materials described above may be included in at least one of the hole injection layer 122, the hole transport layer 124, or the electron blocking layer 126.

In one or more embodiments, the hole transfer region 120 may further include a charge generating material. The charge generating material may be a dopant material such as a p-dopant, so that conductivity of the hole transfer region 120 may be improved.

Non-limiting examples of the dopant material may include a halogenated metal compound (e.g., a metal halide) such as LiF, NaCl, CsF, RbCl, Rbl, CuI, and KI; a quinone derivative such as TCNQ (tetracyanoquinodimethane), F4-TCNQ (2,3,5,6-tetrafluoro-7,7,8,8-tetracyanoquinodimethane), and/or the like; a cyano-containing compound such as HATCN (dipyrazino[2,3-f: 2′,3′-h]quinoxaline-2,3,6,7,10,11-hexacarbonitrile), NDP9 (4-[[2,3-bis[cyano-(4-cyano-2,3,5,6-tetrafluorophenyl)methylidene]cyclopropylidene]-cyanomethyl]-2,3,5,6-tetrafluorobenzonitrile), and/or the like; a tungsten (W) oxide; a molybdenum (Mo) oxide; and/or the like. The hole transfer region 120 may include one of the dopant materials described above, or a combination thereof.

A thickness of the hole transfer region 120 may be in a range of about 100 Å to about 10,000 Å. For example, in one or more embodiments, the thickness of the hole transfer region 120 may be in a range of about 100 Å to about 1,500 Å.

When the hole transfer region 120 includes the hole injection layer 122 or the hole transport layer 124, a thickness of the hole injection layer 122 may be in a range from about 100 Å to about 9,000 Å, from about 100 Å to about 3,000 Å, or from about 100 Å to about 1,000 Å. A thickness of the hole transport layer 124 may be in a range from 50 Å to about 2,000 Å, from about 100 Å to about 1,500 Å, from about 100 Å to about 1,000 Å, or from about 100 Å to about 600 Å.

Within the thickness ranges described above, hole transfer properties may be enhanced even at a low voltage operation, and a life-span of the device may be further improved.

Each constituent layer of the hole transfer region 120 may be formed by a process such as a thermal evaporation deposition, a vacuum deposition, a spin coating, an inkjet printing, a laser printing, a casting, a laser thermal transfer, and/or the like.

The electron transfer region 140 may be formed between the second electrode 150 and the emission layer 130. The electron transfer region 140 may have a single-layered structure, or a multi-layered structure including different materials.

The electron transfer region 140 may include an electron injection layer, an electron transport layer, and/or a hole blocking layer, and may further include an auxiliary emission layer.

In one or more embodiments, as illustrated in FIG. 2, the electron transfer region 140 may include an electron injection layer 142 and an electron transport layer 144, stacked from the second electrode 150 to the emission layer 130.

In one or more embodiments, as illustrated in FIG. 3, the electron transfer region 140 may include an electron injection layer 142, an electron transport layer 144, and a hole blocking layer 146, stacked from the second electrode 150 to the emission layer 130. The hole blocking layer 146 may block or suppress or reduce holes from the hole transfer region 120 to the electron transfer region 140. Accordingly, emission energy and luminescence efficiency in the emission layer 130 may be further improved.

For example, in one or more embodiments, the electron transfer region 140 may include a compound represented by Chemical Formula ET.

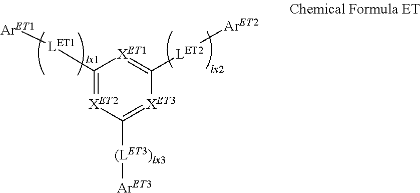

In Chemical Formula ET, at least one selected from among X^{ET1} to X^{ET3} may be N, and the remainder of X^{ET1} to X^{ET3} may each independently be C(R^{ET}). R^{ET} may be hydrogen, deuterium, a substituted or unsubstituted C₁-C₂₀ alkyl group, a substituted or unsubstituted C₆-C₆₀ aryl group, or a substituted or unsubstituted C₂-C₆₀ heteroaryl group.

When one of X^{ET1} to X^{ET3} is N, the compound represented by Chemical Formula ET may include a pyridine group. When two of X^{ET1} to X^{ET3} are N, the compound represented by Chemical Formula ET may include a pyrimidine group.

When X^{ET1} to X^{ET3} are each N, the compound represented by Chemical Formula ET may include a triazine group.

In Chemical Formula ET, Ix1 to Ix3 may each independently be an integer from 0 to 10. L^{ET1} to L^{ET3} may each independently be a direct linkage, a substituted or unsubstituted C₆-C₆₀ arylene group, or a substituted or unsubstituted C₂-C₃₀ heteroarylene group.

When Ix1, Ix2, or Ix3 is 2 or greater, two or more of respective L^{ET1}(s), L^{ET2}(s), or L^{ET3}(s), may be directly linked together, e.g., by carbon atoms of each aryl ring (e.g., sp² carbons), to form a substituted or unsubstituted C₆-C₆₀ arylene group or a substituted or unsubstituted C₂-C₃₀ heteroarylene group. For example, when Ix1 is 2 or greater, two or more of L^{ET1}(s) may be directly linked together, e.g., by carbon atoms of each aryl ring (e.g., sp₂ carbons), to form a substituted or unsubstituted C₆-C₃₀ arylene group or a substituted or unsubstituted C₂-C₃₀ heteroarylene group. When Ix2 is 2 or greater, two or more of L^{ET2}(s) may be directly linked together, e.g., by carbon atoms of each aryl ring (e.g., sp² carbons), to form a substituted or unsubstituted C₆-C₆₀ arylene group or a substituted or unsubstituted C₂-C₃₀ heteroarylene group. When Ix3 is 2 or greater, two or more of L^{ET3}(s) may be directly linked together, e.g., by carbon atoms of each aryl ring (e.g., sp² carbons), to form a substituted or unsubstituted C₆-C₆₀ arylene group or a substituted or unsubstituted C₂-C₃₀ heteroarylene group.

In Chemical Formula ET, Ar^{ET1} to Ar^{ET3} may each independently be hydrogen, deuterium, a substituted or unsubstituted C₁-C₂₀ alkyl group, a substituted or unsubstituted C₆-C₆₀ aryl group, or a substituted or unsubstituted C₂-C₃₀ heteroaryl group. For example, in one or more embodiments, Ar^{ET1} to Ar^{ET3} may each independently be a substituted or unsubstituted phenyl group, a substituted or unsubstituted carbazole group, a substituted or unsubstituted fluorene group, or a substituted or unsubstituted silyl group. The silyl group may be represented by —Si(R^{sa})(R^{sb})(R^{sc}), as explained above.

Non-limiting examples of the electron transport material (e.g., the compound represented by Chemical Formula ET) included in the electron transfer region 140 are as follows.

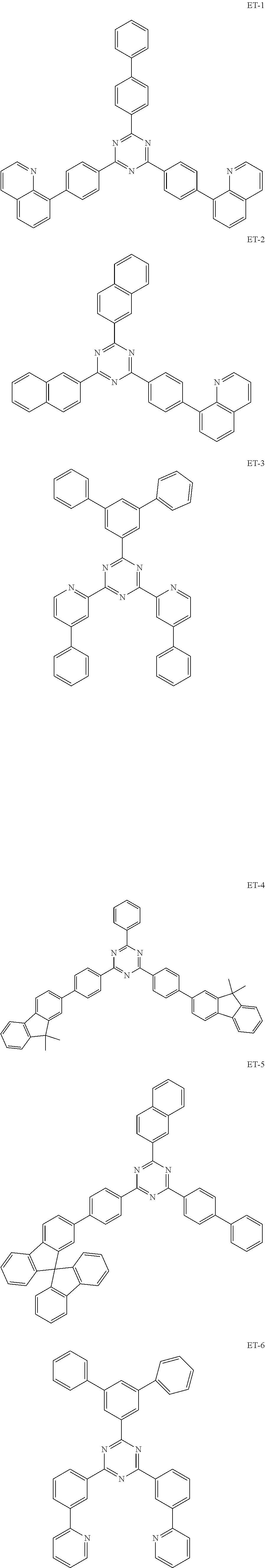

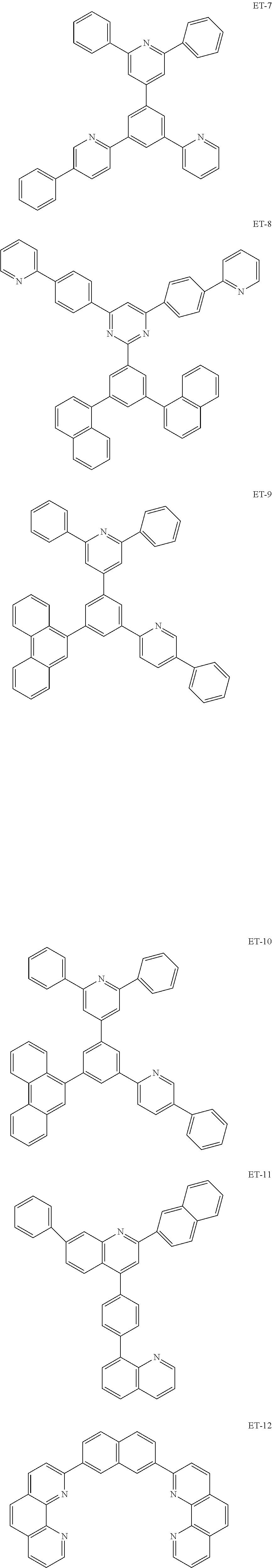 [SMILES: c1ccc(-c2ccc(-c3cc(-c4cc(-c5ccccc5)nc(-c5ccccc5)c4)cc(-c4ccccn4)c3)nc2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1 ; c1ccc(-c2ccc(-c3cc(-c4cc(-c5ccccc5)nc(-c5ccccc5)c4)cc(-c4cc5ccccc5c5ccccc45)c3)nc2)cc1 ; c1ccc(-c2ccc(-c3cc(-c4cc(-c5ccccc5)nc(-c5ccccc5)c4)cc(-c4cc5ccccc5c5ccccc45)c3)nc2)cc1 ; c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12]

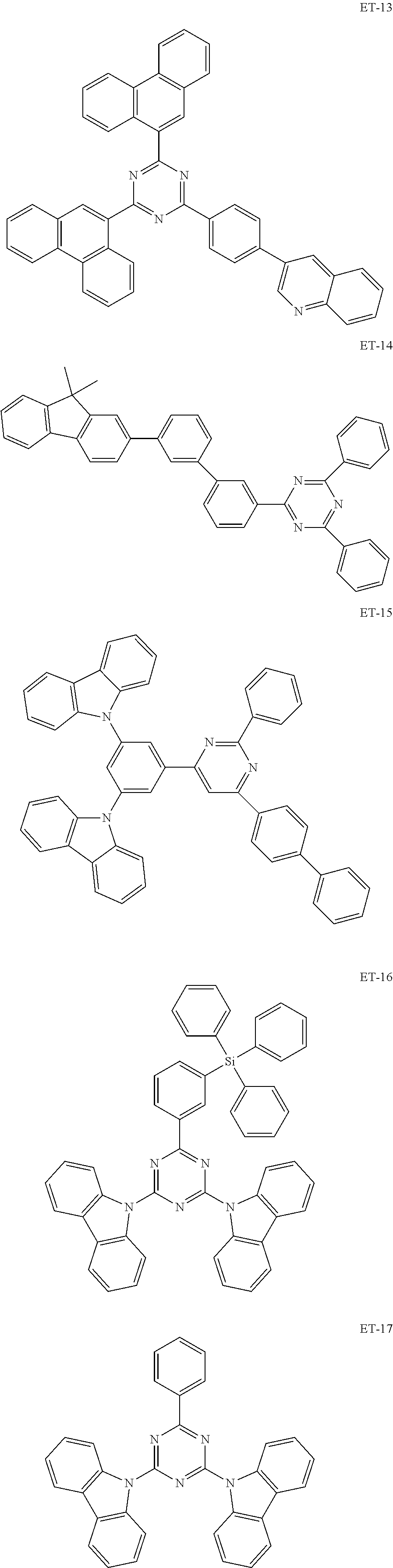 [SMILES: c1ccc2ncc(-c3ccc(-c4nc(-c5cc6ccccc6c6ccccc56)nc(-c5cc6ccccc6c6ccccc56)n4)cc3)cc2c1 ; CC1(C)c2ccccc2-c2ccc(-c3cccc(-c4cccc(-c5nc(-c6ccccc6)nc(-c6ccccc6)n5)c4)c3)cc21 ; c1ccc(-c2ccc(-c3cc(-c4cc(-n5c6ccccc6c6ccccc65)cc(-n5c6ccccc6c6ccccc65)c4)nc(-c4ccccc4)n3)cc2)cc1 ; c1ccc([Si](c2ccccc2)(c2ccccc2)c2cccc(-c3nc(-n4c5ccccc5c5ccccc54)nc(-n4c5ccccc5c5ccccc54)n3)c2)cc1 ; c1ccc(-c2nc(-n3c4ccccc4c4ccccc43)nc(-n3c4ccccc4c4ccccc43)n2)cc1]

In one or more embodiments, the electron transfer region 140 may include an anthracene compound, Alq₃ (tris(8-hydroxyquinolinato)aluminum), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzimidazol-1-yl)phenyl)-9,10-dinaphthylanthracene, TPBi (1,3,5-Tri(1-phenyl-1H-benzo[d]imidazol-2-yl)benzene), BCP (2,9-dimethyl-4,7-diphenyl-1,10-phenanthroline), Bphen (4,7-diphenyl-1,10-phenanthroline), TAZ (3-(biphenyl-4-yl)-4-phenyl-5-tert-butylphenyl-1,2,4-triazole), NTAZ (4-(naphthalen-1-yl)-3,5-diphenyl-4H-1,2,4-triazole), tBu-PBD (2-(biphenyl-4-yl)-5-(4-tert-butylphenyl)-1,3,4-oxadiazole), BAIq (Bis(2-methyl-8-quinolinolato-N1, O8)-(1,1′-biphenyl-4-olato)aluminum), Bebq₂ (beryllium bis(benzoquinolin-10-olate)), AND (9,10-di(naphthalen-2-yl)anthracene), BmPyPhB (1,3-bis[3,5-di(pyridin-3-yl)phenyl]benzene), TSPO1 (diphenyl(4-(triphenylsilyl)phenyl)phosphine oxide) and/or the like. The electron transfer region 140 may include one of the electron transfer materials described above, or a combination thereof.

The above-mentioned material may be included in at least one of the electron injection layer 142, the electron transport layer 144, or the hole blocking layer 146.

In one or more embodiments, the electron transfer region 140 may include an alkali metal, an alkaline earth metal, a rare earth metal, an alkali metal-containing compound, an alkaline earth metal-containing compound, a rare earth metal-containing compound, an alkali metal complex, an alkaline earth metal complex, a rare earth metal complex, or a combination thereof. In one or more embodiments, one or more of the above-mentioned materials may be included electron injection layer 142.

The alkali metal may include Li, Na, K, Rb, Cs, or any combination thereof. The alkaline earth metal may include Mg, Ca, Sr, Ba, or any combination thereof. The rare earth metal may include Sc, Y, Ce, Tb, Yb, Gd, or any combination thereof.

The alkali metal-containing compound, the alkaline earth metal-containing compound, and the rare earth metal-containing compound may include an oxide, a halide (e.g., a fluoride, a chloride, a bromide, an iodide, and/or the like), a telluride, or a combination thereof of the alkali metal, the alkaline earth metal, and the rare earth metal, respectively.

The alkali metal complex, the alkaline earth metal complex, and the rare earth metal complex may include a respective metal ion such as an alkali metal ion, an alkaline earth metal ion, or a rare earth metal ion, and a ligand bonded to the respective metal ion. The ligand may include, e.g., hydroxyquinoline, hydroxyisoquinoline, hydroxybenzoquinoline, hydroxyacridine, hydroxyphenanthridine, hydroxyphenyloxazole, hydroxyphenylthiazole, hydroxyphenyloxadiazole, hydroxyphenylthiadiazole, hydroxyphenylpyridine, hydroxyphenylbenzimidazole, hydroxyphenylbenzothiazole, bipyridine, phenanthroline, cyclopentadiene, or a combination thereof.

A thickness of the electron transfer region 140 may be in a range from about 100 Å to about 1,000 Å, e.g., from about 150 Å to about 500 Å.

When the electron transfer region 140 includes an electron injection layer 142 or an electron transport layer 144, a thickness of the electron injection layer 142 may be in a range from about 1 Å to about 100 Å, from 1 Å to about 90 Å, or from about 5 Å to about 50 Å, and a thickness of the electron transport layer 144 may be in a range from 10 Å to about 900 Å, from about 10 Å to about 500 Å, or from about 100 Å to about 400 Å.

Within any of the respective thickness ranges described above, electron injection and electron transport properties may be further improved without an excessive increase in driving voltage, and stability of the electron transfer region 140 may be improved.

Each constituent layer of the electron transfer region 140 may be formed by a process such as a thermal evaporation deposition, a vacuum deposition, a spin coating, an inkjet printing, a laser printing, a casting, a laser thermal transfer, and/or the like.

In one or more embodiments, the light-emitting device ED may further include a capping layer. Light emission efficiency to an outside of the light-emitting device ED may be improved through the capping layer.

As illustrated in FIG. 4, in one or more embodiments, a second capping layer 160b may be formed on an outer surface of the second electrode 150. In one or more embodiments, a first capping layer 160a may be formed on an outer surface of the first electrode 110.

A refractive index of the first capping layer 160a and/or the second capping layer 160b may be 1.6 or more. For example, in one or more embodiments, the refractive index of the first capping layer 160a and/or the second capping layer 160b may be 1.6 or more, 1.8 or more, or 2.0 or more for light in a wavelength range of 550 nm to 660 nm.

The first capping layer 160a and the second capping layer 160b may each be formed as an organic capping layer including an organic material, an inorganic capping layer including an inorganic material, or an organic-inorganic hybrid capping layer including both (e.g., simultaneously) the organic material and the inorganic material.

The first capping layer 160a and/or the second capping layer 160b may each have a single-layered structure or a multi-layered structure including different materials.

In one or more embodiments, the first capping layer 160a and the second capping layer 160b may each independently include a carbocyclic compound, a heterocyclic compound, an amine group-containing compound, a porphine derivative, a phthalocyanine derivative, a naphthalocyanine derivative, an alkali metal complex, an alkaline earth metal complex, and/or the like. The first capping layer 160a and the second capping layer 160b may each independently include one of the aforementioned materials, or a combination thereof.

In one or more embodiments, the first capping layer 160a and/or the second capping layer 160b may each independently include an amine group-containing compound.

In a non-limiting example, the first capping layer 160a and/or the second capping layer 160b may each include at least one selected from among the compounds represented by Chemical Formulae P1 to P4 and/or at least one selected from among the compounds HT-7, HT-8, HT-14, HT-15, and HT-16.

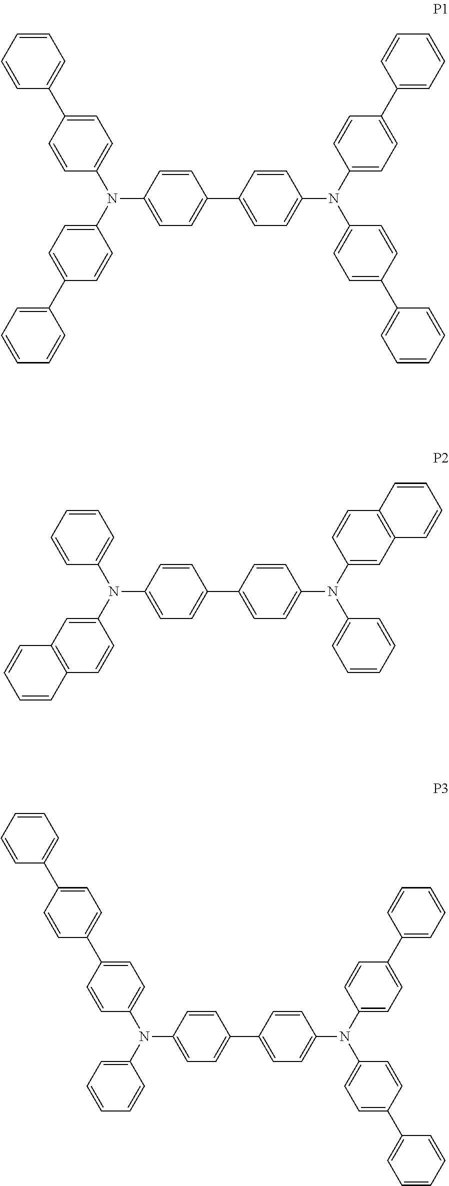 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1]

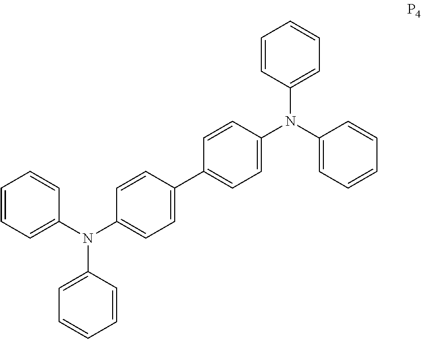 [SMILES: c1ccc(N(c2ccccc2)c2ccc(-c3ccc(N(c4ccccc4)c4ccccc4)cc3)cc2)cc1]

Referring to FIG. 5, in one or more embodiments, the light-emitting device ED may include a plurality of light-emitting structures (e.g., the light-emitting structures ES1, ES2, and ES3). The light-emitting structures ES1, ES2, and ES3 may each include a stacked structure of the hole transfer region 120, the emission layer 130, and the electron transfer region 140, as described with reference to FIGS. 1 to 4. In one or more embodiments, the light-emitting device ED of FIG. 5 may be a light-emitting device having a tandem structure.

Charge generation layers CGL1 and CGL2 may each be respectively arranged between adjacent structures among the light-emitting structures ES1, ES2, and ES3. Charge generation layers CGL1 and CGL2 may each independently include a p-type (kind) charge (e.g., P-charge) generation layer and/or an n-type (kind) charge (e.g., N-charge) generation layer.

The p-type (kind) charge generation layer may include a hole transport host compound, such as NPB. For example, in one or more embodiments, the p-type (kind) charge generation layer may include a compound represented by Chemical Formula HT described above. The p-type (kind) charge generation layer may further include a p-dopant, such as TCNQ.

In one or more embodiments, the n-type (kind) charge generation layer may include at least one selected from the group consisting of an alkali metal, an alkaline earth metal, a lanthanide metal, a rare earth metal, a transition metal, a post-transition metal, and an alloy thereof.

The n-type (kind) charge generation layer may further include, e.g., a metal complex, and the metal complex may include the above-described metal and at least one organic ligand. The organic ligand may include, e.g., hydroxyquinoline, hydroxyisoquinoline, hydroxybenzoquinoline, hydroxyacridine, hydroxyphenanthridine, hydroxyphenyloxazole, hydroxyphenylthiazole, hydroxydiphenyloxadiazole, hydroxydiphenylthiadiazole, hydroxyphenylpyridine, hydroxyphenylbenzimidazole, hydroxyphenylbenzothiazole, bipyridine, phenanthroline, cyclopentadiene, and/or the like.

In one or more embodiments, the n-type (kind) charge generation layer may further include an electron transport host compound. For example, the n-type (kind) charge generation layer may include a compound represented by Chemical Formula ET described above. In one or more embodiments, the n-type (kind) charge generation layer may include a phenanthroline-based compound.

In one or more embodiments, a thickness of the n-type (kind) charge generation layer and a thickness of the p-type (kind) charge generation layer may each independently be in a range from about 20 Å to about 1000 Å, from about 20 Å to about 700 Å, or from about 30 Å to about 500 Å.

The charge generation layers CGL1 and CGL2 may include a first charge generation layer CGL1 arranged between the first light-emitting structure ES1 and the second light-emitting structure ES2, and a second charge generation layer CGL2 arranged between the second light-emitting structure ES2 and the third-light emitting structure ES3.

In one or more embodiments, the first light-emitting structure ES1, the first charge generation layer CGL1, the second light-emitting structure ES2, the second charge generation layer CGL2, the third light-emitting structure ES3, and the second electrode 150 may be sequentially stacked on a top surface of the first electrode 110.

Colors emitted from the first light-emitting structure ES1, the second light-emitting structure ES2, and the third light-emitting structure ES3 may be the same as or different from one another. In one or more embodiments, the first light-emitting structure ES1, the second light-emitting structure ES2, and the third light-emitting structure ES3 may include a red light-emitting layer, a green light-emitting layer, and a blue light-emitting layer, respectively, and a white light-emitting structure may be implemented through the tandem structure, but embodiments of the present disclosure are not limited thereto.

In FIG. 5, a 3-stack tandem structure in which three light-emitting structures are stacked is illustrated as an example, but the tandem structure of the light-emitting device of the present disclosure is not limited to the structure illustrated in FIG. 5. For example, a 2-stack structure, a 4-stack structure, a 5-stack structure, or a 6 or more stacked structure which will be described with reference FIG. 6 may also be implemented.

Referring to FIG. 6, as described with reference to FIG. 5, a tandem structure in which a light-emitting structure and a charge generation layer are alternately and repeatedly stacked may be arranged between the first electrode 110 and the second electrode 150.

In one or more embodiments, first to mth light-emitting structures ES1 to ESm may be sequentially stacked from a top surface of the first electrode 110 with a charge generation layer interposed therebetween. The charge generation layer may include a first charge generation layer CGL1 to an (m−1)th charge generation layer CGLm−1 sequentially stacked from the top surface of the first electrode 110.

As illustrated in FIG. 6, the first light-emitting structure ES1, the first charge generation layer CGL1, the second light-emitting structure ES2, the second charge generation layer CGL2, . . . , an (m−1)th light-emitting structure ESm−1, an (m−1)th charge generation layer CGLm−1, an mth light-emitting structure ESm, and the second electrode 150 may be sequentially stacked from the top surface of the first electrode 110.

In one or more embodiments, m is 4, and an intermediate layer of the light-emitting device may have a 4-stack tandem structure, and may include first to fourth light-emitting structures ES1, ES2, ES3, and ES4, and first to third charge generation layers CGL1, CGL2, and CGL3. Colors of light generated from the first to fourth light-emitting structures ES1, ES2, ES3, and ES4 may be the same as or different from one another.

In one or more embodiments, the first to fourth light emitting structures ES1, ES2, ES3, and ES4 may include at least one blue light-emitting structure and at least one green-light emitting structure. In a non-limiting example, the first to third light emitting structures ES1, ES2 and ES3 may correspond to the blue light-emitting structure, and the fourth light emitting structure ES4 may correspond to the green-light emitting structure.

In one or more embodiments, m is 5, and an intermediate layer of the light-emitting device may have a 5-stack tandem structure, and may include first to fifth light-emitting structures ES1, ES2, ES3, ES4, and ES5, and first to fourth charge generation layers CGL1, CGL2, CGL3, and CGL4. Colors of light generated from the first to fifth light-emitting structures ES1, ES2, ES3, ES4, and ES5 may be the same as or different from one another.

In one or more embodiments, the first to fifth light-emitting structures ES1, ES2, ES3, ES4, and ES5 may include at least one blue light emitting structure and at least one green light emitting structure. In a non-limiting example, the first to fifth light-emitting structures ES1, ES2, ES3, ES4, and ES5 may include three blue light-emitting structures and two green light-emitting structures. For example, in one or more embodiments, the first, third, and fifth light-emitting structures ES1, ES3 and ES5 may each correspond to the blue light-emitting structure, and the second and fourth light-emitting structures ES2 and ES4 may each correspond to the green light-emitting structure.

### Electronic Device

The above-described light-emitting device ED may be applied to an electronic device and may be provided as a light-emitting portion or a light-emitting unit of the electronic device.

The electronic device may include a light-emitting device (ED) including the polycyclic compound of Chemical Formula 1 described above, thereby providing improved color properties, luminous efficiency, and life-span properties.

In one or more embodiments, the electronic device may further include, e.g., a functional layer arranged on the light-emitting device, and may include a sensor layer, a polarizing layer, a color conversion layer, a color filter layer, or a combination of at least two thereof.

Non-limiting examples of the electronic device may include a display device, a billboard, a signboard, a light source, a lighting device, a personal computer such as a laptop computer or a desktop computer, a mobile phone, an electronic book, an electronic dictionary, an electronic notebook, a health-care device including a diagnostic device and one or more suitable sensors, one or more suitable display parts for transportation apparatuses (automobile, aircraft, ship, train, and/or the like).

In one or more embodiments, the light-emitting device ED may be applied to an organic light emitting diode (OLED) display device or a quantum dot (QD)-OLED display device.

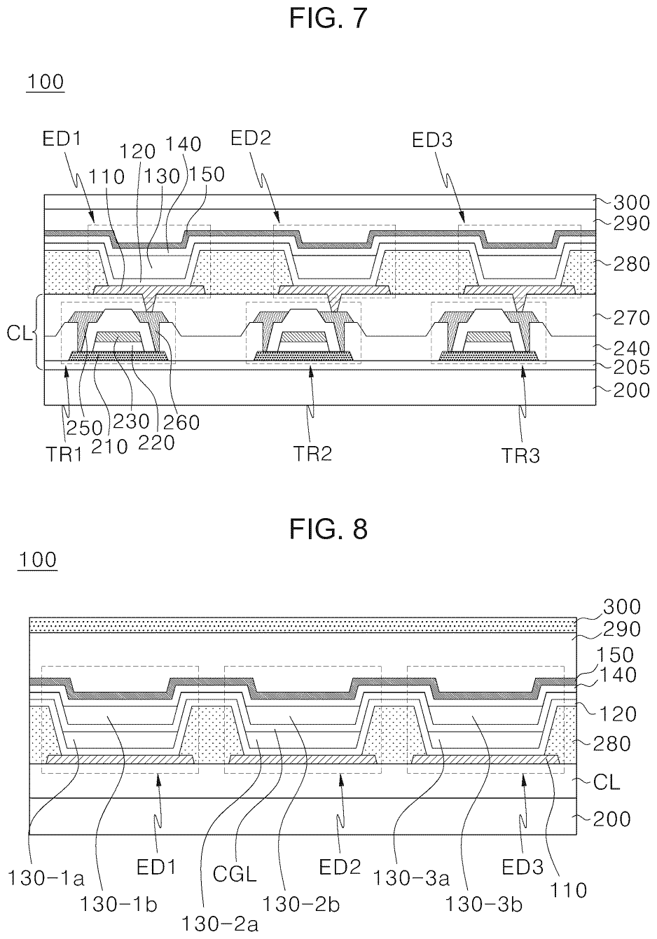

FIG. 7 is a schematic cross-sectional view illustrating a display device in accordance with one or more embodiments of the present disclosure.

Referring to FIG. 7, the display device 100 may include a circuit layer CL arranged on a base substrate 200, and light-emitting devices ED1, ED2, and ED3 each arranged on the circuit layer CL.

The base substrate 200 may serve as a supporting substrate or as a back-plane substrate of the display device. The base substrate 200 may be a glass substrate or a plastic substrate.

In one or more embodiments, the base substrate 200 may include a polymer material having transparent and flexible properties. If (e.g., when) the base substrate 200 includes a polymer material, the base substrate 200 may be used in a transparent flexible display device. For example, in one or more embodiments, the base substrate 200 may include a polymer material such as polyimide, polysiloxane, an epoxy resin, an acrylic resin, polyester, and/or the like. In one or more embodiments, the base substrate 200 may include polyimide.

The circuit layer CL may include transistors TR1, TR2, and TR3. The circuit layer CL may include wiring layers and insulating layers that form a thin film transistor array (TFT-Array).

In one or more embodiments, the circuit layer CL may further include a buffer layer 205 on a top surface of the base substrate 200. The buffer layer 205 may block the penetration of moisture through the base substrate 200, and may also block the diffusion of impurities between the base substrate 200 and the structures formed thereon.

The buffer layer 205 may include, e.g., silicon oxide, silicon nitride, and/or silicon oxynitride. The buffer layer 205 may include one of the aforementioned materials, or a combination thereof. In one or more embodiments, the buffer layer 205 may have a stacked structure that includes a silicon oxide layer and a silicon nitride layer.

The transistors TR1, TR2, and TR3 may be arranged on the buffer layer 205. A first transistor TR1, a second transistor TR2, and a third transistor TR3 may be electrically connected to a first light-emitting device ED1, a second light-emitting device ED2, and a third light-emitting device ED3, respectively.

The transistors TR1, TR2 and TR3 may each include an active layer 210, a gate insulation layer 220, and a gate electrode 230.

The active layer 210 may be arranged on the buffer layer 205, and may be patterned for each pixel. In one or more embodiments, the active layer 210 may include a silicon compound such as amorphous silicon or polysilicon. A p-type (kind) dopant or an n-type (kind) dopant may be doped in a region of the active layer 210, and the active layer 210 may include a source region, a drain region, and a channel region.

In one or more embodiments, the active layer 210 may include an oxide semiconductor, such as indium gallium zinc oxide (IGZO), zinc tin oxide (ZTO), or ITZO.

The gate insulation layer 220 may be formed on the active layer 210, and the gate electrode 230 may be stacked on the gate insulation layer 220. As illustrated in FIG. 7, the gate insulation layer 220 may be patterned to partially cover each active layer 210. In one or more embodiments, the gate insulation layer 220 may extend continuously over multiple pixels or light-emitting regions, and may be provided as a common layer for the first, second, and third transistors TR1, TR2, and TR3.

The gate electrode 230 may overlap the channel region of the active layer 210 in a thickness direction.

An insulating interlayer 240 may be formed on the active layer 210 to cover the gate electrode 230 and the gate insulation layer 220. Connection electrodes 250 and 260 which may be in contact with or electrically connected to the active layer 210 may each be arranged on the insulating interlayer 240.

The connection electrodes 250 and 260 may extend through the insulating interlayer 240 to be in contact with or electrically connected to the active layer 210. When the gate insulation layer 220 is provided as a common layer for multiple light-emitting regions, the connection electrodes 250 and 260 may also extend through the gate insulation layer 220.

The connection electrodes 250 and 260 may include a source electrode 250 that may be in contact with or connected to the source region of the active layer 210, and a drain electrode 260 that may be in contact with or connected to the drain region of the active layer 210.

The gate insulation layer 220 and the insulating interlayer 240 may each independently include silicon oxide, silicon nitride, and/or silicon oxynitride, and may each have a stacked structure that includes a silicon oxide layer and a silicon nitride layer.

The gate electrode 230 and the connection electrodes 250 and 260 may each independently include a metal such as Ag, Mg, Al, W, Cu, Ni, Cr, Mo, Ti, Pt, Ta, Nd, Sc, an alloy thereof, or a nitride thereof.

A via insulation layer 270 may be formed on the insulating interlayer 240 to cover the connection electrodes 250 and 260.

The via insulation layer 270 may accommodate a via structure electrically connecting a first electrode 110 and the drain electrode 260. The via insulation layer 270 may serve as a planarization layer of the circuit layer CL. In one or more embodiments, the via insulation layer 270 may include an organic material such as polyimide, an epoxy resin, an acrylic resin, polyester, and/or the like.

The light-emitting devices ED1, ED2, and ED3 may be arranged on the via insulation layer 270. For example, as described with reference to FIGS. 1 to 4, the light-emitting devices ED1, ED2, and ED3 may each include a first electrode 110, a hole transfer region 120, an emission layer 130, an electron transfer region 140, and a second electrode 150 which are sequentially stacked from the via insulation layer 270.

The first electrode 110 may be electrically connected to the respective transistors TR1, TR2, and TR3 or the respective connection electrodes 250 or 260 in the circuit layer CL through the via structure. As illustrated in FIG. 7, in one or more embodiments, the first electrode 110 may be in contact with or connected to the drain electrode 260 to serve as a pixel electrode patterned for each light-emitting region or pixel.

A pixel defining layer 280 may be formed on the via insulation layer 270 to define each light-emitting region or pixel. A blue light-emitting region, a red light-emitting region, and a green light-emitting region may be separated and defined by the pixel defining layer 280, and the light-emitting devices ED1, ED2, and ED3 may respectively correspond to a blue light-emitting device, a red light-emitting device, and a green light-emitting device.

The pixel defining layer 280 may partially cover the first electrode 110 of each light-emitting region.

As illustrated in FIG. 7, the hole transfer region 120 and the electron transfer region 140 may each be provided as a common layer that continuously extends over the pixel defining layer 280 and the first electrodes 110. The emission layer 130 may be formed within each light emitting-region or pixel, and may be separated by the pixel defining layer 280.

In one or more embodiments, the emission layer 130 may also be provided as a common layer that continuously extends over the light emitting-regions or pixels. In one or more embodiments, the hole transfer region 120, the emission layer 130, and the electron transfer region 140 may each be patterned and separately formed for each light-emitting region or pixel.

The second electrode 150 may be provided as a common electrode that continuously extends over the light-emitting regions or the pixels.

An encapsulation layer 290 may be arranged on the pixel defining layer 280 and the light-emitting devices ED1, ED2, and ED3 to protect the light-emitting devices ED1, ED2, and ED3 from moisture and/or oxygen. The encapsulation layer 290 may be a thin film encapsulation (TFE) having a single-layered structure or a multi-layered structure.

The encapsulation layer 290 may include an inorganic layer that includes silicon nitride (SiNₓ), silicon oxide (SiOₓ), indium tin oxide, indium zinc oxide, or any combination thereof; an organic layer that includes polyethylene terephthalate, polyethylene naphthalate, polycarbonate, polyimide, polyethylene sulfonate, polyoxymethylene, polyarylate, hexamethyldisiloxane, an acrylic resin (e.g., polymethylmethacrylate, polyacrylic acid, and/or the like), an epoxy resin (e.g., an aliphatic glycidyl ether (AGE)), or any combination thereof; or a combination of the inorganic layer and the organic layer.

The display device 100 may further include a functional layer 300 arranged on the encapsulation layer 290. The functional layer 300 may include a sensor layer such as a touch sensor layer, an optical layer such as a polarizing layer, a color conversion layer, a color filter layer, a window film, or any combination thereof.

FIG. 8 is a schematic cross-sectional view illustrating a display device in accordance with one or more embodiments of the present disclosure. Detailed descriptions of elements and structures substantially the same as or similar to those described with reference to FIG. 7 are not provided again or simplified herein for conciseness.

Referring to FIG. 8, each of the light-emitting devices ED1, ED2, and ED3 may have a tandem structure, e.g., a 2-stack tandem structure.

In one or more embodiments, the hole transfer region 120 and the electron transfer region 140 may be continuously and commonly formed and included in an intermediate layer of each light-emitting structure. Additionally, a charge generation layer CGL may continuously extend across a plurality of pixels and may be commonly included in the intermediate layer of each light-emitting structure.

The first light-emitting device ED1 may include a first lower emission layer 130-1a arranged between the hole transfer region 120 and the charge generation layer CGL, and a first upper emission layer 130-1b arranged between the charge generation layer CGL and the electron transfer region 140.

The second light-emitting device ED2 may include a second lower emission layer 130-2a arranged between the hole transfer region 120 and the charge generation layer CGL, and a second upper emission layer 130-2b arranged between the charge generation layer CGL and the electron transfer region 140.

The third light-emitting device ED3 may include a third lower emission layer 130-3a arranged between the hole transfer region 120 and the charge generation layer CGL, and a third upper emission layer 130-3b arranged between the charge generation layer CGL and the electron transfer region 140.

The lower and upper emission layers included in each light-emitting structure (i.e., in each light-emitting tandem structure) may generate light of a same color. In one or more embodiments, each of the first lower emission layer 130-1a and the first upper emission layer 130-1b included in the first light-emitting device ED1 may correspond to a red emission layer. Each of the second lower emission layer 130-2a and the second upper emission layer 130-2b included in the second light-emitting device ED2 may correspond to a green emission layer. Each of the third lower emission layer 130-3a and the third upper emission layer 130-3b included in the third light-emitting device ED3 may correspond to a blue emission layer.

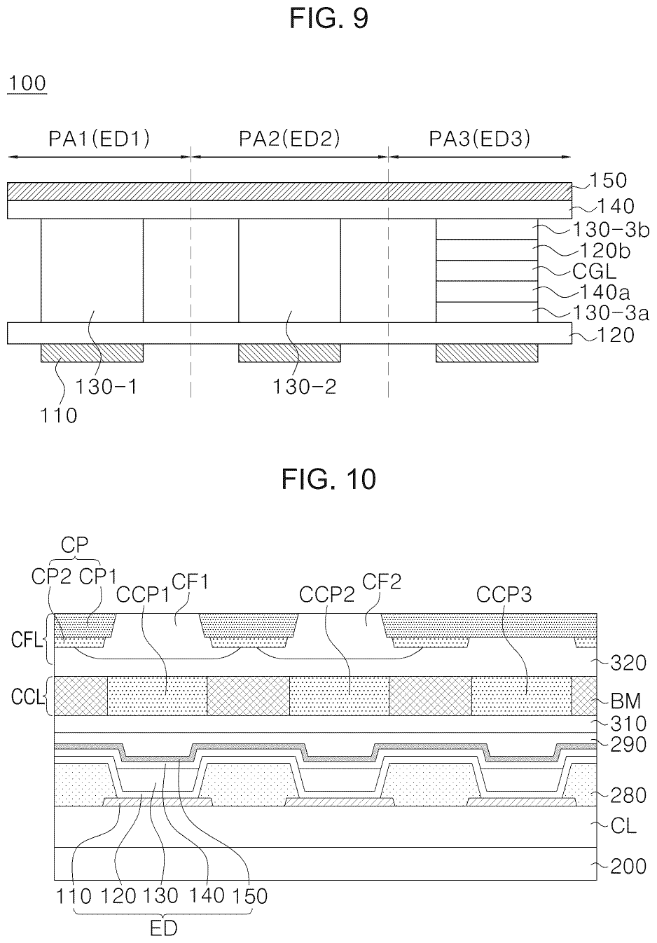

FIG. 9 is a schematic cross-sectional view illustrating a stack construction of light-emitting structure in a display device in accordance with one or more embodiments of the present disclosure. For convenience of illustration and description, illustration of the circuit layer, the base substrate, the pixel defining layer, and/or the like, is omitted from FIG. 9, and a shape of each layer or element in the light-emitting structure is briefly shown as a rectangle.

Referring to FIG. 9, in one or more embodiments, at least one selected from among the light-emitting devices ED1, ED2, and ED3 or selected from among pixel areas PA1, PA2, and PA3 may have a tandem structure including a plurality of emission layers, and at least one selected from among the remainder may have a single emission layer structure.

In one or more embodiments, one selected from among the light-emitting devices ED1, ED2, and ED3 or selected from among the pixel areas PA1, PA2, and PA3 may have a tandem structure, and the remainder may each have a single emission layer structure.

As illustrated in FIG. 9, the first light-emitting device ED1, the second light-emitting device ED2, and the third light-emitting device ED3 may be included in the first pixel area PA1, the second pixel area PA2, and the third pixel area PA3, respectively. In one or more embodiments, the first pixel area PA1, the second pixel area PA2, and the third pixel area PA3 may correspond to a red pixel area, a green pixel area, and a blue pixel area, respectively.

The hole transfer region 120, the electron transfer region 140, and the second electrode 150 may each be provided as a common layer continuously extending over the first pixel area PA1, the second pixel area PA2, and the third pixel area PA3.

The first light-emitting device ED1 included in the first pixel area PA1 may include a first emission layer 130-1, and the second light-emitting device ED2 included in the second pixel area PA2 may include a second emission layer 130-2. Each of the first emission layer 130-1 and the second emission layer 130-2 may be a single-layered emission layer.

The third light-emitting device ED3 included in the third pixel area PA3 may have, e.g., a 2-stack tandem structure. The third light-emitting device ED3 may include a third lower emission layer 130-3a and a third upper emission layer 130-3b separated with a charge generation layer CGL interposed therebetween. For example, each of the third lower emission layer 130-3a and the third upper emission layer 130-3b may correspond to a blue emission layer.

A lower electron transfer region 140a may be arranged between the charge generation layer CGL and the third lower emission layer 130-3a. An upper hole transfer region 120b may be arranged between the charge generation layer CGL and the third upper emission layer 130-3b.

Accordingly, a tandem light-emitting structure in which the first electrode 110, the hole transfer region 120, the third lower emission layer 130-3a, the lower electron transfer region 140a, the charge generation layer CGL, the upper hole transfer region 120b, the third upper emission layer 130-3b, the electron transfer region 140, and the second electrode 150 are sequentially stacked may be arranged in the third pixel area PA3.

FIG. 10 is a schematic cross-sectional view illustrating a display device in accordance with one or more embodiments of the present disclosure.

FIG. 10 illustrates a display device having a QD-OLED structure according to one or more embodiments. Detailed descriptions regarding elements and structures that are the same as or substantially similar to those described with reference to FIG. 7 will not be repeated here for conciseness.

Referring to FIG. 10, the pixel defining layer 280 and the light-emitting device ED may be arranged on the circuit layer CL, as described above with reference to FIG. 7. In one or more embodiments, each pixel may be to emit light of the same wavelength region. In one or more embodiments, each light-emitting device ED may be to emit a blue light.

In one or more embodiments, each light-emitting region may include the light-emitting device having the tandem structure, as described above with respect to FIG. 5. In these embodiments, the intermediate layer of each light-emitting device ED may be provided as a common layer that continuously extends over a plurality of the light-emitting regions.

A color control layer CCL may be arranged on the encapsulation layer 290, and the color control layer CCL may include color control portions CCP1, CCP2, and CCP3.

The color control portions CCP1, CCP2, and CCP3 may each include a light transformer such as a quantum dot and/or a phosphor. In each of the color control portions CCP1, CCP2, and CCP3, the light transformer may convert a wavelength of a provided light and emit a resulting light.

The color control portions CCP1, CCP2, and CCP3 may be separated or spaced and/or apart from one another by a bank BM. The bank BM may substantially overlap the pixel defining layer 280, and the color control portions CCP1, CCP2, and CCP3 may substantially overlap each of the emission layers 130.

The color control layer CCL may include a first color control portion CCP1 including a first quantum dot that converts a first color light provided from the light-emitting device ED into a second color light, a second color control portion CCP2 including a second quantum dot that converts the first color light into a third color light, and a third color control portion CCP3 that transmits the first color light.

In one or more embodiments, the first color light, the second color light, and the third color light may be a blue light, a red light, and a green light, respectively. The first quantum dot and the second quantum dot may respectively be a red quantum dot and a green quantum dot.

The color control portions CCP1, CCP2, and CCP3 may each further include a scattering material such as inorganic particles. The third color control portion CCP3 may not include (e.g., may exclude) quantum dots and may include the scattering material. The scattering material may include TiO₂, ZnO, Al₂O₃, SiO₂, hollow silica, and/or the like. The scattering material may be one of the aforementioned materials or a combination thereof.

The color control portions CCP1, CCP2, and CCP3 may each further include a binder resin that disperses the quantum dot and the scattering material. The binder resin may include an acrylic resin, a urethane resin, a silicone resin, an epoxy resin, and/or the like.

A color filter layer CFL that includes color filters CF1 and CF2 and a light-shielding portion CP may be arranged on the color control layer CCL.

The color filter layer CFL may include a first filter CF1 that transmits the second color light, a second filter CF2 that transmits the third color light, and a third filter that transmits the first color light. For example, the first filter CF1 may be a red filter, the second filter CF2 may be a green filter, and the third filter may be a blue filter.

The color filters CF1 and CF2 may each include a photosensitive binder resin and a colorant including a pigment and/or a dye. The first filter CF1 may include a red pigment and/or a red dye, and the second filter CF2 may include a green pigment and/or a green dye.

The light-shielding portion CP may be arranged between the color filters. In one or more embodiments, the light-shielding portion CP may include a first light-shielding portion CP1 and a second light-shielding portion CP2 that includes colorants of different colors.

In one or more embodiments, the first light-shielding portion CP1 may include a blue colorant, and the second light-shielding portion CP2 may include a red colorant or a black colorant. In one or more embodiments, in the blue light-emitting region, a portion of the first light-shielding portion CP1 may be provided as a blue color filter and may be exposed between the second light-shielding portions CP2, so that an additional color filter (e.g., the third filter) may not be provided.

A first barrier layer 310 may be arranged between the color control layer CCL and the light-emitting device ED (or the encapsulation layer 290). A second barrier layer 320 may be arranged between the color control layer CCL and the color filter layer CFL.

The barrier layers 310 and 320 may each include at least one inorganic layer. For example, the barrier layers 310 and 320 may each independently include silicon nitride, aluminum nitride, zirconium nitride, titanium nitride, hafnium nitride, tantalum nitride, silicon oxide, aluminum oxide, titanium oxide, tin oxide, cerium oxide, silicon oxynitride, and/or the like.

In one or more embodiments, the barrier layers 310 and 320 may each have a multi-layered structure that further includes an organic layer.

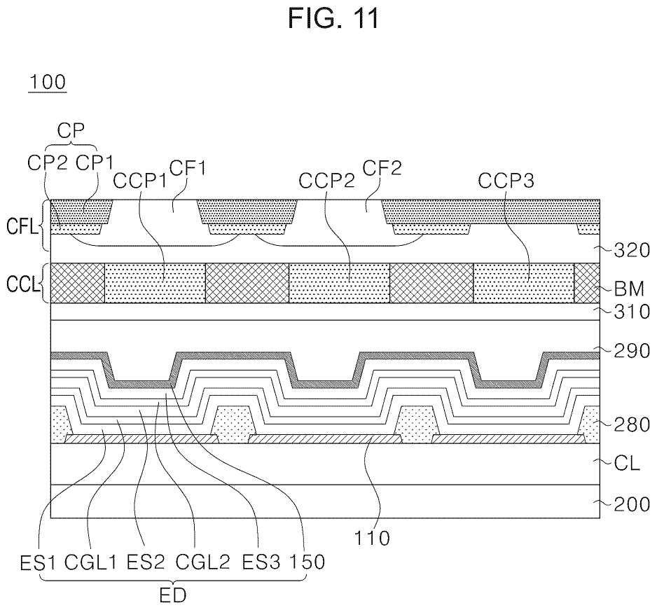

FIG. 11 is a schematic cross-sectional view illustrating a display device in accordance with one or more embodiments. Detailed descriptions of elements and structures substantially the same as or similar to those described with reference to FIG. 10 are omitted herein for conciseness.

Referring to FIG. 11, the light-emitting devices ED corresponding to the color control portions CCP1, CCP2, and CCP3 may each be arranged on the first electrode 110 serving as the pixel electrode, and the light-emitting device ED may have a tandem structure.

In one or more embodiments, as described with reference to FIG. 5, the first light-emitting structure ES1, the first charge generation layer CGL1, the second light-emitting structure ES2, the second charge generation layer CGL2, and the third light-emitting structure ES3 may be sequentially stacked between the first electrode 110 and the second electrode 150. In one or more embodiments, the first light-emitting structure ES1, the first charge generation layer CGL1, the second light-emitting structure ES2, the second charge generation layer CGL2, and the third light-emitting structure ES3 may be continuously and commonly formed in a plurality of pixel areas or light-emitting regions.

In one or more embodiments, the first light-emitting structure ES1, the second light-emitting structure ES2, and the third light-emitting structure ES3 may generate different color lights, and the light-emitting device ED may generate a white light (e.g., combined white light). In one or more embodiments, the first light-emitting structure ES1, the second light-emitting structure ES2, and the third light-emitting structure ES3 may all generate blue lights.

In one or more embodiments, as described with reference to FIG. 6, the light-emitting device ED may include a tandem structure of 4-stack, 5-stack, or more of the stacked number.

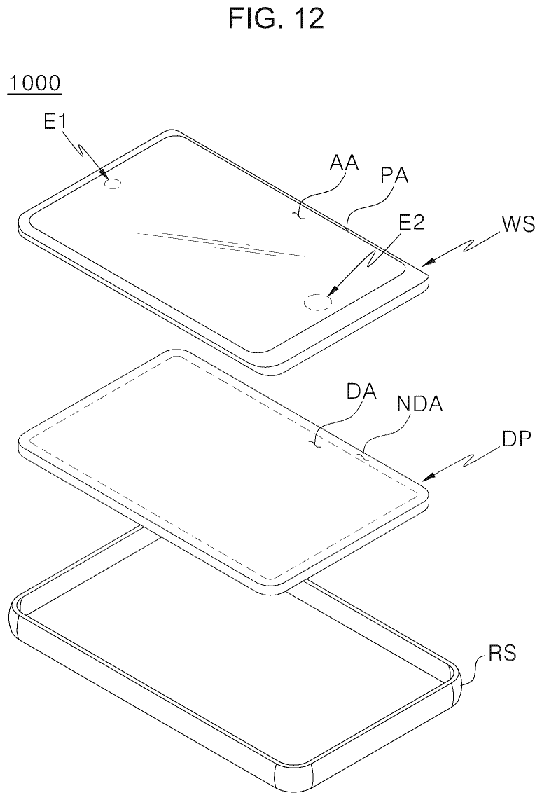

FIG. 12 is a schematic exploded perspective view illustrating an electronic device in accordance with one or more embodiments of the present disclosure.

According to one or more embodiments, the electronic device may be implemented in the form of a mobile phone (smart phone), a tablet, a PC, and/or the like, including the above-described display device.

Referring to FIG. 12, the electronic device 1000 may include a window structure WS, a display panel DP, and a rear structure RS.

The window structure WS may provide an external display surface recognized by a user, such as a viewing surface of a mobile phone, and may include a transparent material film. For example, the window structure WS may include glass (e.g., ultra-thin glass (UTG), a hard coating film, a plastic film, and/or the like.

An outer surface of the window structure WS may include an active area AA and a peripheral area PA. The active area AA may provide a surface from which an image of the display device is substantially displayed and to which a user's touch/command is input. The peripheral area PA may substantially correspond to a bezel area of the display device.

The display panel DP may include the above-described display device and may have a display area DA and a non-display area NDA. The display area DA of the display panel DP may substantially correspond to or overlap the active area AA of the window structure WS. The non-display area NDA of the display panel DP may substantially correspond to or overlap the peripheral area PA of the window structure WS.

In one or more embodiments, functional device areas E1 and E2 may be included in the active area AA of the window structure WS. For example, a first functional device area E1 may be included at one end portion of the active area AA and may be implemented, e.g., in the form of a camera hole. The second functional device area E2 may serve as a fingerprint sensing area.

For example, in one or more embodiments, a sensor structure for a touch sensing or a fingerprint sensing may be arranged in the display panel DP or between the window structure WS and the display panel DP.

The rear structure RS may serve as a frame structure or a housing of the display device or the electronic device 1000. A cover panel may be arranged between the rear structure RS and the display panel DP.

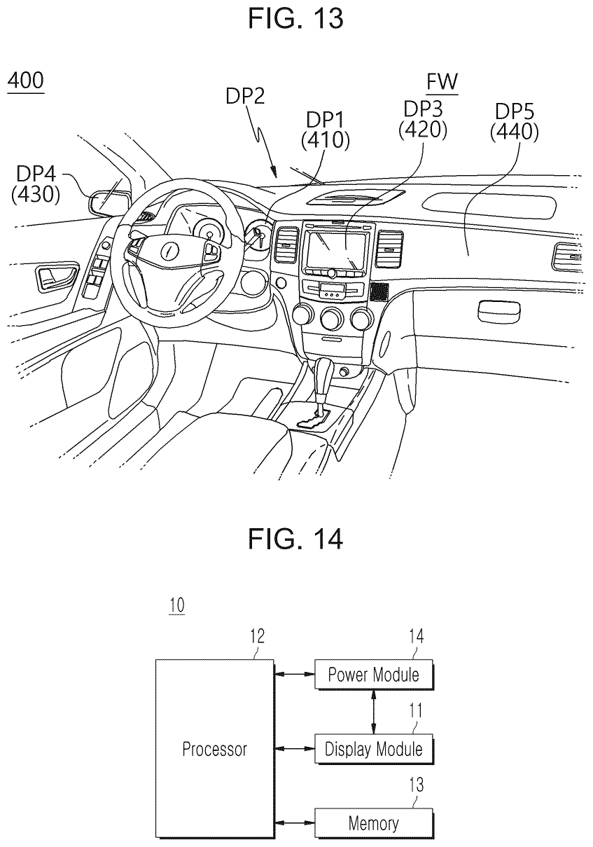

FIG. 13 is a schematic view illustrating an electronic device in accordance with one or more embodiments of the present disclosure.

The electronic device may be installed in, embedded in, attached to, or integrated with a vehicle 400. However, the vehicle 400 is not limited to the embodiment illustrated in FIG. 13. Further examples of the vehicle 400 may include a transportation apparatus such as a three-wheeled or four-wheeled vehicle, a construction machine, a two-wheeled vehicle, a motor vehicle, a bicycle, a train, and/or the like. Other examples of the vehicle 400 may include an electric vehicle, a hybrid vehicle, and/or the like.

Referring to FIG. 13, at least one selected from among first to fifth display devices DP1, DP2, DP3, DP4, and DP5 may be applied to the vehicle 400.

In one or more embodiments, the first display device DP1 may be arranged in a cluster area 410. Driving information such as a driving distance and speed, and one or more suitable warning lights may be displayed in the cluster area 410.

The second display device DP2 may be arranged on a front window FW of the vehicle 400. For example, the second display device DP2 may be installed as a head-up display (HUD).

The third display device DP3 may be arranged on a center fascia 420 of the vehicle 400. In the center fascia 420, a button and/or a switch for controlling an image display or a music player, an air conditioner, a heater, and/or the like, may be displayed, and vehicle information may be displayed thereon.

The fourth display device DP4 may be applied to side mirrors 430 of the vehicle 400. A side mirror 430 may be installed at each of both sides (e.g., two opposite sides) of an exterior of the vehicle 400, and the fourth display device DP4 may be applied to at least one of the side mirrors 430 installed at each of the both sides.

The fifth display device DP5 may be arranged on a passenger seat dashboard 440. Information/image identical to or different from information/image displayed on the cluster area 410 and/or the center fascia 420 may be displayed at the passenger seat dashboard 440.

In one or more embodiments, the electronic device may include, e.g., a flat panel display, a curved display, a computer monitor, a medical monitor, a television, a billboard, an indoor light, an outdoor light, a signal light, a head-up display, a full transparent display, a partial transparent display, a flexible display, a rollable display, a foldable display, a stretchable display, a laser printer, a phone, a mobile phone, a tablet, a phablet, a personal digital assistant (PDA), a wearable device, a laptop computer, a digital camera, a camcorder, a viewfinder, a micro display, a 3D display, a virtual reality display, an augmented reality display, a vehicle, a video wall including multiple displays tiled together, a theater screen, a stadium screen, a phototherapy device, or a signage.

The display device according to one or more embodiments of the present disclosure may be applied to one or more suitable electronic devices. The electronic device according to one or more embodiments includes the above-described display device, and may further include a module or a device having another additional function in addition to the display device.

FIG. 14 is a block diagram of an electronic device in accordance with one or more embodiments of the present disclosure.

Referring to FIG. 14, an electronic device 10 according to one or more embodiments may include a display module 11, a processor 12, a memory 13 and a power module 14.

The processor 12 may include a central processing unit (CPU), an application processor (AP), a graphic processing unit (GPU), a communication processor (CP), an image signal processor (ISP), and/or a controller.

Data information for an operation of the processor 12 and/or the display module 11 may be stored in the memory 13. When the processor 12 executes an application stored in the memory 13, an image data signal and/or an input control signal may be transmitted to the display module 11, and the display module 11 may process the received signal and output image information through a display screen.

The power module 14 may include a power supply module such as a power adapter or a battery device, and a power conversion module that converts a power supplied by the power supply module to generate power desired or required for the operation of the electronic device 10.

At least one selected from among components of the electronic device 10 as described above may be included in the display device according to the above-described embodiments. Additionally, some of individual modules functionally included in one module may be included in the display device, and others may be provided separately from the display device. For example, the display module 11 may include the display device, and the processor 12, the memory 13, and the power module 14 may be provided in the form of another device in the electronic device 10 different from the display device.

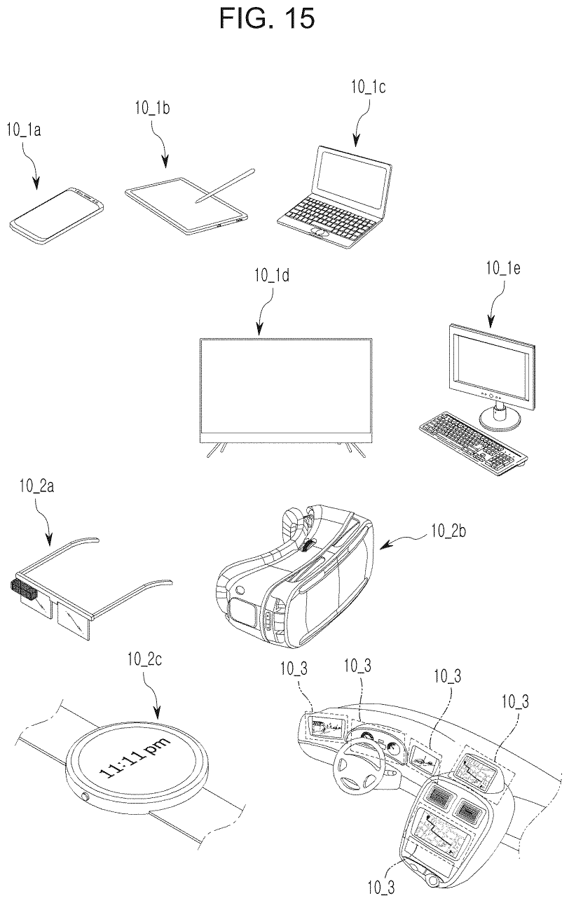

FIG. 15 is a schematic diagram illustrating electronic devices in accordance with one or more embodiments of the present disclosure.

Referring to FIG. 15, non-limiting examples of one or more suitable electronic devices to which the display device according to the above-described embodiments is applied may include an electronic device for displaying an image such as a smartphone 10_1a, a tablet PC 10_b, a laptop 10_1c, a TV 10_1d, a desk monitor 10_1e, and/or the like; a wearable electronic device including a display module such as smart glasses 10_2a, a head mounted display 10_2b, a smart watch 10_2c, and/or the like; a vehicle electronic device 10_3 including a display module such as a center information display (CID) arranged at a vehicle instrument panel, a center fascia, a dashboard, and/or the like, a room mirror display, a head-up display, and/or the like. In one or more embodiments, the electronic device may include a virtual reality glass or an augmented reality glass.

Hereinafter, polycyclic compounds according to one or more embodiments will be described in more detail with reference to the Examples and the Comparative Examples. The Examples are provided to assist in understanding the disclosure, but they are provided as non-limiting examples, and the scope of the disclosure is not limited thereto. It will be clear to those skilled in the art that one or more suitable changes and modifications to disclosed examples can be made within the scope of the disclosure.

### Synthesis Example 1: Synthesis of Compound 1

Compound 1 was synthesized according to a reaction scheme as follows.

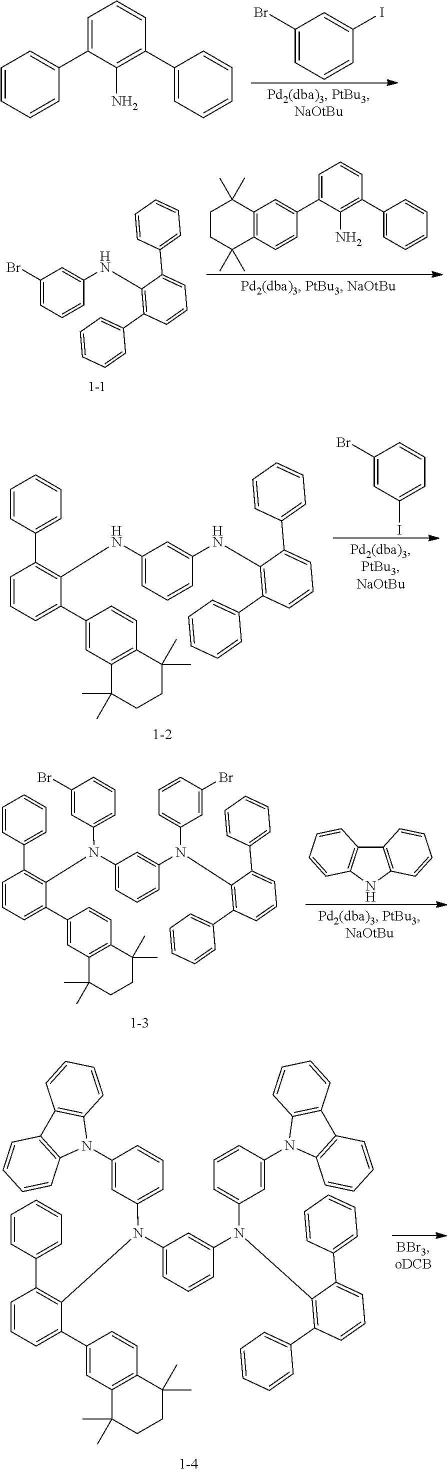

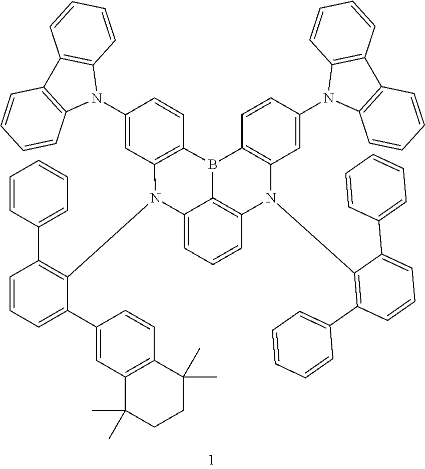 [SMILES: CC1(C)CCC(C)(C)c2cc(-c3cccc(-c4ccccc4)c3N3c4cc(-n5c6ccccc6c6ccccc65)ccc4B4c5ccc(-n6c7ccccc7c7ccccc76)cc5N(c5c(-c6ccccc6)cccc5-c5ccccc5)c5cccc3c54)ccc21]

### 1 Synthesis of Intermediate Compound 1-1

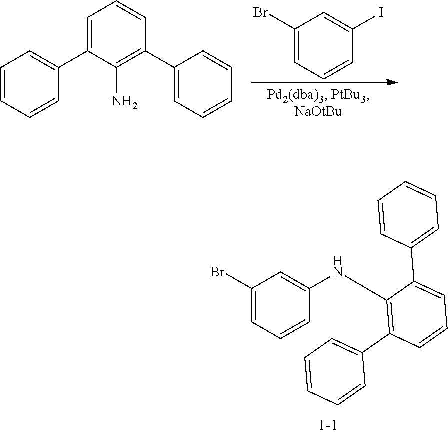 [SMILES: Nc1c(-c2ccccc2)cccc1-c1ccccc1 ; Brc1cccc(I)c1 ; Brc1cccc(Nc2c(-c3ccccc3)cccc2-c2ccccc2)c1]

### 2 Synthesis of Intermediate Compound 1-2

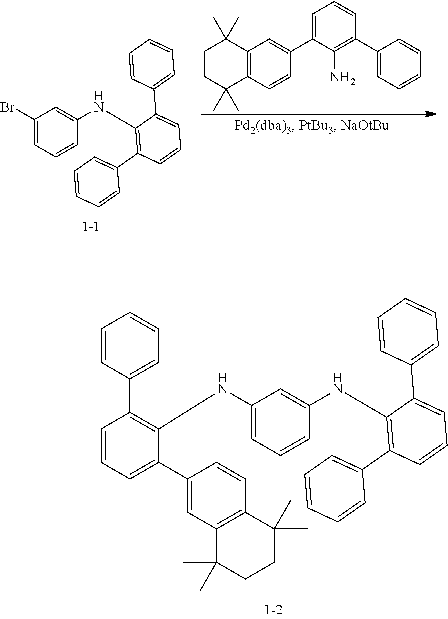

The intermediate compound 1-1 (1 eq), 3-(5,5,8,8-tetramethyl-5,6,7,8-tetrahydronaphthalen-2-yl)-[1,1′-biphenyl]-2-amine (1 eq), Pd₂(dba)₃ (0.05 eq), tri-tert-butylphosphine (0.1 eq), and sodium tert-butoxide (1.5 eq) were dissolved in toluene and stirred at 100° C. for 12 hours. After being cooled, the mixture was diluted with water and washed three times with ethyl acetate. A separated organic layer was dried over anhydrous MgSO₄ and then dried under reduced pressure. An intermediate 1-2 was obtained by purification using a column chromatography (yield: 64%).

### 3 Synthesis of Intermediate Compound 1-3

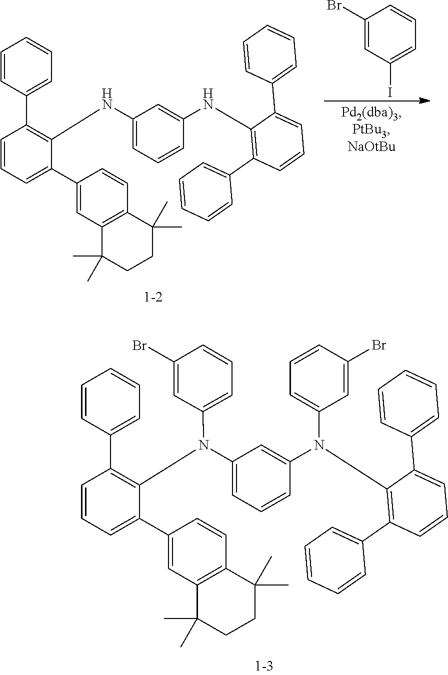 [SMILES: CC1(C)CCC(C)(C)c2cc(-c3cccc(-c4ccccc4)c3Nc3cccc(Nc4c(-c5ccccc5)cccc4-c4ccccc4)c3)ccc21 ; Brc1cccc(I)c1 ; CC1(C)CCC(C)(C)c2cc(-c3cccc(-c4ccccc4)c3N(c3cccc(Br)c3)c3cccc(N(c4cccc(Br)c4)c4c(-c5ccccc5)cccc4-c4ccccc4)c3)ccc21]

The intermediate compound 1-2 (1 eq), 1-bromo-3-iodobenzene (2 eq), Pd₂(dba)₃ (0.05 eq), tri-tert-butylphosphine (0.1 eq), and sodium tert-butoxide (3 eq) were dissolved in toluene and stirred at 110° C. for 12 hours. After being cooled, the mixture was diluted with water and washed three times with ethyl acetate. A separated organic layer was dried over anhydrous MgSO₄ and then dried under reduced pressure. An Intermediate 1-3 was obtained by purification using a column chromatography (yield: 68%).

### 4 Synthesis of Intermediate Compound 1-4

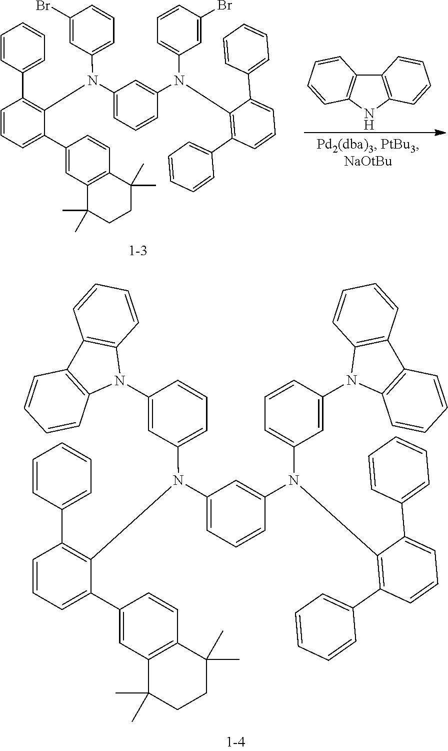

The intermediate compound 1-3 (1 eq), 9H-carbazole (2 eq), Pd₂(dba)₃ (0.05 eq), tri-tert-butylphosphine (0.1 eq), and sodium tert-butoxide (3 eq) were dissolved in toluene and stirred at 110° C. for 12 hours. After being cooled, the mixture was diluted with water and washed three times with ethyl acetate. A separated organic layer was dried over anhydrous MgSO₄ and then dried under reduced pressure. An intermediate compound 1-4 was obtained by purification using a column chromatography (yield: 64%).

### 5 Synthesis of Compound 1

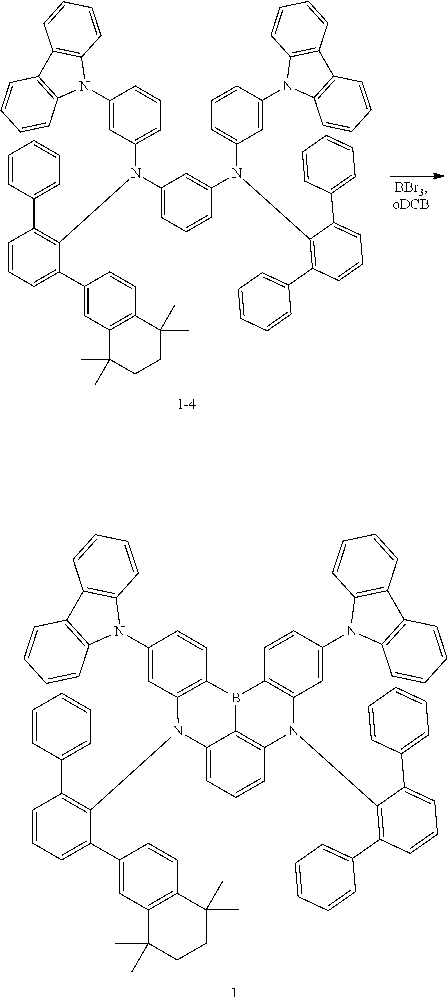 [SMILES: CC1(C)CCC(C)(C)c2cc(-c3cccc(-c4ccccc4)c3N(c3cccc(N(c4cccc(-n5c6ccccc6c6ccccc65)c4)c4c(-c5ccccc5)cccc4-c4ccccc4)c3)c3cccc(-n4c5ccccc5c5ccccc54)c3)ccc21 ; CC1(C)CCC(C)(C)c2cc(-c3cccc(-c4ccccc4)c3N3c4cc(-n5c6ccccc6c6ccccc65)ccc4B4c5ccc(-n6c7ccccc7c7ccccc76)cc5N(c5c(-c6ccccc6)cccc5-c5ccccc5)c5cccc3c54)ccc21]

The intermediate compound 1-4 (1 eq) was dissolved in o-dichlorobenzene (oDCB), cooled to 0° C., and BBr₃ (3 eq) was slowly added under a nitrogen atmosphere. After the addition was completed, the temperature was increased to 180° C. and stirred for 48 hours.

The mixture was cooled, and then triethylamine was slowly dropped into the mixture to terminate the reaction. Thereafter, ethyl alcohol was added, and a product was obtained by precipitation and filtration. The obtained solid was purified by a column chromatography with methylene chloride and n-hexane as an eluent, and Compound 1 was obtained by recrystallization (yield: 2.1%).

The produced compound was confirmed using Mass Spectroscopy/Fast Å tom Bombardment (MS/FAB).

C₈₆H₆₅BN₄ cal. 1164.53, found 1164.54

### Synthesis Example 2: Synthesis of Compound 31

Compound 31 was synthesized according to a reaction scheme as follows.

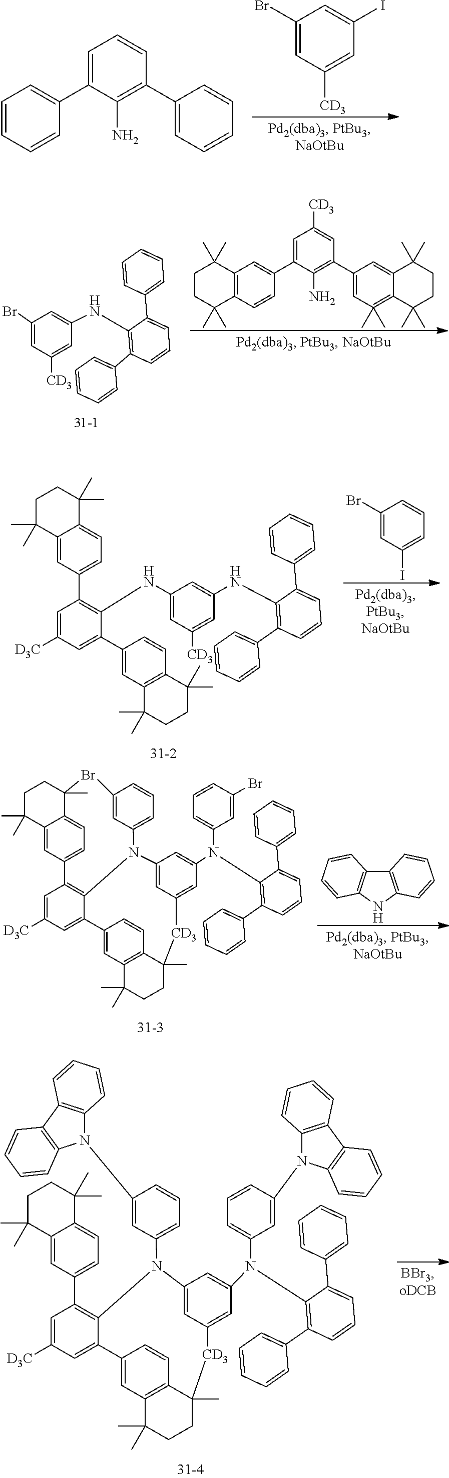

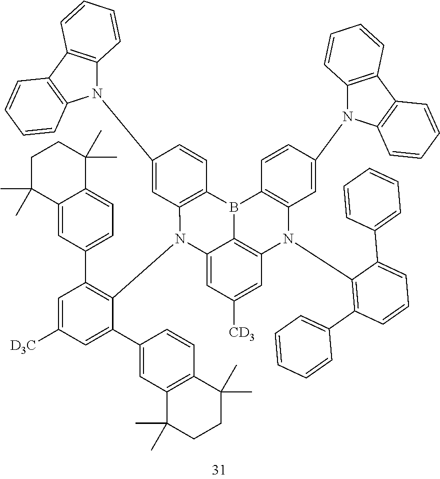 [SMILES: [2H]C([2H])([2H])c1cc(-c2ccc3c(c2)C(C)(C)CCC3(C)C)c(N2c3cc(-n4c5ccccc5c5ccccc54)ccc3B3c4ccc(-n5c6ccccc6c6ccccc65)cc4N(c4c(-c5ccccc5)cccc4-c4ccccc4)c4cc(C([2H])([2H])[2H])cc2c43)c(-c2ccc3c(c2)C(C)(C)CCC3(C)C)c1]

### 1 Synthesis of Intermediate Compound 31-1

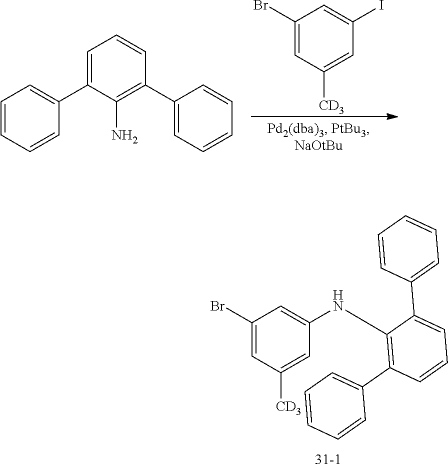 [SMILES: Nc1c(-c2ccccc2)cccc1-c1ccccc1 ; [2H]C([2H])([2H])c1cc(Br)cc(I)c1 ; [2H]C([2H])([2H])c1cc(Br)cc(Nc2c(-c3ccccc3)cccc2-c2ccccc2)c1]

1-bromo-3-iodo-5-(methyl-d₃)benzene (1 eq), [1,1′:3′,1″-terphenyl]-2′-amine (1 eq), Pd₂(dba)₃ (0.05 eq), tri-tert-butylphosphine (0.1 eq), and sodium tert-butoxide (1.5 eq) were dissolved in toluene and stirred at 100° C. for 12 hours. After being cooled, the mixture was diluted with water and washed three times with ethyl acetate. A separated organic layer was dried over anhydrous MgSO₄ and then dried under reduced pressure. An intermediate compound 31-1 was obtained by purification using a column chromatography (yield: 63%)

### 2 Synthesis of Intermediate Compound 31-2

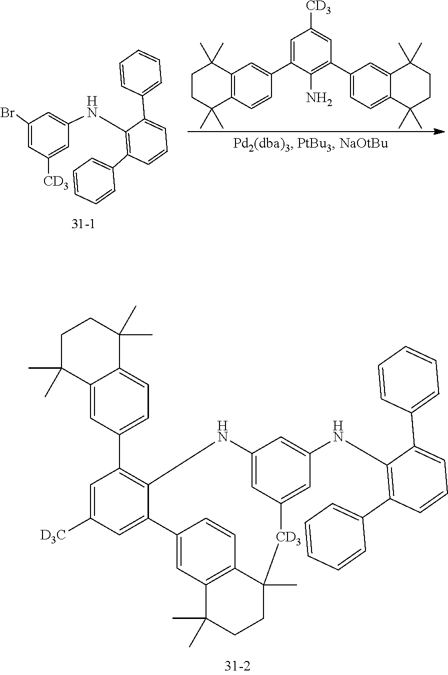

The intermediate compound 31-1 (1 eq), 4-(methyl-ds)-2,6-bis(5,5,8,8-tetramethyl-5,6,7,8-tetrahydronaphthalen-2-yl)aniline (1 eq), Pd₂(dba)₃ (0.05 eq), tri-tert-butylphosphine (0.1 eq), and sodium tert-butoxide (1.5 eq) were dissolved in toluene and stirred at 100° C. for 12 hours. After being cooled, the mixture was diluted with water and washed three times with ethyl acetate. A separated organic layer was dried over anhydrous MgSO₄ and then dried under reduced pressure. An intermediate compound 31-2 was obtained by purification using a column chromatography (yield: 62%).

### 3 Synthesis of Intermediate Compound 31-3

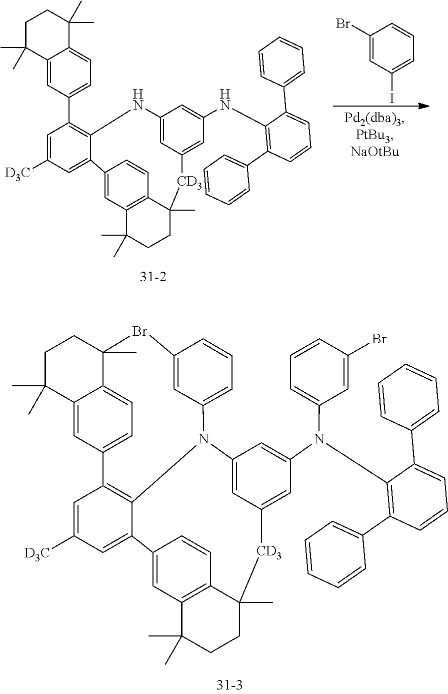

The intermediate compound 31-2 (1 eq), 1-bromo-3-iodobenzene (2 eq), Pd₂(dba)₃ (0.05 eq) Tri-tert-butylphosphine (0.1 eq), and sodium tert-butoxide (3 eq) were dissolved in toluene and stirred at 110° C. for 12 hours. After being cooled, the mixture was diluted with water and washed three times with ethyl acetate. A separated organic layer was dried over anhydrous MgSO₄ and then dried under reduced pressure. An intermediate compound 31-3 was obtained by purification using a column chromatography (yield: 65%).

### 4 Synthesis of Intermediate Compound 31-4

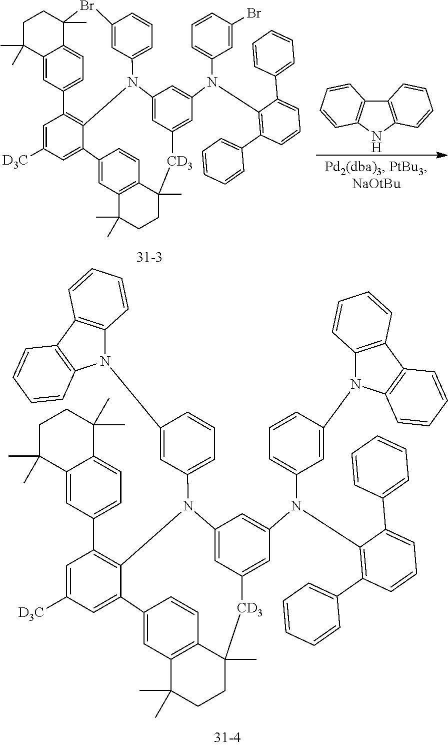

The intermediate compound 31-3 (1 eq), 9H-carbazole (2 eq), Pd₂(dba)₃ (0.05 eq), tri-tert-butylphosphine (0.1 eq), and sodium tert-butoxide (3 eq) were dissolved in toluene and stirred at 110° C. for 12 hours. After being cooled, the mixture was diluted with water and washed three times with ethyl acetate. A separated organic layer was dried over anhydrous MgSO₄ and then dried under reduced pressure. An intermediate compound 31-4 was obtained by purification using a column chromatography (yield: 63%).

### 5 Synthesis of Compound 31

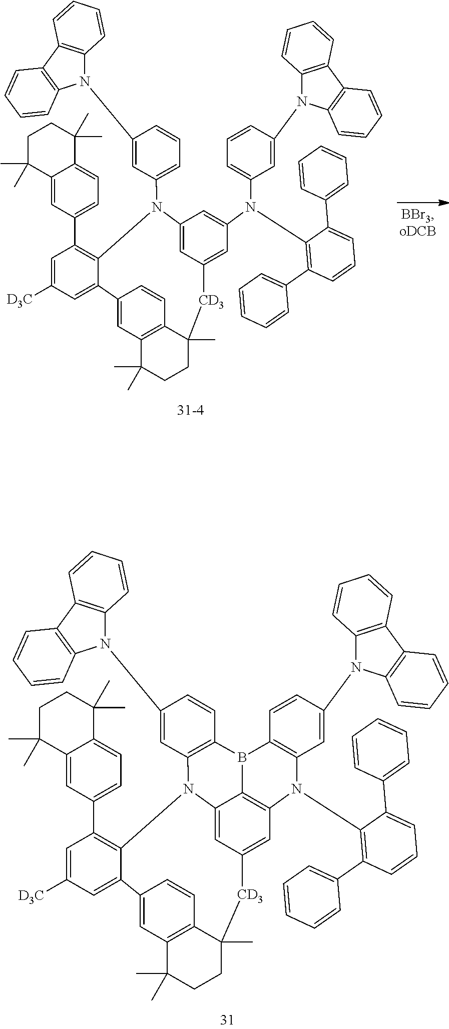 [SMILES: [2H]C([2H])([2H])c1cc(N(c2cccc(-n3c4ccccc4c4ccccc43)c2)c2c(-c3ccccc3)cccc2-c2ccccc2)cc(N(c2cccc(-n3c4ccccc4c4ccccc43)c2)c2c(-c3ccc4c(c3)C(C)(C)CCC4C)cc(C([2H])([2H])[2H])cc2-c2ccc3c(c2)C(C)(C)CCC3(C)C)c1 ; [2H]C([2H])([2H])c1cc(-c2ccc3c(c2)C(C)(C)CCC3C)c(N2c3cc(-n4c5ccccc5c5ccccc54)ccc3B3c4ccc(-n5c6ccccc6c6ccccc65)cc4N(c4c(-c5ccccc5)cccc4-c4ccccc4)c4cc(C([2H])([2H])[2H])cc2c43)c(-c2ccc3c(c2)C(C)(C)CCC3(C)C)c1]

The intermediate compound 31-4 (1 eq) was dissolved in o-dichlorobenzene, cooled to 0° C., and BBr₃ (3 eq) was slowly input in a nitrogen atmosphere. After the addition, the temperature was increased to 180° C. and stirred for 48 hours.

The mixture was cooled, and then triethylamine was slowly dropped to terminate the reaction. Thereafter, ethyl alcohol was added to obtain a product by precipitation and filtration. The obtained solid was purified by a column chromatography with methylene chloride and n-Hexane as an eluent, and Compound 31 was obtained by recrystallization (yield: 1.8%)

The produced compound was confirmed using MS/FAB.

C₉₆H₇₇D₆BN₄ cal. 1308.07, found 1308.09

### Synthesis Example 3: Synthesis of Compound 61

Compound 61 was synthesized according to a reaction scheme as follows.

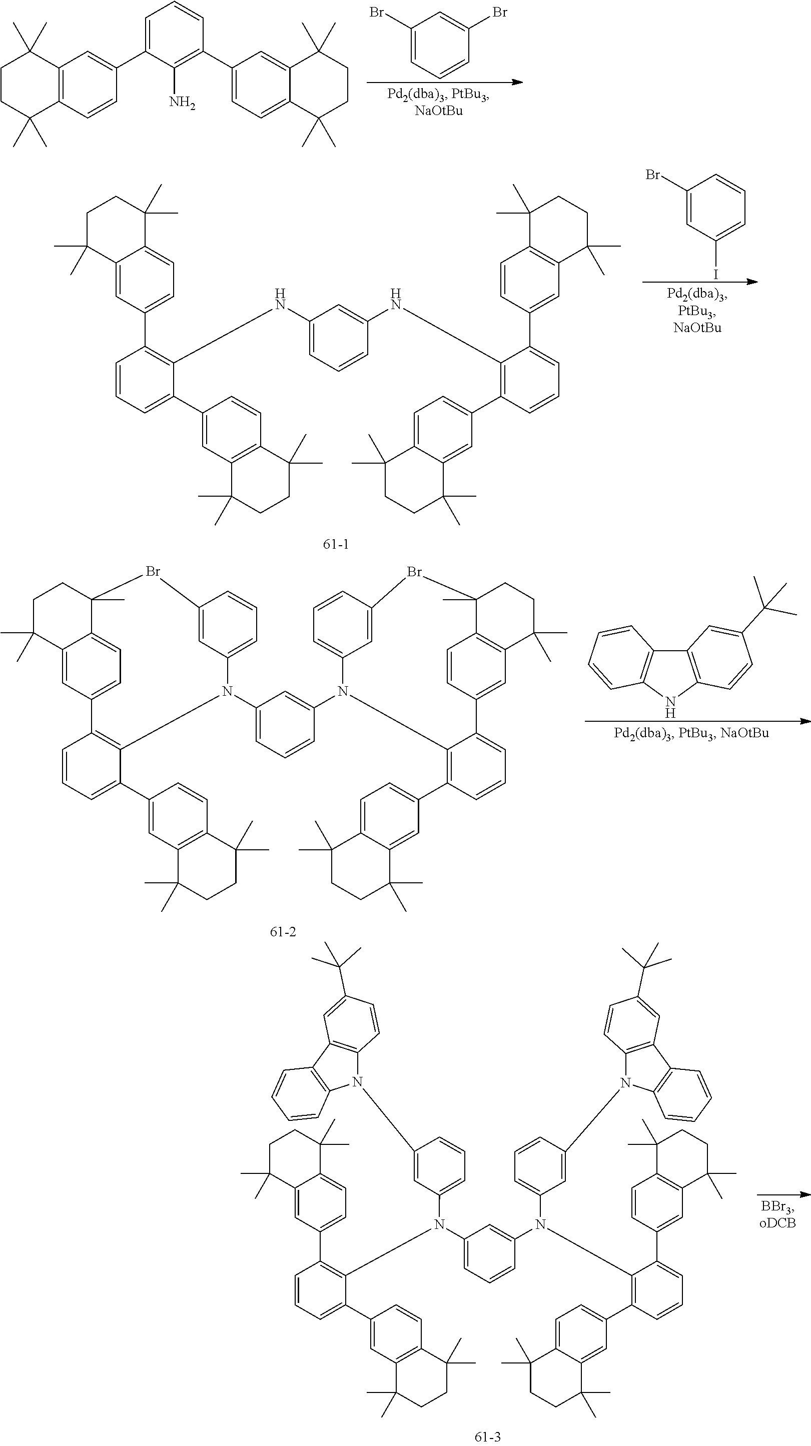

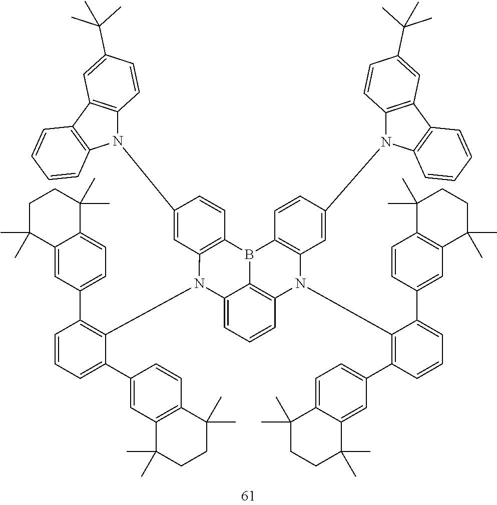

### 1 Synthesis of Intermediate Compound 61-1

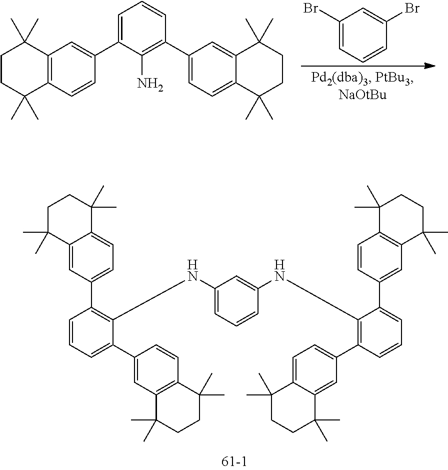

1,3-dibromobenzene (1 eq), 2,6-bis(5,5,8,8-tetramethyl-5,6,7,8-tetrahydronaphthalen-2-yl)aniline (2 eq), Pd₂(dba)₃ (0.05 eq), tri-tert-butylphosphine (0.1 eq), and sodium tert-butoxide (1.5 eq) were dissolved in toluene and stirred at 100° C. for 12 hours. After being cooled, the mixture was diluted with water and washed three times with ethyl acetate. A separated organic layer was dried over anhydrous MgSO₄ and then dried under reduced pressure. An intermediate compound 61-1 was obtained by purification using a column chromatography (yield: 60%).

### 2 Synthesis of Intermediate Compound 61-2

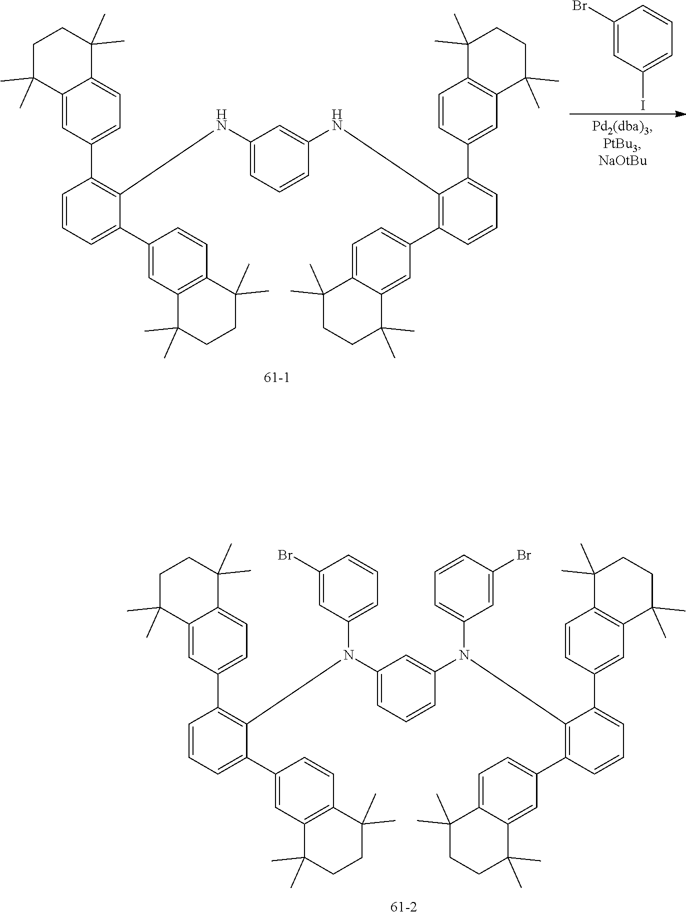

The intermediate compound 61-1 (1 eq), 1-bromo-3-iodobenzene (2 eq), Pd₂(dba)₃ (0.05 eq), Tri-tert-butylphosphine (0.1 eq), and sodium tert-butoxide (3 eq) were dissolved in toluene and stirred at 110° C. for 12 hours. After being cooled, the mixture was diluted with water and washed three times with ethyl acetate. A separated organic layer was dried over anhydrous MgSO₄ and then dried under reduced pressure. An intermediate compound 61-2 was obtained by purification using a column chromatography (yield: 62%).

### 3 Synthesis of Intermediate 61-3

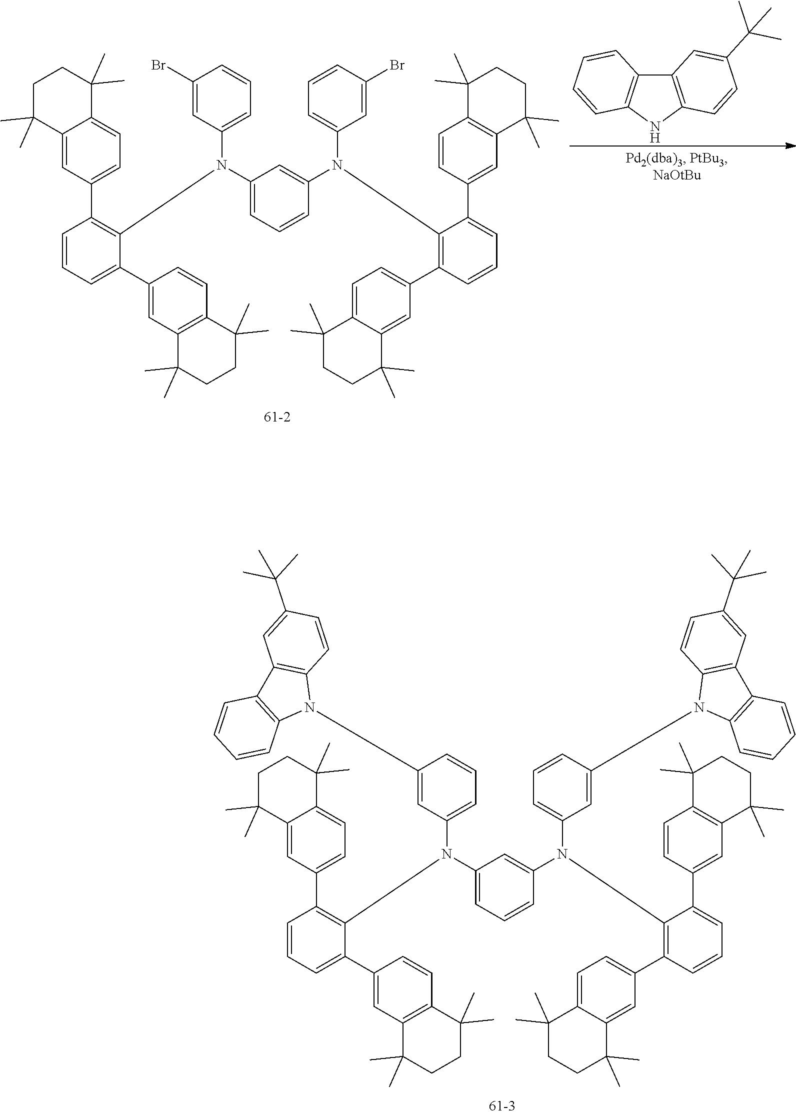

The intermediate compound 61-2 (1 eq), 3-(tert-butyl)-9H-carbazole (2 eq), Pd₂(dba)₃ (0.05 eq), tri-tert-butylphosphine (0.1 eq), and sodium tert-butoxide (3 eq) were dissolved in toluene and stirred at 110° C. for 12 hours. After being cooled, the mixture was diluted with water and washed three times with ethyl acetate. A separated organic layer was dried over anhydrous MgSO₄ and then dried under reduced pressure. An intermediate compound 61-3 was obtained by purification using a column chromatography (yield: 59%).

### 4 Synthesis of Compound 61

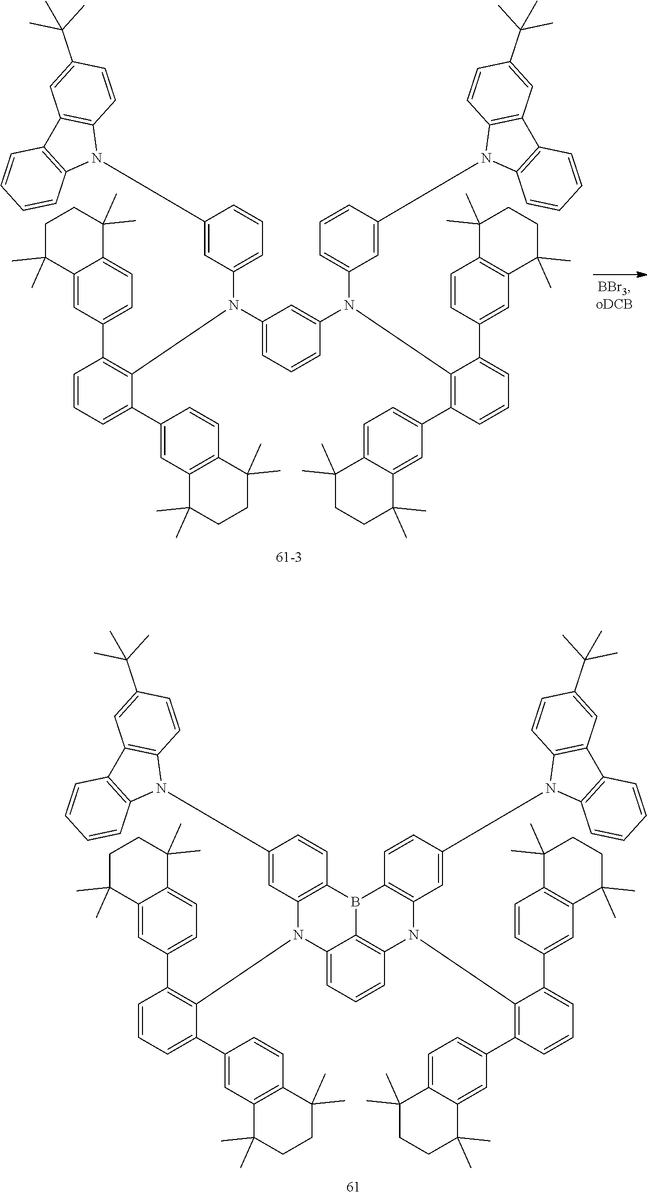 [SMILES: CC(C)(C)c1ccc2c(c1)c1ccccc1n2-c1cccc(N(c2cccc(N(c3cccc(-n4c5ccccc5c5cc(C(C)(C)C)ccc54)c3)c3c(-c4ccc5c(c4)C(C)(C)CCC5(C)C)cccc3-c3ccc4c(c3)C(C)(C)CCC4(C)C)c2)c2c(-c3ccc4c(c3)C(C)(C)CCC4(C)C)cccc2-c2ccc3c(c2)C(C)(C)CCC3(C)C)c1 ; CC(C)(C)c1ccc2c(c1)c1ccccc1n2-c1ccc2c(c1)N(c1c(-c3ccc4c(c3)C(C)(C)CCC4(C)C)cccc1-c1ccc3c(c1)C(C)(C)CCC3(C)C)c1cccc3c1B2c1ccc(-n2c4ccccc4c4cc(C(C)(C)C)ccc42)cc1N3c1c(-c2ccc3c(c2)C(C)(C)CCC3(C)C)cccc1-c1ccc2c(c1)C(C)(C)CCC2(C)C]

The intermediate compound 61-3 (1 eq) was dissolved in o-dichlorobenzene, cooled to 0° C., and BBr₃ (3 eq) was slowly added under a nitrogen atmosphere. After the addition, the temperature was increased to 180° C. and stirred for 48 hours.

The mixture was cooled, triethylamine was slowly dropped to terminate the reaction. Thereafter, ethyl alcohol was added to obtain a product by precipitation and filtration. The obtained solid was purified by a column chromatography with methylene chloride and n-hexane as an eluent, and Compound 61 was obtained by recrystallization (Yield: 1.7%).

The product was confirmed using MS/FAB.

C₁₁₈H₁₂₃BN₄ cal. 1606.98, found 1607.00

### Synthesis Example 4: Synthesis of Compound 111

Compound 111 was synthesized according to a reaction scheme as follows.

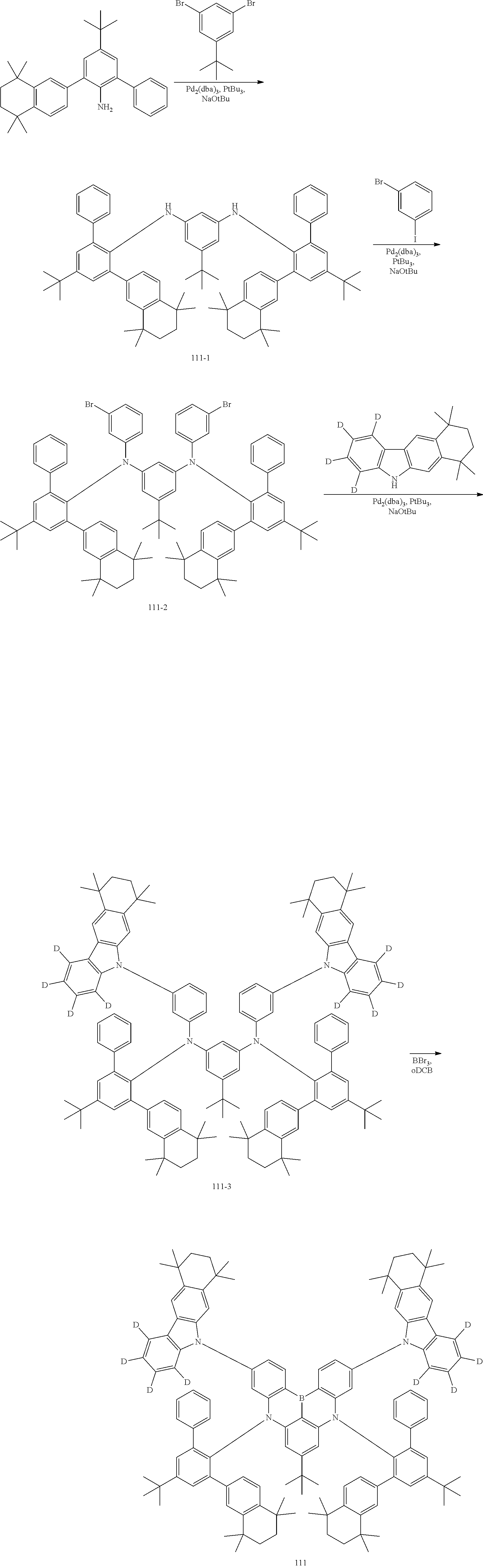

### 1 Synthesis of Intermediate Compound 111-1

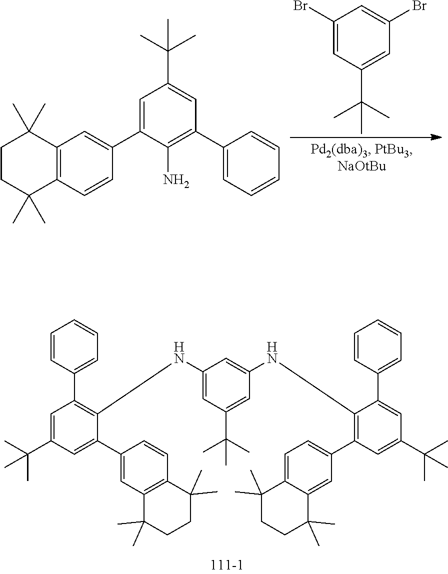 [SMILES: CC(C)(C)c1cc(-c2ccccc2)c(N)c(-c2ccc3c(c2)C(C)(C)CCC3(C)C)c1 ; CC(C)(C)c1cc(Br)cc(Br)c1 ; CC(C)(C)c1cc(Nc2c(-c3ccccc3)cc(C(C)(C)C)cc2-c2ccc3c(c2)C(C)(C)CCC3(C)C)cc(Nc2c(-c3ccccc3)cc(C(C)(C)C)cc2-c2ccc3c(c2)C(C)(C)CCC3(C)C)c1]

1,3-dibromo-5-(tert-butyl)benzene (1 eq), 5-(tert-butyl)-3-(5,5,8,8-tetramethyl-5,6,7,8-tetrahydronaphthalen-2-yl)-[1,1′-biphenyl]-2-amine (2 eq), Pd₂(dba)₃ (0.05 eq), tri-tert-butylphosphine (0.1 eq), and sodium tert-butoxide (1.5 eq) were dissolved in toluene and stirred at 100° C. for 12 hours. After being cooled, the mixture was diluted with water and washed three times with ethyl acetate. A separated organic layer was dried over anhydrous MgSO₄ and then dried under reduced pressure. An intermediate compound 111-1 was obtained by purification using a column chromatography (yield: 59%).

### 2 Synthesis of Intermediate Compound 111-2

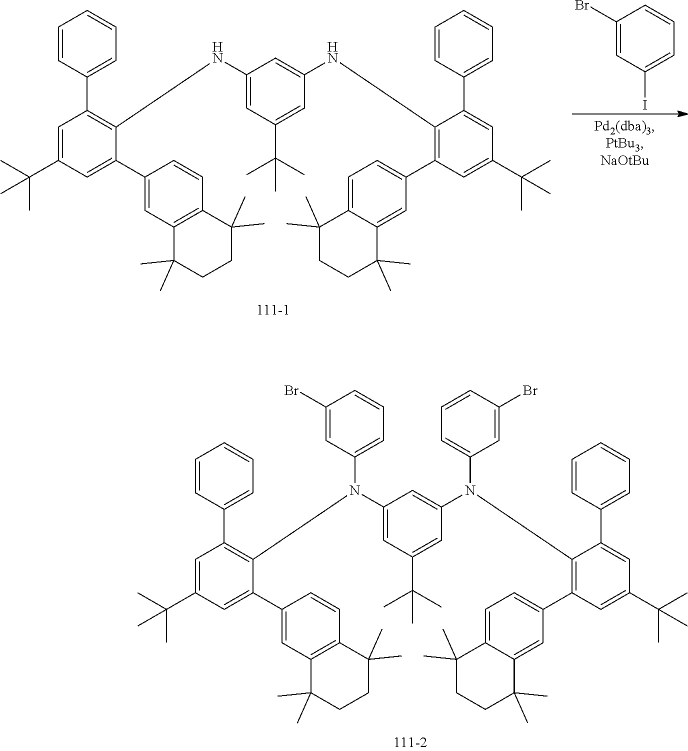

The intermediate compound 111-1 (1 eq), 1-bromo-3-iodobenzene (2 eq), Pd₂(dba)₃ (0.05 eq), tri-tert-butylphosphine (0.1 eq), and sodium tert-butoxide (3 eq) were dissolved in toluene and stirred at 110° C. for 12 hours. After being cooled, the mixture was diluted with water and washed three times with ethyl acetate. A separated organic layer was dried over anhydrous MgSO₄ and then dried under reduced pressure. An intermediate compound 111-2 was obtained by purification using a column chromatography (yield: 62%).

### 3 Synthesis of Intermediate 111-3

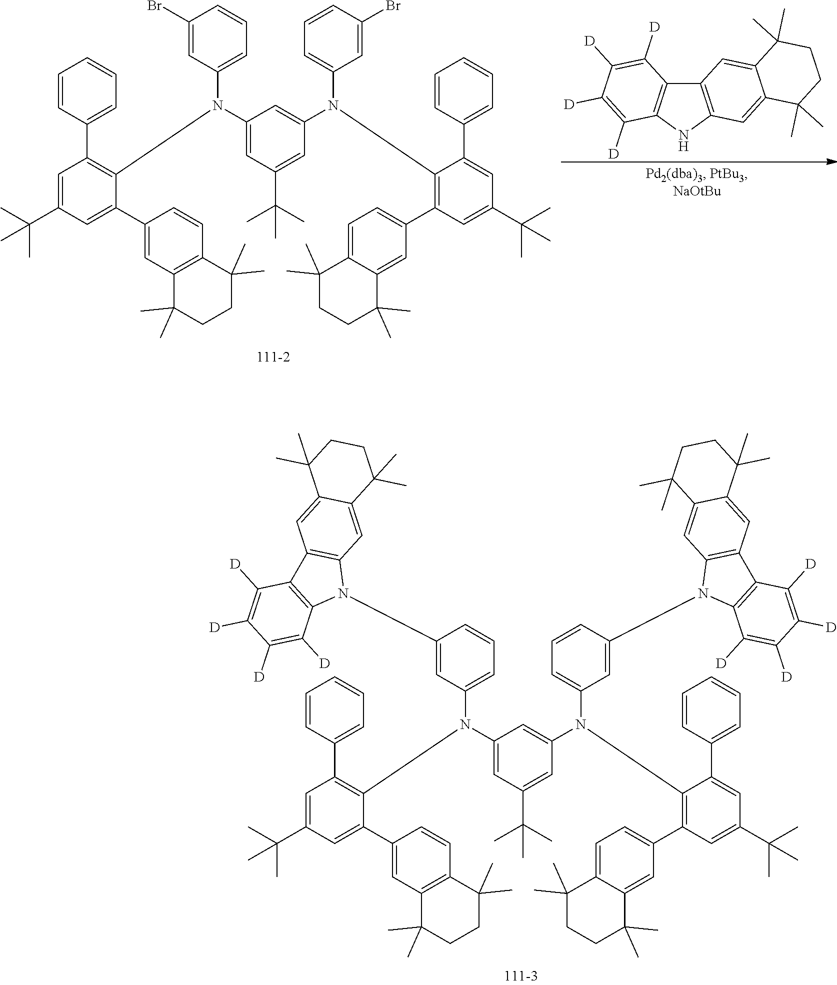

The intermediate compound 111-2 (1 eq), 7,7,10,10-tetramethyl-7,8,9,10-tetrahydro-5H-benzo[b]carbazole-1,2,3,4-d₄ (2 eq), Pd₂(dba)₃ (0.05 eq), tri-tert-butylphosphine (0.1 eq), and sodium tert-butoxide (3 eq) were dissolved in toluene and stirred at 110° C. for 12 hours. After being cooled, the mixture was diluted with water and washed three times with ethyl acetate. A separated organic layer was dried over anhydrous MgSO₄ and then dried under reduced pressure. An intermediate 111-3 was obtained by purification using a column chromatography (yield: 56%).

### 4 Synthesis of Compound 111

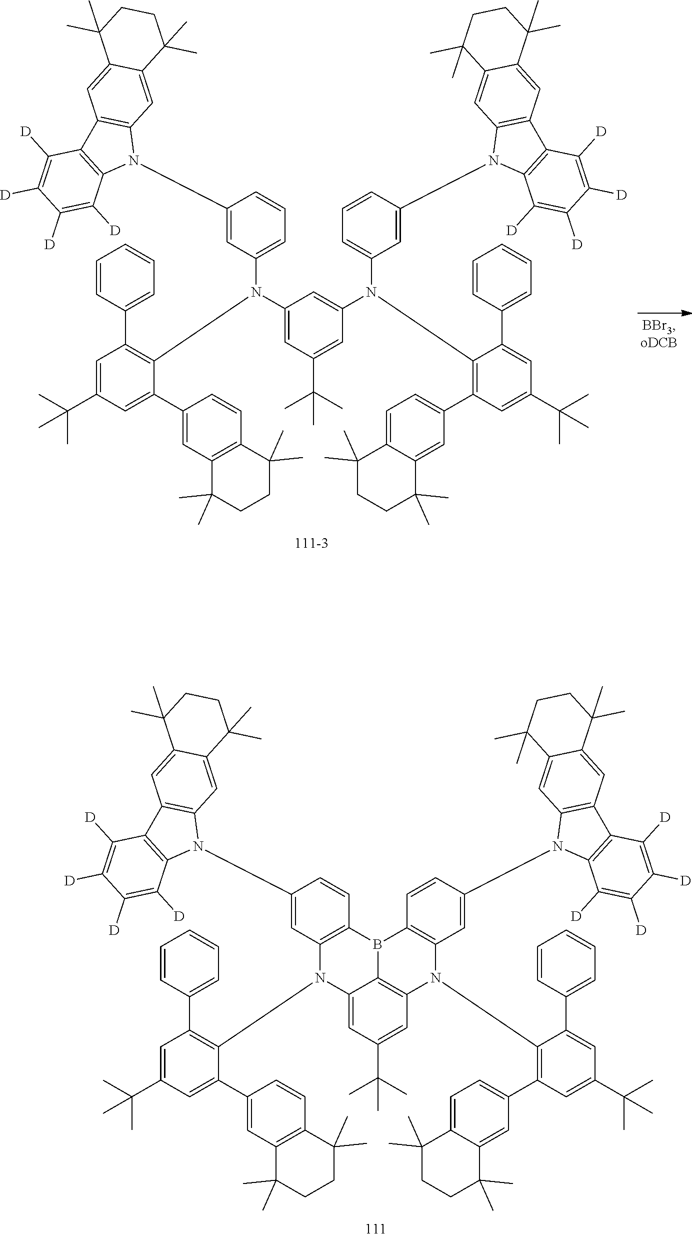

The intermediate compound 111-3 (1 eq) was dissolved in o-dichlorobenzene, cooled to 0° C., and BBr₃ (3 eq) was slowly added under a nitrogen atmosphere. After the addition, the temperature was increased to 180° C. and stirred for 48 hours.

The mixture was cooled, and then triethylamine was slowly dropped to terminate the reaction. Thereafter, ethyl alcohol was added to obtain a product by precipitation and filtration. The obtained solid was purified by a column chromatography with methylene chloride and n-hexane as an eluent, and Compound 111 was obtained by recrystallization (yield: 1.5%).

The produced compound was confirmed using MS/FAB.

C₁₂₂H₁₂₃D₈BN₄ cal. 1671.10, found 1671.09

### Synthesis Example 5: Synthesis of Compound 119

Compound 119 was synthesized according to a reaction scheme as follows.

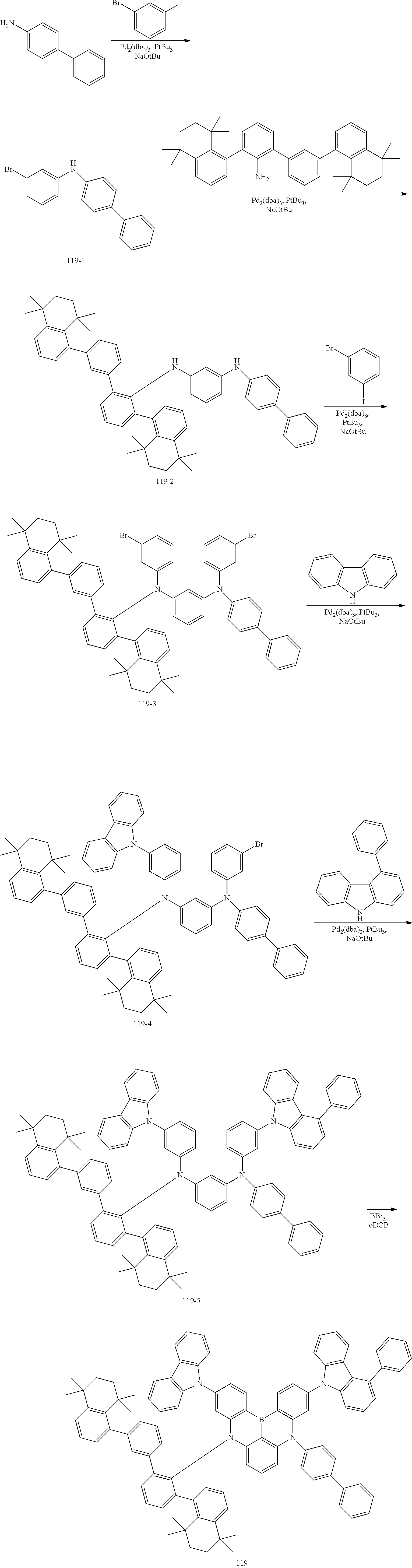

### 1 Synthesis of Intermediate Compound 119-1

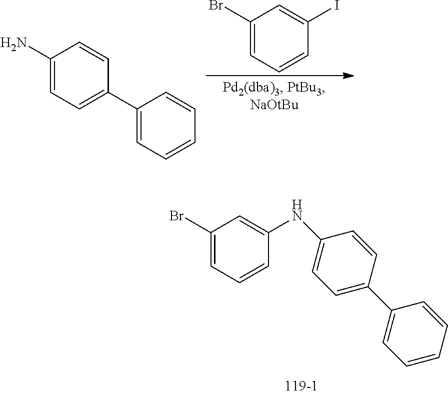 [SMILES: Nc1ccc(-c2ccccc2)cc1 ; Brc1cccc(I)c1 ; Brc1cccc(Nc2ccc(-c3ccccc3)cc2)c1]

1-bromo-3-iodobenzene (1 eq), [1,1′-biphenyl]-4-amine (1 eq), Pd₂(dba)₃ (0.05 eq), tri-tert-butylphosphine (0.1 eq), and sodium tert-butoxide (1.5 eq) were dissolved in toluene and stirred at 100° C. for 12 hours. After being cooled, the mixture was diluted with water and washed three times with ethyl acetate. A separated organic layer was dried over anhydrous MgSO₄ and then dried under reduced pressure. An intermediate compound 119-1 was obtained by purification using a column chromatography (yield: 67%).

### 2 Synthesis of Intermediate 119-2

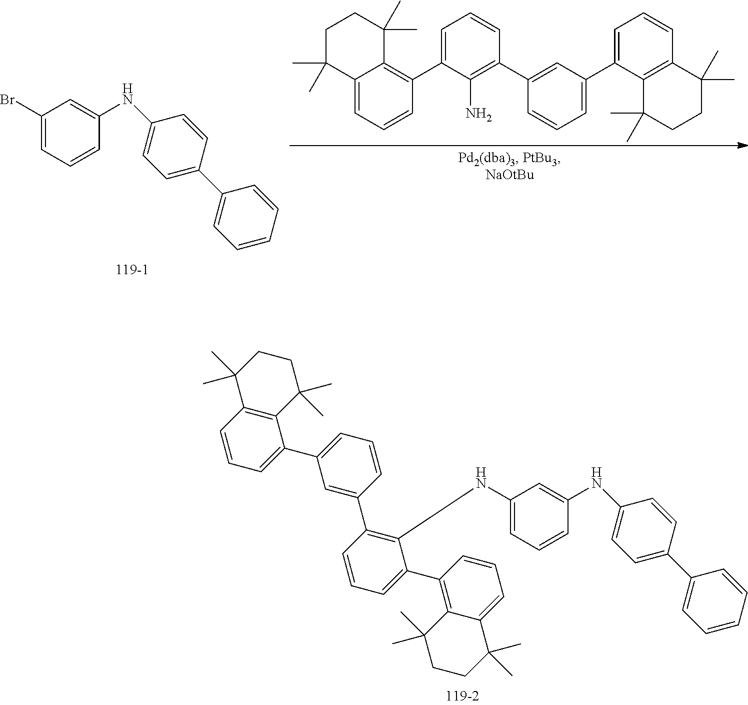

The intermediate compound 119-1 (1 eq), 3,3′-bis(5,5,8,8-tetramethyl-5,6,7,8-tetrahydronaphthalen-1-yl)-[1,1′-biphenyl]-2-amine (1 eq), Pd₂(dba)₃ (0.05 eq), tri-tert-butylphosphine (0.1 eq), and sodium tert-butoxide (1.5 eq) were dissolved in toluene and stirred at 100° C. for 12 hours. After being cooled, the mixture was diluted with water and washed three times with ethyl acetate. A separated organic layer was dried over anhydrous MgSO₄ and then dried under reduced pressure. An intermediate compound 119-2 was obtained by purification using a column chromatography (yield: 63%).

### 3 Synthesis of Intermediate Compound 119-3

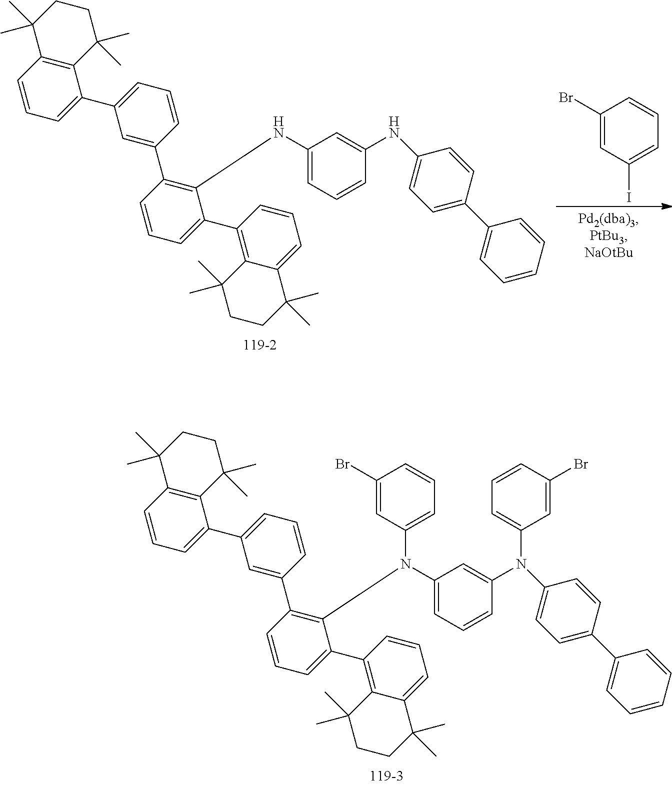 [SMILES: CC1(C)CCC(C)(C)c2c(-c3cccc(-c4cccc(-c5cccc6c5C(C)(C)CCC6(C)C)c4Nc4cccc(Nc5ccc(-c6ccccc6)cc5)c4)c3)cccc21 ; Brc1cccc(I)c1 ; CC1(C)CCC(C)(C)c2c(-c3cccc(-c4cccc(-c5cccc6c5C(C)(C)CCC6(C)C)c4N(c4cccc(Br)c4)c4cccc(N(c5ccc(-c6ccccc6)cc5)c5cccc(Br)c5)c4)c3)cccc21]

The intermediate compound 119-2 (1 eq), 1-bromo-3-iodobenzene (2 eq), Pd₂(dba)₃ (0.05 eq), tri-tert-butylphosphine (0.1 eq), and sodium tert-butoxide (3 eq) were dissolved in toluene and stirred at 110° C. for 12 hours. After being cooled, the mixture was diluted with water and washed three times with ethyl acetate. A separated organic layer was dried over anhydrous MgSO₄ and then dried under reduced pressure. An intermediate compound 119-3 was obtained by purification using a column chromatography (yield: 66%).

### 4 Synthesis of Intermediate Compound 119-4

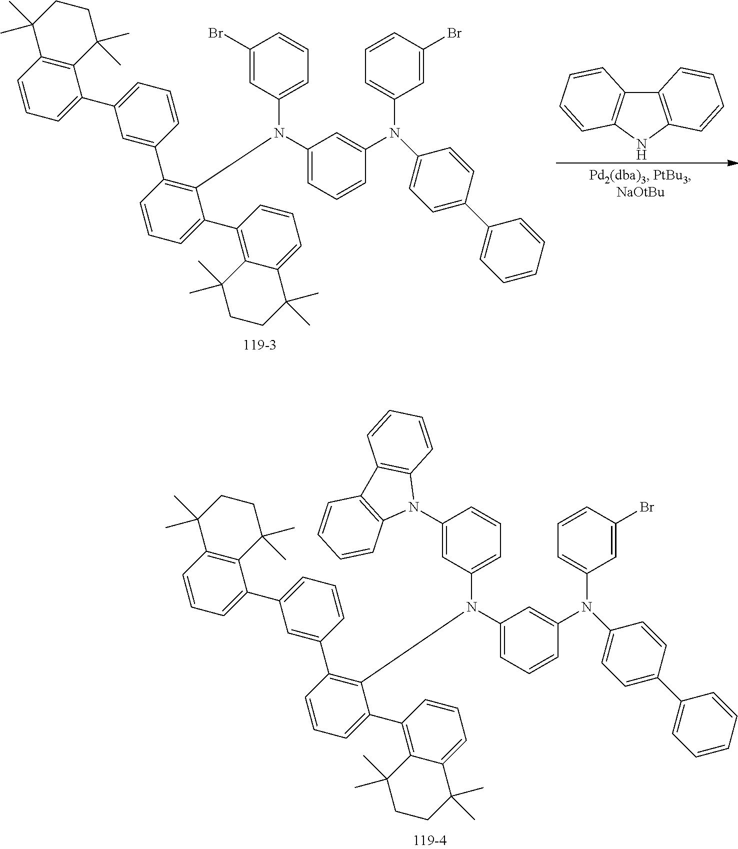 [SMILES: CC1(C)CCC(C)(C)c2c(-c3cccc(-c4cccc(-c5cccc6c5C(C)(C)CCC6(C)C)c4N(c4cccc(Br)c4)c4cccc(N(c5ccc(-c6ccccc6)cc5)c5cccc(Br)c5)c4)c3)cccc21 ; c1ccc2c(c1)[nH]c1ccccc12 ; CC1(C)CCC(C)(C)c2c(-c3cccc(-c4cccc(-c5cccc6c5C(C)(C)CCC6(C)C)c4N(c4cccc(N(c5ccc(-c6ccccc6)cc5)c5cccc(Br)c5)c4)c4cccc(-n5c6ccccc6c6ccccc65)c4)c3)cccc21]

The intermediate compound 119-3 (1 eq), 9H-carbazole (1 eq), Pd₂(dba)₃ (0.05 eq), tri-tert-butylphosphine (0.1 eq), and sodium tert-butoxide (3 eq) were dissolved in toluene and stirred at 110° C. for 12 hours. After being cooled, the mixture was diluted with water and washed three times with ethyl acetate. A separated organic layer was dried over anhydrous MgSO₄ and then dried under reduced pressure. An intermediate compound 119-4 was obtained by purification using a column chromatography (yield: 65%).

### 5 Synthesis of Intermediate 119-5

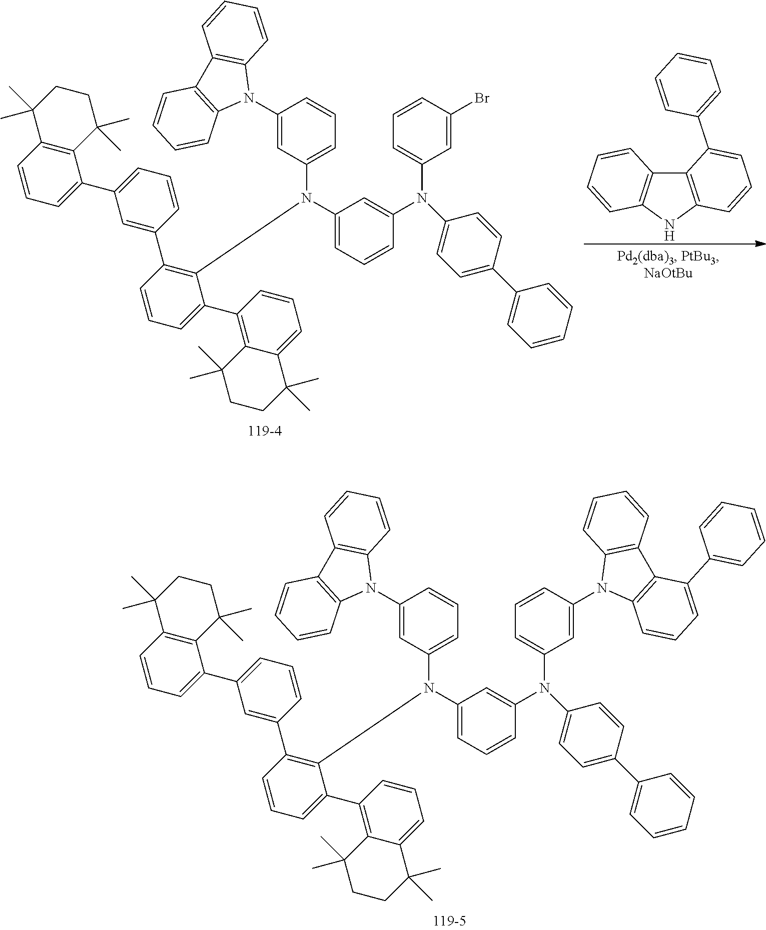 [SMILES: CC1(C)CCC(C)(C)c2c(-c3cccc(-c4cccc(-c5cccc6c5C(C)(C)CCC6(C)C)c4N(c4cccc(N(c5ccc(-c6ccccc6)cc5)c5cccc(Br)c5)c4)c4cccc(-n5c6ccccc6c6ccccc65)c4)c3)cccc21 ; c1ccc(-c2cccc3[nH]c4ccccc4c23)cc1 ; CC1(C)CCC(C)(C)c2c(-c3cccc(-c4cccc(-c5cccc6c5C(C)(C)CCC6(C)C)c4N(c4cccc(N(c5ccc(-c6ccccc6)cc5)c5cccc(-n6c7ccccc7c7c(-c8ccccc8)cccc76)c5)c4)c4cccc(-n5c6ccccc6c6ccccc65)c4)c3)cccc21]

The intermediate compound 119-4 (1 eq) 4-phenyl 9H-carbazole (1 eq), Pd₂(dba)₃ (0.05 eq), tri-tert-butylphosphine (0.1 eq), and sodium tert-butoxide (3 eq) were dissolved in toluene and stirred at 110° C. for 12 hours. After being cooled, the mixture was diluted with water and washed three times with ethyl acetate. A separated organic layer was dried over anhydrous MgSO₄ and then dried under reduced pressure. An intermediate compound 119-5 was obtained by purification using a column chromatography (yield: 63%).

### Synthesis of Compound 119

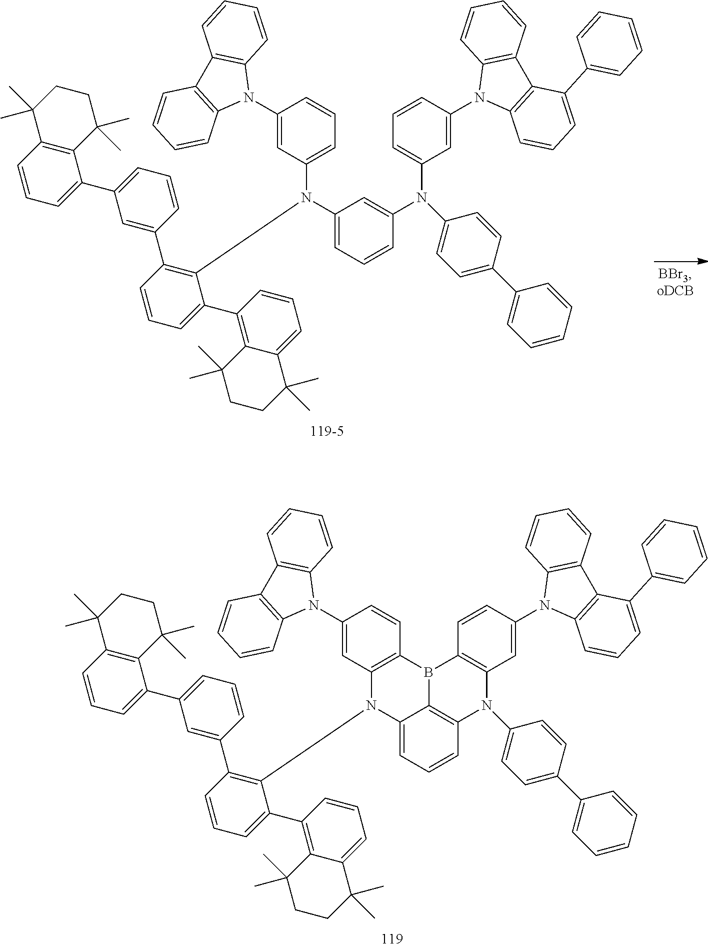 [SMILES: CC1(C)CCC(C)(C)c2c(-c3cccc(-c4cccc(-c5cccc6c5C(C)(C)CCC6(C)C)c4N(c4cccc(N(c5ccc(-c6ccccc6)cc5)c5cccc(-n6c7ccccc7c7c(-c8ccccc8)cccc76)c5)c4)c4cccc(-n5c6ccccc6c6ccccc65)c4)c3)cccc21 ; CC1(C)CCC(C)(C)c2c(-c3cccc(-c4cccc(-c5cccc6c5C(C)(C)CCC6(C)C)c4N4c5cc(-n6c7ccccc7c7ccccc76)ccc5B5c6ccc(-n7c8ccccc8c8c(-c9ccccc9)cccc87)cc6N(c6ccc(-c7ccccc7)cc6)c6cccc4c65)c3)cccc21]

The intermediate compound 119-5 (1 eq) was dissolved in o-dichlorobenzene, cooled to 0° C., and BBr₃ (3 eq) was slowly added under a nitrogen atmosphere. After the addition, the temperature was increased to 180° C. and stirred for 48 hours.

The mixture was cooled, and then triethylamine was slowly dropped to terminate the reaction. Thereafter, ethyl alcohol was added to obtain a product by precipitation and filtration. The obtained solid was purified by a column chromatography with methylene chloride and n-hexane as an eluent, and Compound 119 was obtained by recrystallization (Yield: 1.7%).

The produced compound was confirmed through MS/FAB.

C₁₀₀H₈₃BN₄ cal. 1350.67, found 1350.66

### Fabrication of Light-Emitting Device

As a first electrode (i.e., anode), a glass substrate (Corning product) on which a 15 Ω/cm² (1200 Å) ITO electrode was formed was cut into a size of 50 mm×50 mm×0.7 mm, and the cut substrate was ultrasonically cleaned for 5 minutes with isopropyl alcohol and then with pure water. The ultrasonically cleaned substrate was irradiated with an ultraviolet ray for 30 minutes and exposed to ozone, and then mounted on a vacuum deposition device.

Thereafter, NPB (N,N′-di(naphthalen-1-yl)-N,N′-diphenyl-benzidine) was deposited on the anode to form a hole injection layer having a thickness of 300 Å. HT-13 was deposited on the hole injection layer to form a hole transport layer having a thickness of 200 Å. CzSi (9-(4-tert-butylphenyl)-3,6-bis(triphenylsilyl)-9H-carbazole) was deposited on the hole transport layer to form an auxiliary emission layer having a thickness of 100 Å.

A host mixture of PH-13 and ET-17 mixed in a weight ratio of 1:1, PD1-14 (sensitizer) and a dopant compound were co-deposited in a weight ratio of 82:15:3 on the auxiliary emission layer a to form an emission layer having a thickness of 200 Å.

TSPO1 (diphenyl (4-(triphenylsilyl)phenyl) phosphine oxide) was deposited on the emission layer to form a hole blocking layer having a thickness of 200 Å. TPBi (1,3,5-tri(1-phenyl-1H-benzo[d]imidazol-2-yl)benzene) was deposited on the hole blocking layer to form an electron transport layer having a thickness of 300 Å. LiF was deposited on the electron transport layer to form an electron injection layer having a thickness of 10 Å. Al was deposited on the electron injection layer to form a cathode having a thickness of 3000 Å, and HT-7 was deposited on the cathode to form a capping layer having a thickness of 700 Å to obtain a light-emitting device. Each layer was formed by a vacuum deposition method.

As the above-mentioned dopant compound, compounds of Examples synthesized according to the above-described Synthesis Examples and commercially available compounds of Comparative Examples as shown below were used.

### Compounds of Examples

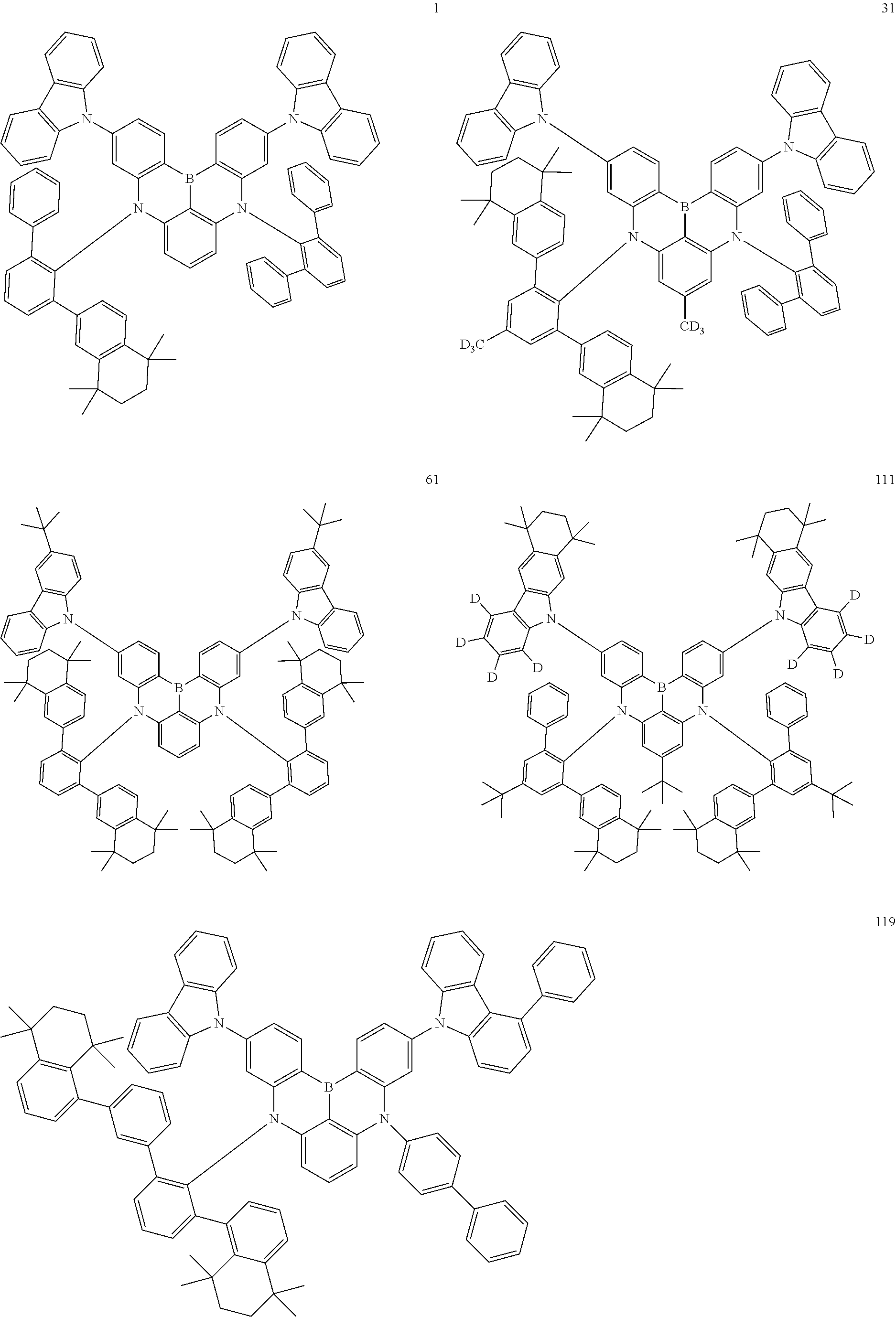

### Compounds of Comparative Examples

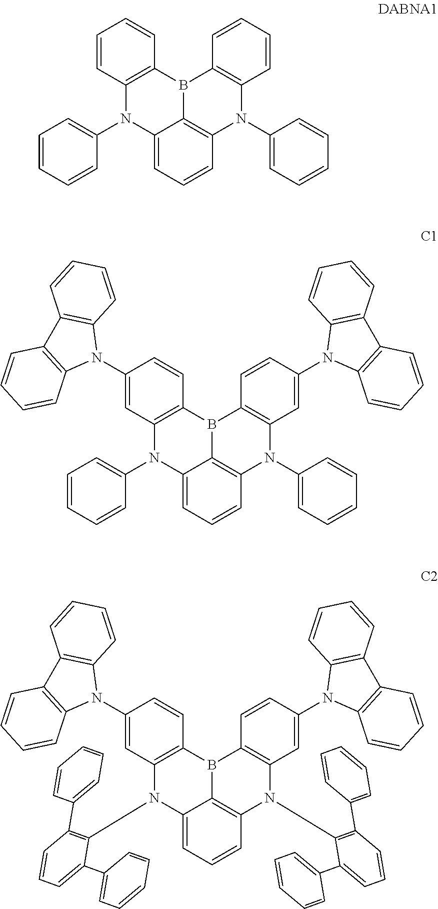 [SMILES: c1ccc(N2c3ccccc3B3c4ccccc4N(c4ccccc4)c4cccc2c43)cc1 ; c1ccc(N2c3cc(-n4c5ccccc5c5ccccc54)ccc3B3c4ccc(-n5c6ccccc6c6ccccc65)cc4N(c4ccccc4)c4cccc2c43)cc1 ; c1ccc(-c2cccc(-c3ccccc3)c2N2c3cc(-n4c5ccccc5c5ccccc54)ccc3B3c4ccc(-n5c6ccccc6c6ccccc65)cc4N(c4c(-c5ccccc5)cccc4-c4ccccc4)c4cccc2c43)cc1]

The following compounds were used in the fabrication of the light-emitting device. For example, the commercially available products were used after sublimation purification.

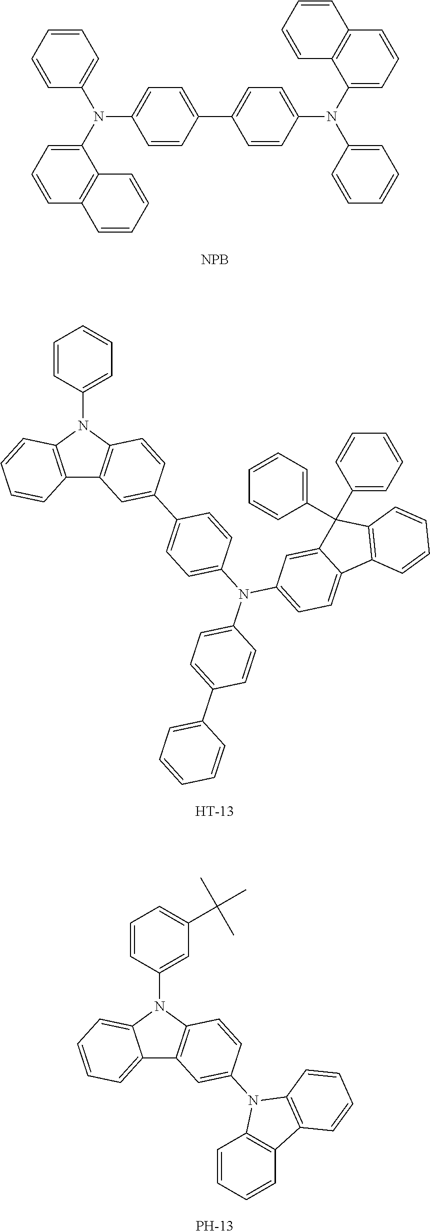

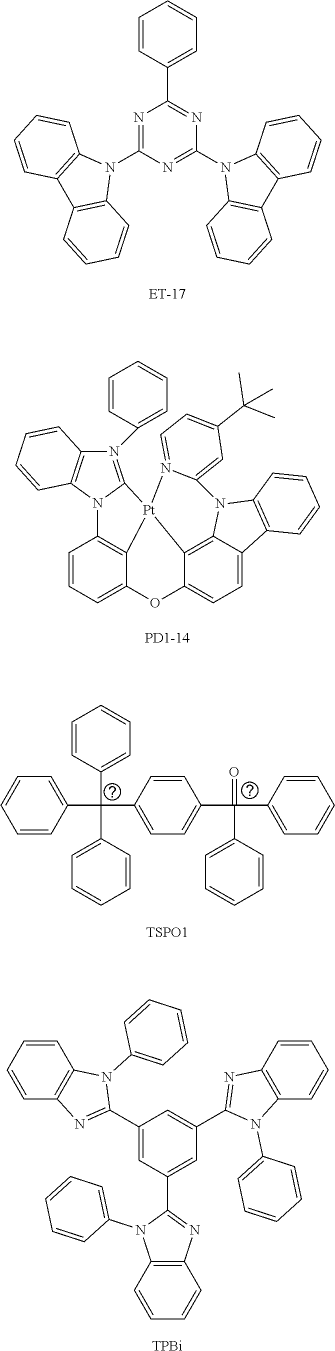

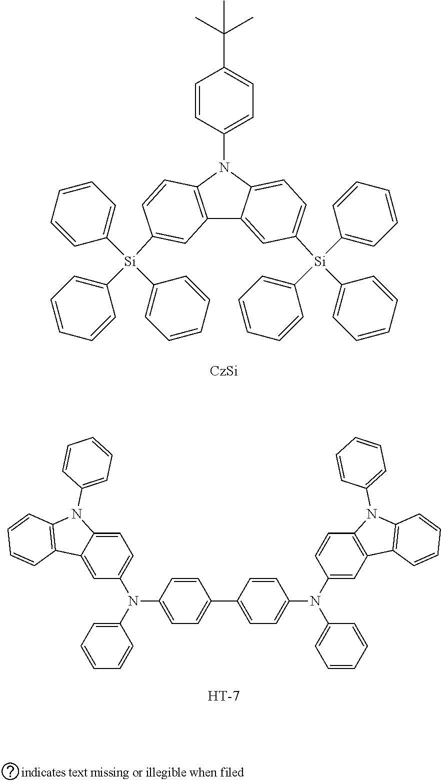

### Evaluation Example

### Evaluation Example 1: Evaluation on Properties of Polycyclic Compounds

Properties of each of the compounds of Examples and Comparative Examples were evaluated.

HOMO and LUMO energy levels (eV), an oscillator strength (f), an up-conversion rate constant (i.e., reverse intersystem crossing constant) (k_{RISC}, s⁻¹) from a triplet state to a singlet state, and energy levels (eV) of the triplet and the singlet state of each of the compounds were evaluated by a DFT (density functional theory) method of Gaussian 09 program which was structure-optimized at B3LYP/6-311G** level.

The results are shown in Table 1.

TABLE 1

| | | | | | | oscil- | |
|---|---|---|---|---|---|---|---|
| | E_{HOMO} | E_{LUMO} | E_{S1} | E_{T1} | ΔE_{ST} | lator | k_{RISC} |
| | [eV] | [eV] | [eV] | [eV] | [eV] | strength | [s⁻¹] |
| Example 1 | −5.19 | −1.64 | 2.98 | 2.59 | 0.39 | 0.36 | 6.13E+04 |
| Example 2 | −5.13 | −1.62 | 2.97 | 2.59 | 0.38 | 0.37 | 8.45E+04 |
| Example 3 | −5.12 | −1.61 | 2.97 | 2.60 | 0.37 | 0.39 | 2.31E+05 |
| Example 4 | −5.16 | −1.63 | 2.99 | 2.62 | 0.37 | 0.40 | 3.82E+05 |
| Example 5 | −5.14 | −1.63 | 2.98 | 2.60 | 0.38 | 0.38 | 1.65E+05 |
| Compar- | −5.00 | −1.37 | 3.10 | 2.62 | 0.48 | 0.20 | 2.26E+03 |
| ative | | | | | | | |
| Example 1 | | | | | | | |
| Compar- | −5.27 | −1.73 | 2.99 | 2.57 | 0.42 | 0.35 | 2.79E+04 |
| ative | | | | | | | |
| Example 2 | | | | | | | |
| Compar- | −5.26 | −1.71 | 2.99 | 2.59 | 0.40 | 0.34 | 3.13E+04 |
| ative | | | | | | | |
| Example 3 | | | | | | | |

Referring to Table 1, in each of the polycyclic compounds according to Examples, a difference (AEST) in the energy levels (eV) of the triplet state and the singlet state was lowered, and the oscillator strength was high. In each of the polycyclic compounds according to Example 3 and 4, AEST was lowered, the oscillator strength was high, and k_{RISC} was also markedly increased.

In the polycyclic compounds according to Comparative Examples, AEST was increased, and the oscillator strength and k_{RISC} were lowered.

### Evaluation Example 2. Performance Evaluation of Light-Emitting Device

Properties of each of the light-emitting devices fabricated as described above were measured at a current density of 10 mA/cm² using V7000 OLED IVL Test System, (Polaronix). For example, a driving voltage (V), a luminous efficiency (cd/A), and an emission wavelength at a luminance of 1000 cd/in² were measured using Keithley MU 236 and a luminance meter PR650.

The light-emitting device was continuously driven at a current density of 10 mA/cm², and a time until a luminance dropped to 95% of an initial value was measured. A relative value with respect to the time measured in the light-emitting device using the compound of Comparative Example 1 was expressed as a life-span (T95) of each light-emitting device.

The results are shown in Table 2.

TABLE 2

| | | | Light- | | | | |
|---|---|---|---|---|---|---|---|
| | host | | emitting | Driving | | Emission | life- |
| | (PH:ET = | sensitizer | material | voltage | efficiency | wavelength | span |
| | 1:1) | (15%) | (3%) | (V) | (cd/A) | (nm) | (T95) |
| Example | PH-13:ET- | PD1- | 1 | 4.1 | 35.2 | 455 | 7.3 |
| 1 | 17 | 14 | | | | | |
| Example | PH-13:ET- | PD1- | 31 | 4.1 | 35.8 | 455 | 7.5 |
| 2 | 17 | 14 | | | | | |
| Example | PH-13:ET- | PD1- | 61 | 4.2 | 37.6 | 454 | 8.9 |
| 3 | 17 | 14 | | | | | |
| Example | PH-13:ET- | PD1- | 111 | 4.3 | 37.4 | 456 | 9.0 |
| 4 | 17 | 14 | | | | | |
| Example | PH-13:ET- | PD1- | 119 | 4.3 | 36.3 | 455 | 7.7 |
| 5 | 17 | 14 | | | | | |
| Compar- | PH-13:ET- | PD1- | DABNA1 | 4.8 | 19.2 | 457 | 1 |
| ative | 17 | 14 | | | | | |
| Example | | | | | | | |
| 1 | | | | | | | |
| Compar- | PH-13:ET- | PD1- | C1 | 4.5 | 23.2 | 458 | 2.2 |
| ative | 17 | 14 | | | | | |
| Example | | | | | | | |
| 2 | | | | | | | |
| Compar- | PH-13:ET- | PD1- | C2 | 4.4 | 24.1 | 460 | 4.5 |
| ative | 17 | 14 | | | | | |
| Example | | | | | | | |
| 3 | | | | | | | |

Referring to Table 2, the polycyclic compounds according to Examples having enhanced multiple resonance effect each provided improved color properties of the light-emitting device. Additionally, in the polycyclic compounds according to Examples, an alicyclic hydrocarbon ring was condensed at a group bonded to a nitrogen atom in an emission core, so that a Dexter energy transfer was suppressed or reduced and a Forster energy transfer was induced. Accordingly, the luminous efficiency and life-span of the light-emitting device were enhanced.

In the polycyclic compounds according to Comparative Examples, the energy transfer between triplet excitons due to the Dexter energy transfer easily occurred to deteriorate the luminous efficiency and life-span of the light-emitting device.

In this disclosure, it will be further understood that the terms “comprise(s)/comprising,” “include(s)/including,” and/or “have(has)/having,” if (e.g., when) used in this disclosure, specify the presence of stated features, numbers, steps, operations, elements, components, and/or groups thereof, but do not preclude the presence or addition of one or more other features, numbers, steps, operations, elements, components, and/or groups thereof. Additionally, the terms “comprise(s)/comprising,” “include(s)/including,” “have/has/having,” or other similar terms include or support the terms “consisting of” and “consisting essentially of,” indicating the presence of stated features, numbers, steps, operations, elements, and/or components, without or essentially without the presence of other features, numbers, steps, operations, elements, components, and/or groups thereof.

In the disclosure, it will be understood that if (e.g., when) an element (or a region, a layer, a portion, and/or the like) is referred to as being “on” or “connected to” another element, it may be directly arranged on or connected to the other element, or intervening elements may be arranged therebetween. In contrast, “directly on” may refer to that there are no additional layers, films, regions, plates, and/or the like, between a layer, a film, a region, a plate, and/or the like and the other part. For example, “directly on” may refer to two layers or two members are arranged without utilizing an additional member such as an adhesive member therebetween.

As used herein, the term “and/or” or “or” may include any and all combinations of one or more of the associated listed items. Expressions such as “at least one of,” “one of,” and “selected from,” when preceding a list of elements, modify the entire list of elements and do not modify the individual elements of the list. For example, “at least one of a, b, or c,” “at least one selected from a, b, and c,” “at least one selected from among a to c,” and/or the like, may indicate only a, only b, only c, both (e.g., simultaneously) a and b, both (e.g., simultaneously) a and c, both (e.g., simultaneously) b and c, all of a, b, and c, or variations thereof. The “/” utilized herein may be interpreted as “and” or as “or” depending on the situation.

It will be understood that, although the terms “first,” “second,” and/or the like may be used herein to describe one or more suitable elements, components, regions, layers, and/or sections, these elements, components, regions, layers, and/or sections should not be limited by these terms. These terms are only used to distinguish one element, component, region, layer, or section from another element, component, region, layer, or section. Thus, a first element, component, region, layer, or section discussed herein could be termed a second element, component, region, layer, or section, respectively, without departing from the scope of the disclosure. Similarly, a second element, component, region, layer, or section may be termed a first element, component, region, layer, or section, respectively. As used herein, the singular forms, “a,” “an,” “one,” and “the” are intended to include the plural forms as well, unless the context clearly indicates otherwise. Further, the utilization of “may” when describing embodiments of the present disclosure refers to “one or more embodiments of the present disclosure”.

Unless otherwise defined, all terms (including technical and scientific terms) used herein have the same meaning as commonly understood by one of ordinary skill in the art to which this disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As utilized herein, the terms “substantially,” “about,” or similar terms are used as terms of approximation and not as terms of degree, and are intended to account for the inherent deviations in measured or calculated values that would be recognized by those of ordinary skill in the art. “About” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, or 5% of the stated value.

In the context of the present application and unless otherwise defined, the terms “use,” “using,” and “used” may be considered synonymous with the terms “utilize,” “utilizing,” and “utilized,” respectively.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this disclosure, including the claims, to expressly recite any sub-range subsumed within the ranges expressly recited herein.

The light emitting device, the display apparatus/device, the electronic apparatus/device, a device for manufacturing the same, or any other relevant apparatuses/devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random-access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

In the present disclosure, each suitable feature of the various embodiments of the disclosure may be combined or combined with each other, partially or entirely, and may be technically interlocked and operated in various suitable ways, and each embodiment may be implemented independently of each other or in conjunction with each other in any suitable manner unless otherwise stated or implied.

Although one or more embodiments of the disclosure have been described, it is understood that the disclosure should not be limited to these embodiments, but one or more suitable changes and modifications can be made by one ordinary skilled in the art within the spirit and scope of disclosure as hereinafter claimed.

Accordingly, the technical scope of the disclosure is not intended to be limited to the contents set forth in the detailed description of the disclosure, but is intended to be defined by the appended claims and equivalents thereof.

What is claimed is:

1. A polycyclic compound represented by Chemical Formula 1: 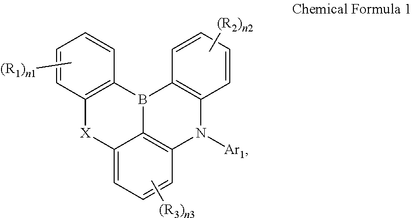
wherein, in Chemical Formula 1, X represents N(R₄), S, O, or Se, and Ar is represented by Chemical Formula 2, 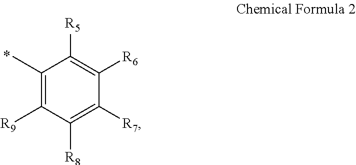
wherein, in Chemical Formulae 1 and 2, R₁ to R₉ are each independently selected from among hydrogen, deuterium, —OH, —CN, —F, —CL, —Br, —I, —CD₃, —CD₂H, —CDH₂, —CF₃, —CF₂H, —CFH₂, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₆₀ cycloalkyl group, a substituted or unsubstituted C₅-C₆₀ cycloalkenyl group, a substituted or unsubstituted C₃-C₆₀ heterocycloalkyl group, a substituted or unsubstituted C₃-C₆₀ heterocycloalkenyl group, a substituted or unsubstituted C₆-C₆₀ aryl group, a substituted or unsubstituted C₇-C₆₀ arylalkyl group, a substituted or unsubstituted C₂-C₆₀ heteroaryl group, a substituted or unsubstituted C₃-C₆₀ heteroarylalkyl group, a substituted or unsubstituted C₆-C₆₀ aryloxy group, a substituted or unsubstituted C₆-C₆₀ arylthio group, a substituted or unsubstituted C₈-C₆₀ condensed polycyclic group, and a substituted or unsubstituted silyl group, and two or more adjacent groups selected from among R₁ to R₉ are optionally combined with each other to form a saturated ring or an unsaturated ring,
n1 and n2 are the same as or different from each other, and are each an integer from 0 to 4, at least one of n1 or n2 is not 0, and n3 is an integer from 0 to 3,
at least one group selected from the group consisting of at least one R₁, at least one R₂, and a combination thereof is a substituted or unsubstituted carbazole group,
at least one selected from among R₅ to R₉ is an aryl group in which a substituted or unsubstituted alicyclic hydrocarbon ring is condensed; two or more adjacent groups selected from among R₅ to R₉ are bonded to each other to form an alicyclic hydrocarbon ring; or, at least one selected from among R₅ to R₉ is an aryl group in which a substituted or unsubstituted alicyclic hydrocarbon ring is condensed, and two or more adjacent groups among remaining groups of R₅ to R₉ are bonded to each other to form an alicyclic hydrocarbon ring, and
*- represents a bonding position.

2. The polycyclic compound of claim 1, wherein X represents N(R₄), and R₄ is represented by Chemical Formula 3: 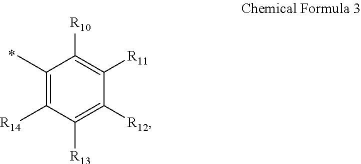
wherein, in Chemical Formula 3, R₁₀ to R₁₄ are each independently selected from among hydrogen, deuterium, —OH, —CN, —F, —CL, —Br, —I, —CD₃, —CD₂H, —CDH₂, —CF₃, —CF₂H, —CFH₂, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₆₀ cycloalkyl group, a substituted or unsubstituted C₅-C₆₀ cycloalkenyl group, a substituted or unsubstituted C₃-C₆₀ heterocycloalkyl group, a substituted or unsubstituted C₃-C₆₀ heterocycloalkenyl group, a substituted or unsubstituted C₆-C₆₀ aryl group, a substituted or unsubstituted C₇-C₆₀ arylalkyl group, a substituted or unsubstituted C₂-C₆₀ heteroaryl group, a substituted or unsubstituted C₃-C₆₀ heteroarylalkyl group, a substituted or unsubstituted C₆-C₆₀ aryloxy group, a substituted or unsubstituted C₆-C₆₀ arylthio group, a substituted or unsubstituted C₈-C₆₀ condensed polycyclic group, and a substituted or unsubstituted silyl group, and two or more adjacent groups selected from among R₁₀ to R₁₄ are optionally combined with each other to form a saturated ring or an unsaturated ring,
wherein: at least one selected from among R₁₀ to R₁₄ is an aryl group in which a substituted or unsubstituted alicyclic hydrocarbon ring is condensed; two or more adjacent groups selected from among R₁₀ to R₁₄ is combined with each other to form an alicyclic hydrocarbon ring; or, at least one selected from among R₁₀ to R₁₄ is an aryl group in which a substituted or unsubstituted alicyclic hydrocarbon ring is condensed, and two or more adjacent groups selected from among remaining groups of R₁₀ to R₁₄ are bonded to each other to form an alicyclic hydrocarbon ring, and
*- represents a bonding position.

3. The polycyclic compound of claim 1, wherein the alicyclic hydrocarbon ring is selected from among a 5-membered ring to a 9-membered ring.

4. The polycyclic compound of claim 1, wherein the alicyclic hydrocarbon ring is each independently selected from among a substituted or unsubstituted C₅-C₃₀ cycloalkane, a substituted or unsubstituted C₅-C₃₀ bicycloalkane, and a substituted or unsubstituted C₉-C₃₀ spiroalkane.

5. The polycyclic compound of claim 4, wherein the alicyclic hydrocarbon ring is each independently selected from the group consisting of substituted or unsubstituted cyclopentane, substituted or unsubstituted cyclohexane, substituted or unsubstituted cycloheptane, substituted or unsubstituted bicyclo[2.1.0]pentane, substituted or unsubstituted bicyclo[2.2.0]hexane, substituted or unsubstituted bicyclo[4.1.0]heptane, substituted or unsubstituted spiro[4.4]nonane, substituted or unsubstituted spiro[4.5]decane, substituted or unsubstituted spiro[5.5]undecane, substituted or unsubstituted spiro[6.5]dodecane, and substituted or unsubstituted spiro[6.6]tridecane.

6. The polycyclic compound of claim 1, wherein the polycyclic compound is represented by Chemical Formula 1-1: 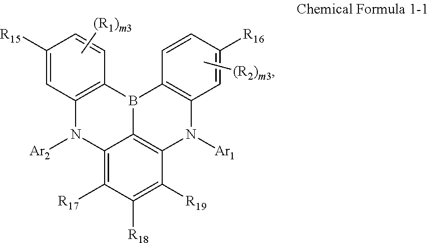
wherein, in Chemical Formula 1-1, at least one of Ar₁ or Ar₂ is each independently selected from among groups represented by Chemical Formulae 4-1 to 4-19, 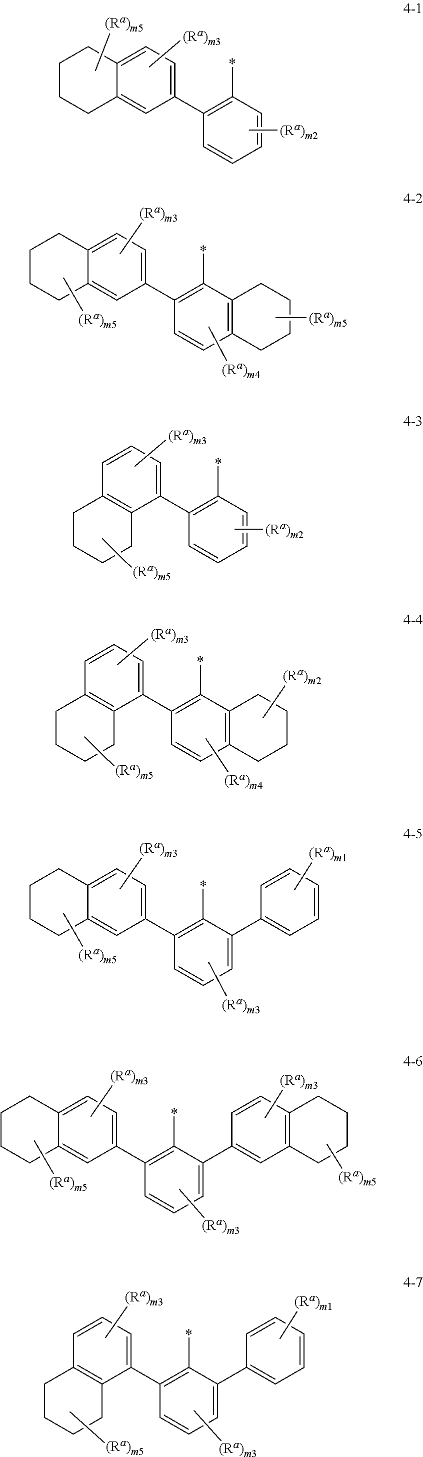 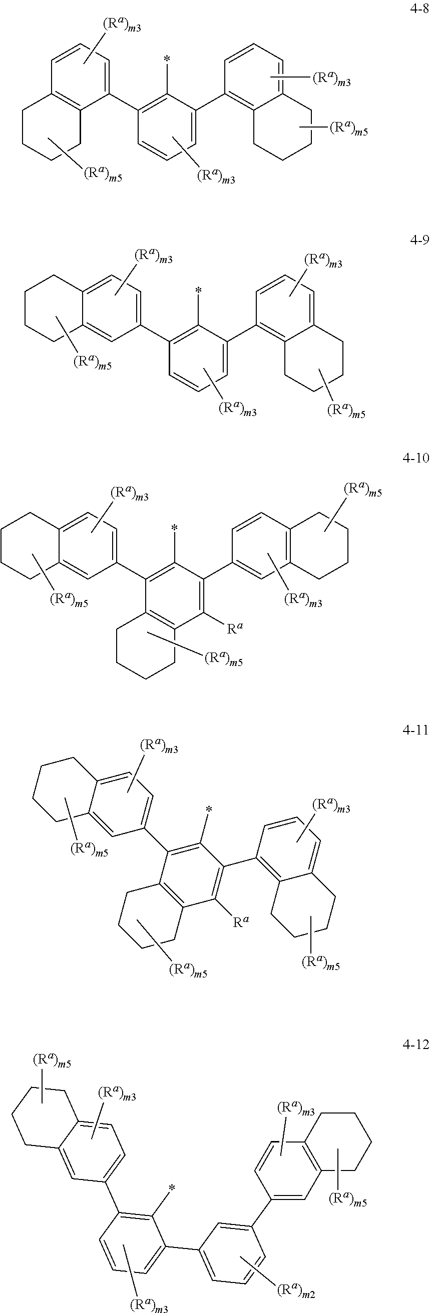 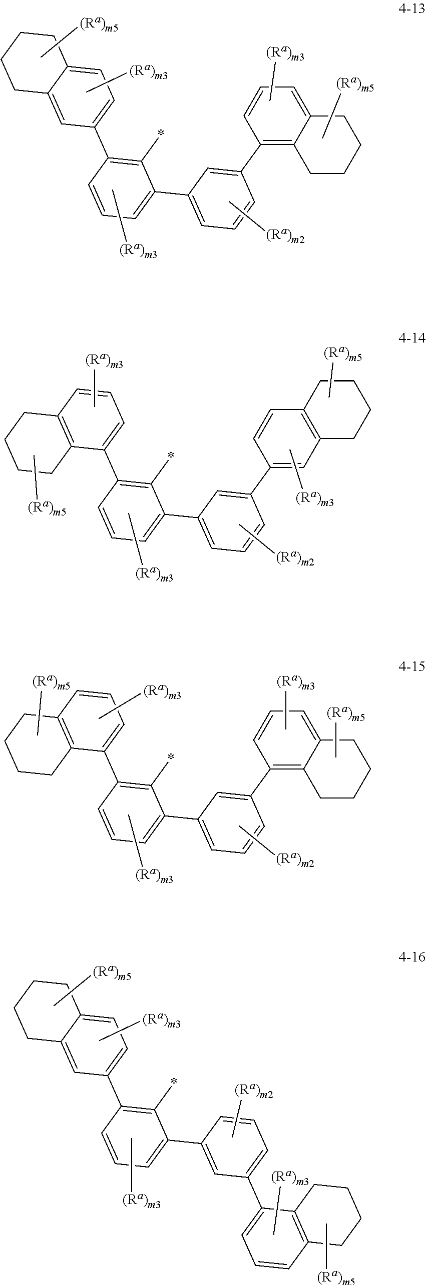 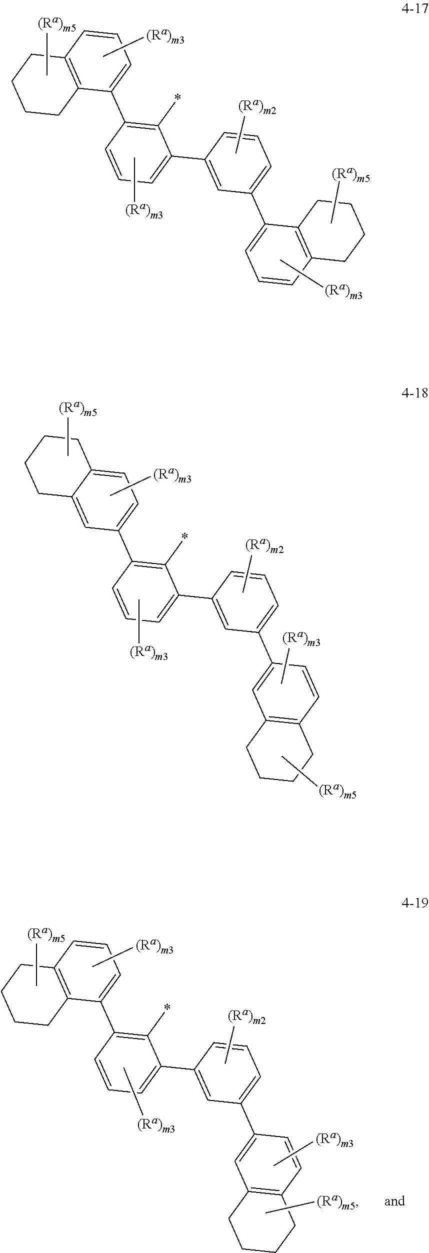
wherein, in Chemical Formula 1-1 and Chemical Formulae 4-1 to 4-19, R₁, R₂, R₁₅ to R₁₉, and R^{a} are each independently selected from among hydrogen, deuterium, —OH, —ON, —F, —CL, —Br, —I, —CD₃, —CD₂H, —CDH₂, —CF₃, —CF₂H, —CFH₂, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₆₀ cycloalkyl group, a substituted or unsubstituted C₅-C₆₀ cycloalkenyl group, a substituted or unsubstituted C₃-C₆₀ heterocycloalkyl group, a substituted or unsubstituted C₃-C₆₀ heterocycloalkenyl group, a substituted or unsubstituted C₆-C₆₀ aryl group, a substituted or unsubstituted C₇-C₆₀ arylalkyl group, a substituted or unsubstituted C₂-C₆₀ heteroaryl group, a substituted or unsubstituted C₃-C₆₀ heteroarylalkyl group, a substituted or unsubstituted C₆-C₆₀ aryloxy group, a substituted or unsubstituted C₆-C₆₀ arylthio group, a substituted or unsubstituted C₈-C₆₀ condensed polycyclic group, and a substituted or unsubstituted silyl group, and two or more adjacent groups selected from among R₁, R₂, R₁₅ to R₁₉, and R^{a} are optionally combined with each other to form a saturated ring or an unsaturated ring,
at least one of R₁₅ or R₁₆ is a substituted or unsubstituted carbazole group,
m1 at each occurrence is independently an integer from 0 to 5,
m2 at each occurrence is independently an integer from 0 to 4,
m3 at each occurrence is independently an integer from 0 to 3,
m4 at each occurrence is independently an integer from 0 to 2,
m5 at each occurrence is independently an integer from 0 to 8, and
*- represents a bonding position.

7. The polycyclic compound of claim 6, wherein Ar₁ and Ar₂ are each independently selected from among the groups represented by Chemical Formulae 4-1 to 4-19.

8. The polycyclic compound of claim 6, wherein at least one of Ar₁ or Ar₂ is each selected from among the groups represented by Chemical Formulae 4-5 to 4-11.

9. The polycyclic compound of claim 6, wherein R₁₅ and R₁₆ are each independently selected from among groups represented by Chemical Formulae 5-1 to 5-6, and
at least one of R₁₅ or R₁₆ is represented by Chemical Formula 5-1: 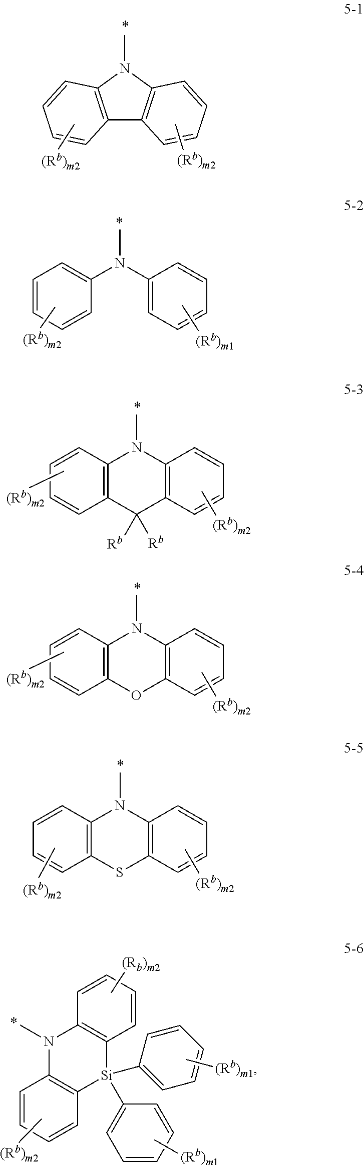
wherein, in Chemical Formulae 5-1 to 5-6, R^{b} is each independently selected from among hydrogen, deuterium, —OH, —CN, —F, —CL, —Br, —I, —CD₃, —CD₂H, —CDH₂, —CF₃, —CF₂H, —CFH₂, a substituted or unsubstituted C₁-C₆₀ alkyl group, a substituted or unsubstituted C₂-C₆₀ alkenyl group, a substituted or unsubstituted C₃-C₆₀ cycloalkyl group, a substituted or unsubstituted C₅-C₆₀ cycloalkenyl group, a substituted or unsubstituted C₃-C₆₀ heterocycloalkyl group, a substituted or unsubstituted C₃-C₆₀ heterocycloalkenyl group, a substituted or unsubstituted C₆-C₆₀ aryl group, a substituted or unsubstituted C₇-C₆₀ arylalkyl group, a substituted or unsubstituted C₂-C₆₀ heteroaryl group, and a substituted or unsubstituted C₃-C₆₀ heteroarylalkyl group, and two or more adjacent groups selected from among R^{b} are optionally combined with each other to form a saturated ring or an unsaturated ring, and
wherein m1 at each occurrence is independently an integer from 0 to 5,
m2 at each occurrence is independently an integer from 0 to 4, and
*- represents a bonding position.

10. The polycyclic compound of claim 6, wherein R₁₇ to R₁₉ are each independently selected from among hydrogen, deuterium, —CD₃, —CD₂H, —CDH₂, and groups represented by Chemical Formulae 6-1 to 6-8: 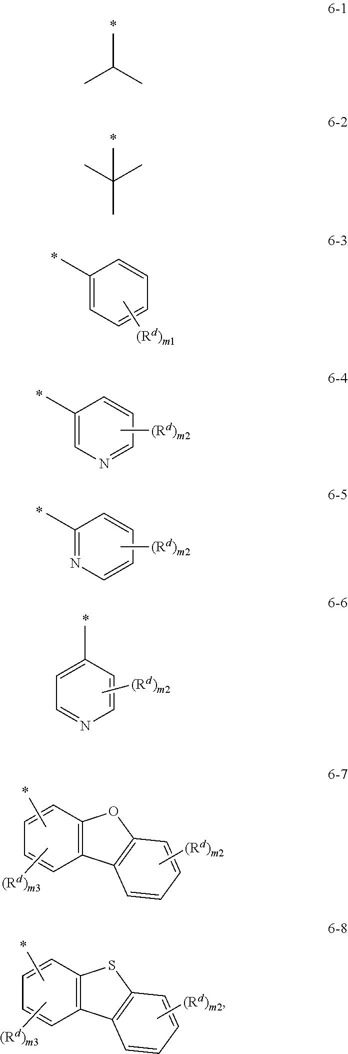
wherein, in Chemical Formulae 6-1 to 6-8, R^{d} is each independently selected from among hydrogen, deuterium, —OH, —CN, —F, —CL, —Br, —I, —CD₃, —CD₂H, —CDH₂, —CF₃, —CF₂H, —CFH₂, a substituted or unsubstituted C₁-C₃₀ alkyl group, a substituted or unsubstituted C₂-C₃₀ alkenyl group, a substituted or unsubstituted C₃-C₃₀ cycloalkyl group, a substituted or unsubstituted C₅-C₃₀ cycloalkenyl group, a substituted or unsubstituted C₃-C₃₀ heterocycloalkyl group, a substituted or unsubstituted C₃-C₃₀ heterocycloalkenyl group, a substituted or unsubstituted C₆-C₃₀ aryl group, a substituted or unsubstituted C₇-C₃₀ arylalkyl group, a substituted or unsubstituted C₂-C₃₀ heteroaryl group, and a substituted or unsubstituted C₃-C₃₀ heteroarylalkyl group, and two or more adjacent groups selected from among R^{d} are optionally combined with each other to form a saturated ring or an unsaturated ring, and
wherein m1 at each occurrence is independently an integer of 0 to 5,
m2 at each occurrence is independently an integer of 0 to 4,
m3 at each occurrence is independently an integer of 0 to 3, and
*- represents a bonding position.

11. The polycyclic compound of claim 10, wherein
R₁₇ and R₁₉ are each independently hydrogen, deuterium, —CD₃, —CD₂H, or -CDH₂, and
R₁₈ is selected from among hydrogen, deuterium, —CD₃, —CD₂H, —CDH₂, and groups represented by Chemical Formulae 6-1 to 6-3.

12. The polycyclic compound of claim 1, wherein a reverse intersystem crossing constant (k_{RISC}) of the polycyclic compound is 6.00×10⁴ s⁻¹ or more.

13. The polycyclic compound of claim 1, wherein,
an oscillator strength of the polycyclic compound is 0.36 or more, and
an absolute value (ΔEst) of a difference between an energy level of a lowest singlet excited state (S₁ level) and an energy level of a lowest triplet excited state (T1 level) of the polycyclic compound is 0.39 eV or less.

14. A light-emitting device, comprising:
a first electrode;
a second electrode; and
an emission layer between the first electrode and the second electrode, the emission layer comprising a polycyclic compound represented by Chemical Formula 1: 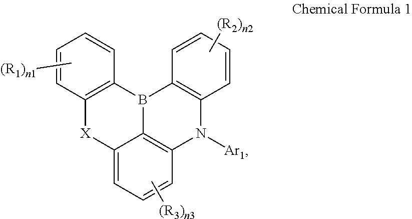
wherein, in Chemical Formula 1, X represents N(R₄), S, O, or Se, and
Ar₁ is represented by Chemical Formula 2, 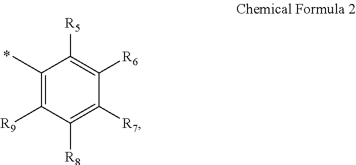
wherein, in Chemical Formulae 1 and 2, R₁ to R₉ are each independently selected from among hydrogen, deuterium, —OH, —CN, —F, —CL, —Br, —I, —CD₃, —CD₂H, —CDH₂, —CF₃, —CF₂H, —CFH₂, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₆₀ cycloalkyl group, a substituted or unsubstituted C₅-C₆₀ cycloalkenyl group, a substituted or unsubstituted C₃-C₆₀ heterocycloalkyl group, a substituted or unsubstituted C₃-C₆₀ heterocycloalkenyl group, a substituted or unsubstituted C₆-C₆₀ aryl group, a substituted or unsubstituted C₇-C₆₀ arylalkyl group, a substituted or unsubstituted C₂-C₆₀ heteroaryl group, a substituted or unsubstituted C₃-C₆₀ heteroarylalkyl group, a substituted or unsubstituted C₆-C₆₀ aryloxy group, a substituted or unsubstituted C₆-C₆₀ arylthio group, a substituted or unsubstituted C₈-C₆₀ condensed polycyclic group, and a substituted or unsubstituted silyl group, and two or more adjacent groups selected from among R₁ to R₉ are optionally combined with each other to form a saturated ring or an unsaturated ring,
n1 and n2 are the same as or different from each other, and are each an integer from 0 to 4, at least one of n1 or n2 is not 0, and n3 is an integer from 0 to 3,
at least one group selected from the group consisting of at least one R₁, at least one R₂, and a combination thereof is a substituted or unsubstituted carbazole group,
at least one selected from among R₅ to R₉ is an aryl group in which a substituted or unsubstituted alicyclic hydrocarbon ring is condensed; two or more adjacent groups selected from among R₅ to R₉ are bonded to each other to form an alicyclic hydrocarbon ring; or, at least one selected from among R₅ to R₉ is an aryl group in which a substituted or unsubstituted alicyclic hydrocarbon ring is condensed, and two or more adjacent groups selected from among remaining groups of R₅ to R₉ are bonded to each other to form an alicyclic hydrocarbon ring, and
*- represents a bonding position.

15. The light-emitting device of claim 14, further comprising a charge generation layer between the first electrode and the second electrode,
wherein the emission layer comprises a plurality of emission layers, and
the charge generation layer is between adjacent emission layers among the plurality of emission layers, and
wherein at least one selected from among the plurality of emission layers comprises the polycyclic compound of Chemical Formula 1.

16. The light-emitting device of claim 14, wherein the polycyclic compound is a thermally activated delayed fluorescence (TADF) dopant, a host for a phosphorescent dopant, or a fluorescent host.

17. The light-emitting device of claim 15, wherein each of the plurality of emission layers comprises the polycyclic compound, and
the polycyclic compound is a thermally activated delayed fluorescence (TADF) dopant.

18. The light-emitting device of claim 14, wherein the emission layer is configured to emit a blue light having a maximum emission wavelength from 440 nm to 490 nm.

19. An electronic device comprising a light-emitting device, wherein,
the light-emitting device comprises:
a first electrode;
a second electrode; and
an emission layer between the first electrode and the second electrode, the emission layer comprising a polycyclic compound represented by Chemical Formula 1: 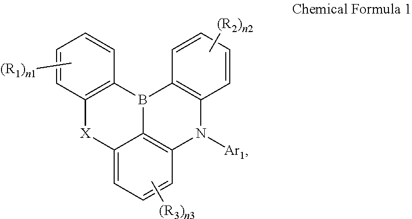
wherein, in Chemical Formula 1, X represents N(R₄), S, O, or Se, and
Ar₁ is represented by Chemical Formula 2, 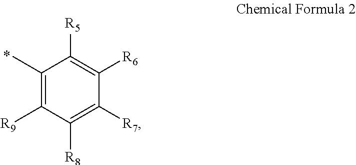
wherein, in Chemical Formulae 1 and 2, R₁ to R₉ are each independently selected from among hydrogen, deuterium, —OH, —CN, —F, —CL, —Br, —I, —CD₃, —CD₂H, —CDH₂, —CF₃, —CF₂H, —CFH₂, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₆₀ cycloalkyl group, a substituted or unsubstituted C₅-C₆₀ cycloalkenyl group, a substituted or unsubstituted C₃-C₆₀ heterocycloalkyl group, a substituted or unsubstituted C₃-C₆₀ heterocycloalkenyl group, a substituted or unsubstituted C₆-C₆₀ aryl group, a substituted or unsubstituted C₇-C₆₀ arylalkyl group, a substituted or unsubstituted C₂-C₆₀ heteroaryl group, a substituted or unsubstituted C₃-C₆₀ heteroarylalkyl group, a substituted or unsubstituted C₆-C₆₀ aryloxy group, a substituted or unsubstituted C₆-C₆₀ arylthio group, a substituted or unsubstituted C₈-C₆₀ condensed polycyclic group, and a substituted or unsubstituted silyl group, and two or more adjacent groups selected from among R₁ to R₉ are optionally combined with each other to form a saturated ring or an unsaturated ring,
n1 and n2 are the same as or different from each other, and are each an integer from 0 to 4, at least one of n1 or n2 is not 0, and n3 is an integer from 0 to 3,
at least one group selected from the group consisting of at least one R₁, at least one R₂, and a combination thereof is a substituted or unsubstituted carbazole group,
at least one selected from among R₅ to R₉ is an aryl group in which a substituted or unsubstituted alicyclic hydrocarbon ring is condensed; two or more adjacent groups selected from among R₅ to R₉ are bonded to each other to form an alicyclic hydrocarbon ring; or, at least one selected from among R₅ to R₉ is an aryl group in which a substituted or unsubstituted alicyclic hydrocarbon ring is condensed, and two or more adjacent groups selected from among remaining groups of R₅ to R₉ are bonded to each other to form an alicyclic hydrocarbon ring, and
*- represents a bonding position.

20. The electronic device of claim 19, wherein the electronic device is at least one of a flat panel display, a curved display, a computer monitor, a medical monitor, a television, a billboard, an indoor light, an indoor light, a signal light, a head-up display, a full transparent display, a partial transparent display, a flexible display, a rollable display, a foldable display, a stretchable display, a laser printer, a phone, a mobile phone, a tablet, a phablet, a personal information terminal (PDA), a wearable device, a laptop computer, a digital camera, a camcorder, a viewfinder, a micro display, a 3D display, a virtual reality display, an augmented reality display, a vehicle, a video wall comprising multiple displays tiled together, a theater or stadium screen, a phototherapy device, or a signage.
